(19) United States
(12) Patent Application Publication
(10) Pub. No.: US 2024/0260421 A1
(43) Pub. Date: Aug. 1, 2024

(54) LIGHT EMITTING ELEMENT AND DISPLAY DEVICE

(71) Applicant: Sony Semiconductor Solutions Corporation, Kanagawa (JP)

(72) Inventor: Shinichi Arakawa, Kanagawa (JP)

(21) Appl. No.: 18/030,172

(22) PCT Filed: Oct. 6, 2021
(86) PCT No.: PCT/JP2021/036948

§ 371 Date: Apr. 4, 2023

(30) Foreign Application Priority Data
Oct. 13, 2020 (JP) 2020-172648

(51) Int. Cl. H10K 59/80

(52) U.S. Cl. CPC H10K 59/879

(57) ABSTRACT

A light emitting element (10) includes a light emitting unit (30) including one light emitting region, a first optical path control unit group consisting of a plurality of first optical path control units (71) formed above the light emitting unit (30), and a second optical path control unit (72) formed on or above the first optical path control unit group, wherein the first optical path control units 71 and the second optical path control unit (72) have positive optical power, and light emitted from the light emitting unit (30) and focused by the first optical path control units (71) is further focused by the second optical path control unit (72).

### FIELD

The present disclosure relates to a light emitting element and a display device.

### BACKGROUND

Display devices in which organic electroluminescence (EL) elements are used as light emitting elements (organic EL display devices) have recently been developed. In a light emitting element constituting an organic EL display device, an organic layer including at least a light emitting layer and a second electrode (upper electrode, e.g. cathode electrode) are formed on a first electrode (lower electrode, e.g. anode electrode) formed separately for each pixel, for example. For example, a red light emitting element in which an organic layer that emits white light or red light and a red color filter layer are combined, a green light emitting element in which an organic layer that emits white light or green light and a green color filter layer are combined, and a blue light emitting element in which an organic layer that emits white light or blue light and a blue color filter layer are combined, are each provided as a subpixel, and these subpixels constitute one pixel (light emitting element unit). Light from the organic layers is emitted outside via the second electrode (upper electrode).

From JP 2012-109230 A, known is a solid-state light emitting element 270 having a light emitting body in which a hemispherical structure 251 is provided on a first surface of a low refractive index member 250 and a hemispherical recessed structure 252 is provided on a second surface to improve light extraction efficiency. The light emitting body 270 includes a plurality of sub solid-state light emitting bodies 270a, 270b, 270c . . . , and an outer shape of a light emitting region of the sub solid-state light emitting bodies 270a, 270b, 270c . . . is smaller than an outer shape of the hemispherical recessed structure 252 (see FIGS. 5 and 6 of JP 2012-109230 A). The sub solid-state light emitting bodies 270a, 270b, 270c . . . and the second surface of the low refractive index member 250 are bonded by a high refractive index bonding layer 260. Light having entered the high refractive index bonding layer 260 travels to the hemispherical recessed structure 252 provided in the low refractive index member 250, but since the hemispherical recessed structure 252 has various angles not parallel to the light emitting surface, total reflection is unlikely to be repeated at the interface formed by the high refractive index bonding layer 260 and the second surface of the low refractive index member 250.

### CITATION LIST

### Patent Literature

Patent Literature 1: JP 2012-109230 A

### SUMMARY

### Technical Problem

However, manufacturing the solid-state light emitting element disclosed in the above Patent Publication is complicated since the hemispherical recessed structure 252 is provided to face the light emitting region of the sub solid-state light emitting bodies 270a, 270b, 270c . . . . In addition, the degree of freedom in designing the light emitting bodies is low since the sub solid-state light emitting bodies and the low refractive index member 250 are bonded by the high refractive index bonding layer 260. Further, the above-described Patent Publication does not mention at all optical crosstalk that may occur between adjacent solid-state light emitting elements.

An object of the present disclosure is to provide a light emitting element having a configuration and a structure with which complicated manufacturing can be avoided, desired structures in a wide range can be obtained, and optical crosstalk hardly occurs, and a display device including the light emitting element.

### Solution to Problem

To solve the problems described above, a light emitting element according to the present disclosure includes: a light emitting unit including one light emitting region; a first optical path control unit group consisting of a plurality of first optical path control units formed above the light emitting unit; and a second optical path control unit formed on or above the first optical path control unit group, wherein the first optical path control units and the second optical path control unit have positive optical power, and light emitted from the light emitting unit and focused by the first optical path control units is further focused by the second optical path control unit.

To solve the problems described above, a display device according to the present disclosure includes: a first substrate; second substrate; and a plurality of light emitting element units including a plurality of types of light emitting elements, wherein each light emitting element includes: a light emitting unit provided above the first substrate and including one light emitting region, a first optical path control unit group consisting of a plurality of first optical path control units formed above the light emitting unit; and a second optical path control unit formed on or above the first optical path control unit group, wherein the first optical path control units and the second optical path control unit have positive optical power, and light emitted from the light emitting unit and focused by the first optical path control units is further focused by the second optical path control unit.

### BRIEF DESCRIPTION OF DRAWINGS

FIG. 1 is a schematic and partial sectional view of a light emitting element and a display device of Example 1.

FIG. 2 is a schematic and partial sectional view in which a part of the light emitting element of Example 1 is enlarged.

FIG. 3A is a diagram schematically illustrating an arrangement relationship between a first optical path control unit and a second optical path control unit in the light emitting element of Example 1.

FIG. 3B is a diagram schematically illustrating an arrangement relationship between the first optical path control unit and the second optical path control unit in the light emitting element of Example 1.

FIG. 4A is a diagram schematically illustrating an arrangement relationship between the first optical path control unit and the second optical path control unit in the light emitting element of Example 1.

FIG. 4B is a diagram schematically illustrating an arrangement relationship between the first optical path control unit and the second optical path control unit in the light emitting element of Example 1.

FIG. 5A is a schematic and partial sectional view in which a part of Modification-1 of the light emitting element of Example 1 is enlarged.

FIG. 5B is a schematic and partial sectional view in which a part of Modification-2 of the light emitting element of Example 1 is enlarged.

FIG. 6A is a schematic and partial sectional view in which a part of Modification-3 of the light emitting element of Example 1 is enlarged. 10

FIG. 6B is a schematic and partial sectional view in which a part of Modification-4 of the light emitting element of Example 1 is enlarged.

FIG. 7A is a diagram schematically illustrating an array of light emitting elements in the display device of Example 1.

FIG. 7B is a diagram schematically illustrating an array of light emitting elements in the display device of Example 1.

FIG. 7C is a diagram schematically illustrating an array of light emitting elements in the display device of Example 1.

FIG. 7D is a diagram schematically illustrating an array of light emitting elements in the display device of Example 1.

FIG. 7E is a diagram schematically illustrating an array of light emitting elements in the display device of Example 1.

FIG. 8 is a schematic and partial sectional view of Modification-5 of the light emitting element and display device of Example 1.

FIG. 9 is a schematic and partial sectional view of Modification-6 of the light emitting element and display device of Example 1.

FIG. 10 is a schematic and partial sectional view of Modification-7 of the light emitting element and display device of Example 1.

FIG. 11 is a schematic and partial sectional view in which a part of a light emitting element of Example 2 is enlarged.

FIG. 12A is a schematic and partial sectional view in which a part of Modification-1 of the light emitting element of Example 2 is enlarged.

FIG. 12B is a schematic and partial sectional view in which a part of Modification-2 of the light emitting element of Example 2 is enlarged.

FIG. 13A is a schematic and partial sectional view in which a part of Modification-3 of the light emitting element of Example 2 is enlarged.

FIG. 13B is a schematic and partial sectional view in which a part of Modification-4 of the light emitting element of Example 2 is enlarged.

FIG. 14 is a schematic and partial sectional view of a light emitting element and a display device of Example 3.

FIG. 15 is a schematic and partial sectional view in which a part of the light emitting element of Example 3 is enlarged.

FIG. 16A is a schematic and partial sectional view in which a part of Modification-1 of the light emitting element of Example 3 is enlarged.

FIG. 16B is a schematic and partial sectional view in which a part of Modification-2 of the light emitting element of Example 3 is enlarged.

FIG. 17A is a schematic and partial sectional view in which a part of Modification-3 of the light emitting element of Example 3 is enlarged.

FIG. 17B is a schematic and partial sectional view in which a part of Modification-4 of the light emitting element of Example 3 is enlarged.

FIG. 18A is a schematic and partial sectional view in which a part of Modification-5 of the light emitting element of Example 3 is enlarged.

FIG. 18B is a schematic and partial sectional view in which a part of Modification-6 of the light emitting element of Example 3 is enlarged.

FIG. 19 is a schematic and partial sectional view of a light emitting element and a display device of Example 4.

FIG. 20 is a schematic and partial sectional view of a light emitting element of Example 5.

FIG. 21 is a schematic and partial sectional view of a light emitting element for explaining behavior of light from the light emitting element of Example 5.

FIG. 22A is a schematic and partial end view of a modification of the light emitting element of Example 5.

FIG. 22B is a schematic and partial end view of the modification of the light emitting element of Example 5.

FIG. 23A is a schematic and partial end view of another modification of the light emitting element of Example 5.

FIG. 23B is a schematic and partial end view of the other modification of the light emitting element of Example 5.

FIG. 24A is a schematic and partial end view of a base and the like for explaining a method for producing the display device of Example 5 illustrated in FIG. 20.

FIG. 24B is a schematic and partial end view of the base and the like for explaining the method for producing the display device of Example 5 illustrated in FIG. 20.

FIG. 24C is a schematic and partial end view of the base and the like for explaining the method for producing the display device of Example 5 illustrated in FIG. 20.

FIG. 25A is a schematic and partial end view of the base and the like for explaining the method for producing the display device of Example 5 illustrated in FIG. 20 following FIG. 24C.

FIG. 25B is a schematic and partial end view of the base and the like for explaining the method for producing the display device of Example 5 illustrated in FIG. 20 following FIG. 24C.

FIG. 26A is a schematic and partial end view of a base and the like for explaining another method for producing the display device of Example 5 illustrated in FIG. 20.

FIG. 26B is a schematic and partial end view of the base and the like for explaining the other method for producing the display device of Example 5 illustrated in FIG. 20.

FIG. 27 is a schematic and partial sectional view of a light emitting element and a display device of Example 6.

FIG. 28A is a conceptual diagram of light emitting elements having a first example of a resonator structure in Example 6.

FIG. 28B is a conceptual diagram of light emitting elements having a second example of the resonator structure in Example 6.

FIG. 29A is a conceptual diagram of light emitting elements having a third example of the resonator structure in Example 6.

FIG. 29B is a conceptual diagram of light emitting elements having a fourth example of the resonator structure in Example 6.

FIG. 30A is a conceptual diagram of light emitting elements having a fifth example of the resonator structure in Example 6.

FIG. 30B is a conceptual diagram of light emitting elements having a sixth example of the resonator structure in Example 6.

FIG. 31A is a conceptual diagram of light emitting elements having a seventh example of the resonator structure in Example 6.

FIG. 31B is a conceptual diagram of light emitting elements having an eighth example of the resonator structure in Example 6.

FIG. 31C is a conceptual diagram of light emitting elements having the eighth example of the resonator structure in Example 6.

FIG. 32 is a conceptual diagram for explaining a relationship between a normal line LN₀ passing through the center of a light emitting region and a normal line LN₁ passing through the center of a second optical path control unit in a display device of Example 7.

FIG. 33A is a schematic view illustrating a positional relationship between a light emitting element and a reference point in the display device of Example 7.

FIG. 33B is a schematic view illustrating a positional relationship between a light emitting element and a reference point in the display device of Example 7.

FIG. 34A is a diagram schematically illustrating a positional relationship between a light emitting element and a reference point in a modification of the display device of Example 7.

FIG. 34B is a diagram schematically illustrating a positional relationship between a light emitting element and a reference point in the modification of the display device of Example 7.

FIG. 35A is a diagram schematically illustrating a change of D_{0-X} with respect to a change of D_{1-X} and a change of D_{0-Y} with respect to a change of D_{1-Y} in the display device of Example 7.

FIG. 35B is a diagram schematically illustrating a change of D_{0-X} with respect to a change of D_{1-X} and a change of D_{0-Y} with respect to a change of D_{1-Y} in the display device of Example 7.

FIG. 35C is a diagram schematically illustrating a change of D_{0-X} with respect to a change of D_{1-X} and a change of D_{0-Y} with respect to a change of D_{1-Y} in the display device of Example 7.

FIG. 35D is a diagram schematically illustrating a change of D_{0-X} with respect to a change of D_{1-X} and a change of D_{0-Y} with respect to a change of D_{1-Y} in the display device of Example 7.

FIG. 36A is a diagram schematically illustrating a change of D_{0-X} with respect to a change of D_{1-X} and a change of D_{0-Y} with respect to a change of D_{1-Y} in the display device of Example 7.

FIG. 36B is a diagram schematically illustrating a change of D_{0-X} with respect to a change of D_{1-X} and a change of D_{0-Y} with respect to a change of D_{1-Y} in the display device of Example 7.

FIG. 36C is a diagram schematically illustrating a change of D_{0-X} with respect to a change of D_{1-X} and a change of D_{0-Y} with respect to a change of D_{1-Y} in the display device of Example 7.

FIG. 36D is a diagram schematically illustrating a change of D_{0-X} with respect to a change of D_{1-X} and a change of D_{0-Y} with respect to a change of D_{1-Y} in the display device of Example 7.

FIG. 37A is a diagram schematically illustrating a change of D_{0-X} with respect to a change of D_{1-X} and a change of D_{0-Y} with respect to a change of D_{1-Y} in the display device of Example 7.

FIG. 37B is a diagram schematically illustrating a change of D_{0-X} with respect to a change of D_{1-X} and a change of D_{0-Y} with respect to a change of D_{1-Y} in the display device of Example 7.

FIG. 37C is a diagram schematically illustrating a change of D_{0-X} with respect to a change of D_{1-X} and a change of D_{0-Y} with respect to a change of D_{1-Y} in the display device of Example 7.

FIG. 37D is a diagram schematically illustrating a change of D_{0-X} with respect to a change of D_{1-X} and a change of D_{0-Y} with respect to a change of D_{1-Y} in the display device of Example 7.

FIG. 38A is a diagram schematically illustrating a change of D_{0-X} with respect to a change of D_{1-X} and a change of D_{0-Y} with respect to a change of D_{1-Y} in the display device of Example 7.

FIG. 38B is a diagram schematically illustrating a change of D_{0-X} with respect to a change of D_{1-X} and a change of D_{0-Y} with respect to a change of D_{1-Y} in the display device of Example 7.

FIG. 38C is a diagram schematically illustrating a change of D_{0-X} with respect to a change of D_{1-X} and a change of D_{0-Y} with respect to a change of D_{1-Y} in the display device of Example 7.

FIG. 38D is a diagram schematically illustrating a change of D_{0-X} with respect to a change of D_{1-X} and a change of D_{0-Y} with respect to a change of D_{1-Y} in the display device of Example 7.

FIG. 39 is a schematic and partial sectional view of a light emitting element and a display device of Example 8.

FIG. 40A is a conceptual diagram for explaining a relationship between a normal line LN₀ passing through the center of a light emitting region, a normal line LN₁ passing through the center of a second optical path control unit, and a normal line LN₂ passing through the center of a wavelength selection unit in a display device of Example 8.

FIG. 40B is a conceptual diagram for explaining a relationship between the normal line LN₀ passing through the center of the light emitting region, the normal line LN₁ passing through the center of the second optical path control unit, and the normal line LN₂ passing through the center of the wavelength selection unit in the display device of Example 8.

FIG. 40C is a conceptual diagram for explaining a relationship between the normal line LN₀ passing through the center of the light emitting region, the normal line LN; passing through the center of the second optical path control unit, and the normal line LN₂ passing through the center of the wavelength selection unit in the display device of Example 8.

FIG. 41 is a conceptual diagram for explaining a relationship between the normal line LN₀ passing through the center of the light emitting region, the normal line LN₁ passing through the center of the second optical path control unit, and the normal line LN₂ passing through the center of the wavelength selection unit in the display device of Example 8.

FIG. 42A is a conceptual diagram for explaining a relationship between the normal line LN₀ passing through the center of the light emitting region, the normal line LN₁ passing through the center of the second optical path control unit, and the normal line LN₂ passing through the center of the wavelength selection unit in the display device of Example 8.

FIG. 42B is a conceptual diagram for explaining a relationship between the normal line LN₀ passing through the center of the light emitting region, the normal line LN; passing through the center of the second optical path control unit, and the normal line LN₂ passing through the center of the wavelength selection unit in the display device of Example 8.

FIG. 43 is a conceptual diagram for explaining a relationship between the normal line LN₀ passing through the center of the light emitting region, the normal line LN₁ passing through the center of the second optical path control unit, and the normal line LN₂ passing through the center of the wavelength selection unit in the display device of Example 8.

FIG. 44A is a front view of a digital still camera illustrating an example in which the display device of the present disclosure is applied to a mirrorless interchangeable lens digital still camera.

FIG. 44B is a back view of the digital still camera illustrating the example in which the display device of the present disclosure is applied to a mirrorless interchangeable lens digital still camera.

FIG. 45 is an external view of a head mounted display illustrating an example in which the display device of the present disclosure is applied to a head mounted display.

FIG. 46A is a schematic plan view of a lens member having a truncated quadrangular pyramid shape.

FIG. 46B is a schematic perspective view of the lens member having a truncated quadrangular pyramid shape.

FIG. 47 is a schematic and partial sectional view of a light emitting element and a display device provided with a light emission direction control member.

### DESCRIPTION OF EMBODIMENTS

Hereinafter, the present disclosure will be described based on Examples with reference to the drawings. The present disclosure is not limited to Examples, and various numerical values and materials in Examples are examples. The description will be given in the following order.

1. Overall description of light emitting element of present disclosure and display device of present disclosure

2. Example 1 (light emitting element of present disclosure and display device of present disclosure)

3. Example 2 (modification of Example 1)

4. Example 3 (another modification of Example 1)

5. Example 4 (modification of Examples 1 to 3)

6. Example 5 (modification of Examples 1 to 4)

7. Example 6 (modification of Examples 1 to 5)

8. Example 7 (modification of Examples 1 to 6)

9. Example 8 (modification of Examples 1 to 7)

10. Others

### Overall Description of Light Emitting Element of Present Disclosure and Display Device of Present Disclosure

In the light emitting element of the present disclosure or the light emitting element constituting the display device of the present disclosure (hereinafter, these light emitting elements may be collectively referred to as “light emitting elements of the present disclosure”), an orthogonal projection image of a first optical path control unit may be included in an orthogonal projection image of a second optical path control unit. In this case, the orthogonal projection image of the first optical path control unit may be located on an outer periphery of the orthogonal projection image of the second optical path control unit, but the location is not limited to the outer periphery, and the orthogonal projection image of the first optical path control unit may be located on the outer periphery and an inner side of the orthogonal projection image of the second optical path control unit. The orthographic projection image is an orthographic projection image with respect to the first substrate. In the description of the light emitting elements of the present disclosure, in principle, a direction away from the light emitting unit is expressed as “upward”, and a direction toward the light emitting unit is expressed as “downward”.

In the light emitting elements of the present disclosure including the above preferred embodiment, a relationship between the first optical path control unit (first lens member) and the second optical path control unit (second lens member) may take

(A) a form in which the first optical path control unit and the second optical path control unit each of which consists of a plano-convex lens having a convex shape in a direction away from the light emitting unit.

That is, the light emission surface of the first optical path control unit (first lens member) may have a convex shape, and the light incident surface may be, for example, flat. The light emission surface of the second optical path control unit (second lens member) may have a convex shape, and the light incident surface may be, for example, flat.

However, the relationship is not limited to these forms but may take
(B) a form in which the first optical path control unit consists of a plano-convex lens having a convex shape in a direction away from the light emitting unit, and the second optical path control unit consists of a plano-convex lens having a convex shape in a direction toward the light emitting unit,
(C) a form in which the first optical path control unit consists of a plano-convex lens having a convex shape in a direction toward the light emitting unit, and the second optical path control unit consists of a plano-convex lens having a convex shape in a direction away from the light emitting unit, or
(D) a form in which the first optical path control unit consists of a plano-convex lens having a convex shape in a direction toward the light emitting unit, and the second optical path control unit consists of a plano-convex lens having a convex shape in a direction toward the light emitting unit.

Similarly, a relationship between the first optical path control unit (first lens member) and a third optical path control unit (third lens member) to be described later may take
(E) a form in which the first optical path control unit and the third optical path control unit each include a plano-convex lens having a convex shape in a direction away from the light emitting unit.

However, the relationship is not limited to this form but may take
(F) a form in which the first optical path control unit is composed of a plano-convex lens having a convex shape in a direction away from the light emitting unit, and the third optical path control unit is composed of a plano-convex lens having a convex shape in a direction toward the light emitting unit,
(G) a form in which the first optical path control unit is composed of a plano-convex lens having a convex shape in a direction toward the light emitting unit, and the third optical path control unit is composed of a plano-convex lens having a convex shape in a direction away from the light emitting unit, or
(H) a form in which the first optical path control unit is composed of a plano-convex lens having a convex shape in a direction toward the light emitting unit, and the third optical path control unit is composed of a plano-convex lens having a convex shape in a direction toward the light emitting unit.

When the refractive index of the material constituting the first optical path control unit is n₁, the refractive index of the material constituting the second optical path control unit is n₂, and the refractive index of the material constituting the third optical path control unit is n₃,

$${n}_{1} > {n}_{2}$$

is preferably satisfied, and

$${n}_{3} > {n}_{1}$$

is preferably satisfied. It is preferable to satisfy, but not limited to,

$${n}_{1} - {n}_{2} \geq 0.2$$

$${n}_{3} - {n}_{1} \geq 0.2 .$$

Alternatively, it is preferable to sequentially lower the refractive index of the materials constituting the optical path control units through which light from the light emitting unit passes or the refractive index of the materials constituting the regions through which light from the light emitting unit passes in the order of passing of light. When the radius of curvature of the first optical path control unit is r₁, the radius of curvature of the second optical path control unit is r₂, and the radius of curvature of the third optical path control unit is r₃, r₂=r₁ may be satisfied, r₂>r₁ may be satisfied, or r₂<r₁ may be satisfied, and r₃=r₁ may be satisfied, r₃>r₁ may be satisfied, or r₃<r₁ may be satisfied.

In the display device of the present disclosure, the size of the planar shape of the second optical path control unit may be changed depending on the light emitting element. For example, when one light emitting element unit (pixel) is composed of three light emitting elements (subpixels), the sizes of the planar shapes of the first optical path control unit, the second optical path control unit, and the third optical path control unit (hereinafter, these optical path control units may be collectively referred to as “optical path control units”) may be the same value in three light emitting elements constituting one light emitting element unit, may be the same value in two light emitting elements except for one light emitting element, or may be different values in three light emitting elements. The refractive index of the materials constituting the optical path control units may be changed depending on the light emitting element. For example, when one light emitting element unit (pixel) is composed of three light emitting elements (subpixels), the refractive indexes of the materials constituting the optical path control units may be the same value in the three light emitting elements, may be the same value in the two light emitting elements except for one light emitting element, or may be different values in the three light emitting elements.

In the light emitting elements of the present disclosure including the various preferable forms and configurations described above, the first lens member, the second lens member, and the third lens member (hereinafter, these may be collectively referred to as “lens members”) constituting the first optical path control unit, the second optical path control unit, and the third optical path control unit may be formed in a hemispherical shape or a part of a sphere, or may be formed in a shape suitable for functioning as lenses in a broad sense. Specifically, as described above, the lens members may include a convex lens member, specifically, a plano-convex lens. The lens members may be spherical lenses or aspherical lenses. The optical path control units may be refractive lenses or diffractive lenses.

The optical path control units may be lens members each having, as a whole, a rounded three-dimensional shape of a rectangular parallelepiped having a square or rectangular bottom surface, in which the four side surfaces and one top surface of the rectangular parallelepiped have convex shapes, ridge parts where the side surfaces intersect each other are rounded, and ridge parts where the top surface intersects the side surfaces are also rounded. The optical path control units may be lens members each having a three-dimensional shape of a rectangular parallelepiped (including a cube approximating a rectangular parallelepiped) having a square or rectangular bottom surface, in which the four side surfaces and one top surface of the rectangular parallelepiped have a planar shape. In this case, ridge parts where the side surfaces intersect each other may be rounded in some case, and ridge parts where the top surface intersects the side surfaces may also be rounded in some cases. The lens members may each include a lens unit having a rectangular or isosceles trapezoidal sectional shape cut along a virtual plane (vertical virtual plane) including its thickness direction. In other words, the lens members may each include a lens member whose sectional shape is constant or changed along the thickness direction.

Alternatively, in the light emitting elements of the present disclosure, the optical path control units may each include a light emission direction control member having a rectangular or isosceles trapezoidal sectional shape cut along a virtual plane (vertical virtual plane) including its thickness direction. In other words, the optical path control units may each include a light emission direction control unit whose sectional shape is constant or changed along the thickness direction.

In the light emitting elements of the present disclosure including the various preferable forms described above, a wavelength selection unit may be provided above the light emitting unit, and the first optical path control unit and the second optical path control unit may be provided on or above the wavelength selection unit. Such a configuration may be referred to as “light emitting element of the first configuration” for convenience.

In the light emitting element of the first configuration, a third optical path control unit may be provided between the wavelength selection unit and the first optical path control unit. Such a configuration may be referred to as “light emitting element of the first-A configuration” for convenience. In the light emitting element of the first-A configuration, one or a plurality of (specifically, four to eight, for example) third optical path control units may be provided for one first optical path control unit.

In the light emitting element of the first configuration, the third optical path control unit may be provided beneath or below the wavelength selection unit. Such a configuration may be referred to as “light emitting element of the first-B configuration” for convenience. In the light emitting element of the first-B configuration, one or a plurality of (specifically, four to eight, for example) third optical path control units may be provided for one first optical path control unit.

In the light emitting elements of the present disclosure including the various preferable forms described above, the wavelength selection unit may be provided between the first optical path control unit and the second optical path control unit. Such a configuration may be referred to as “light emitting element of the second configuration” for convenience. In the light emitting element of the second configuration, the third optical path control unit may be provided beneath or below the first optical path control unit. In this case, one or a plurality of (specifically, four to eight, for example) third optical path control units may be provided for one first optical path control unit.

In the light emitting elements of the present disclosure including the various preferable forms described above, the wavelength selection unit may be provided on or above the second optical path control unit. Such a configuration may be referred to as “light emitting element of the third configuration” for convenience. In the light emitting element of the third configuration, the third optical path control unit may be provided beneath or below the first optical path control unit. In this case, one or a plurality of (specifically, four to eight, for example) third optical path control units may be provided for one first optical path control unit.

The wavelength selection unit is provided above the first substrate. The wavelength selection unit may be provided on the first substrate side or the second substrate side. The size of the wavelength selection unit may be appropriately changed according to light emitted from the light emitting element.

Examples of the wavelength selection unit include a color filter layer. Examples of the color filter layer include a color filter layer that transmits not only red, green, and blue, but also specific wavelengths such as cyan, magenta, and yellow in some cases. The color filter layer is made of a resin (for example, a photocurable resin) to which a colorant including a desired pigment or dye is added, and by selecting a pigment or dye, the light transmittance of the color filter layer is adjusted to be high in a target wavelength region such as red, green, and blue and low in other wavelength regions. Such a color filter layer may be made of a known color resist material. In a light emitting element that emits white light, which will be described later, a transparent filter layer may be disposed. Alternatively, examples of the wavelength selection unit include a photonic crystal, a wavelength selection element to which plasmon is applied (for example, a wavelength selection unit having a conductor grid structure in which a grid-shaped hole structure is provided in a conductor thin film disclosed in JP 2008-177191 A, or a wavelength selection unit based on surface plasmon excitation using a diffraction grating), a wavelength selection unit with a dielectric multilayer film capable of transmitting a specific wavelength by using multiple reflection in a thin film by stacking dielectric thin films, a thin film made of an inorganic material such as thin film amorphous silicon, and a quantum dot. Hereinafter, the color filter layer may be described as a representative of the wavelength selection unit, but the wavelength selection unit is not limited to the color filter layer.

A relationship between the wavelength selection unit and the second optical path control unit may take,
(a) a form in which an orthographic projection image of the second optical path control unit match with an orthographic projection image of the wavelength selection unit,
(b) a form in which the orthographic projection image of the second optical path control unit is included in the orthographic projection image of the wavelength selection unit, or
(c) a form in which the orthogonal projection image of the wavelength selection unit is included in the orthogonal projection image of the second optical path control unit.

That is, the planar shape of the wavelength selection unit may be the same as, similar to, approximate to, or different from the planar shape of the second optical path control unit. Adopting a form in which the orthogonal projection image of the second optical path control unit is included in the orthogonal projection image of the wavelength selection unit can reliably reduce occurrence of color mixture between adjacent light emitting elements.

The planar shape of the wavelength selection unit may be the same as, similar to, approximate to, or different from the planar shape of the light emitting region, but the wavelength selection unit is preferably larger than the light emitting region. The center of the wavelength selection unit (the center when the wavelength selection is orthogonally projected onto the first substrate) may pass through the center of the light emitting region but does not have to pass through the center of the light emitting region. The size of the wavelength selection unit may be appropriately changed according to the distance (offset amount) do (described later) between a normal line passing through the center of the light emitting region and a normal line passing through the center of the wavelength selection unit. The various normal lines are perpendicular to the first substrate.

The center of the wavelength selection unit refers to an area centroid point of a region occupied by the wavelength selection unit. Alternatively, when the planar shape of the wavelength selection unit is a circle, an ellipse, a square (including a square with rounded corners), a rectangle (including a rectangle with rounded corners), or a regular polygon (including a regular polygon with rounded corners), the center of these shapes corresponds to the center of the wavelength selection unit. When the planar shape has a shape in which a part of these shapes is cutout, the center of the shape complementing the cutout part corresponds to the center of the wavelength selection unit. When the planar shape has a shape in which these shapes are connected, the connection part is removed, and the center of the shape complementing the removed part corresponds to the center of the wavelength selection portion. The center of the second optical path control unit refers to an area centroid point of a region occupied by the second optical path control unit. When the planar shape of the second optical path control unit is a circle, an ellipse, a square (including a square with rounded corners), a rectangle (including a rectangle with rounded corners), or a regular polygon (including a regular polygon with rounded corners), the center of these shapes corresponds to the center of the second optical path control unit. The center of the light emitting region refers to an area centroid point of a region where a first electrode and an organic layer (which will be described later) are in contact with each other.

Further, in the light emitting elements of the present disclosure including the preferable forms described above, the light emitting unit may have a sectional shape protruding toward the first substrate, or may have an uneven sectional shape toward the first substrate.

In the light emitting elements of the present disclosure including the various preferable forms and configurations described above, the light emitting unit (organic layer) may include an organic electroluminescence layer. That is, the light emitting elements of the present disclosure including the various preferable forms and configurations described above may be composed of an organic electroluminescence element (organic EL element), and the display device of the present disclosure may be composed of an organic electroluminescence display device (organic EL display device).

The organic EL display device includes:
a first substrate, a second substrate, and
a plurality of light emitting elements located between the first substrate and the second substrate and arranged two-dimensionally;
wherein
each of the light emitting elements provided on a base formed on the first substrate includes the light emitting elements of the present disclosure including the preferable forms and configurations described above,
or
each of the light emitting elements provided on the base formed on the first substrate includes a light emitting unit, and
the light emitting unit includes, at least:
a first electrode;
a second electrode; and
an organic layer (including a light emitting layer consisting of an organic electroluminescence layer) sandwiched between the first electrode and the second electrode,
wherein light from the organic layer is emitted outside via the second substrate. That is, the display device of the present disclosure may be a top emission type display device that emits light from the second substrate.

In the display device of the present disclosure, the first light emitting element may emit red light, the second light emitting element may emit green light, and the third light emitting element may emit blue light. Further, a fourth light emitting element that emits white light or a fourth light emitting element that emits light of a color other than red light, green light, and blue light may be added.

Examples of the array of the pixels (or subpixels) in the display device of the present disclosure include delta array, stripe array, diagonal array, rectangle array, Pentile array, and square array. The array of the wavelength selection units may be in delta array, stripe array, diagonal array, rectangle array, or Pentile array in accordance with the array of the pixels (or subpixels).

That is, the light emitting elements of the present disclosure specifically include a first electrode, an organic layer formed on the first electrode, a second electrode formed on the organic layer, and a protective layer formed on the second electrode. The first optical path control unit is formed on the protective layer or above the protective layer. Then, light from the organic layer is emitted outside via the second electrode, the protective layer, the first optical path control unit, the second optical path control unit, and the second substrate, or in some cases, via the second electrode, the protective layer, the first optical path control unit, a flattening layer, the second optical path control unit, and the second substrate, or when a wavelength selection unit is provided in these optical paths of emitted light, or when an underlayer is provided on an inner surface (surface facing the first substrate) of the second substrate, the light is emitted outside via the wavelength selection unit and the underlayer.

The first electrode is provided for each light emitting element. The organic layer including a light emitting layer made of an organic light emitting material is provided for each light emitting element or is shared by the light emitting elements. The second electrode is shared by the plurality of light emitting elements. That is, the second electrode is a so-called solid electrode and a common electrode. The first substrate is disposed below or beneath the base, and the second substrate is disposed above the second electrode. The light emitting elements are formed on the first substrate side, and the light emitting unit is provided on the base. Specifically, the light emitting unit is provided on the base formed on or above the first substrate. In this manner, the first electrode, the organic layer (including the light emitting layer), and the second electrode constituting the light emitting unit are sequentially formed on the base.

In the light emitting elements of the present disclosure, the first electrode may be in contact with a part of the organic layer, the first electrode may be in contact with the organic layer, or the first electrode may be in contact with the organic layer. In these cases, specifically, the size of the first electrode may be smaller than the size of the organic layer, the size of the first electrode may be the same as the size of the organic layer, or the size of the first electrode may be larger than the size of the organic layer. An insulating layer may be formed in a part between the first electrode and the organic layer. A region where the first electrode and the organic layer are in contact with each other is a light emitting region. The size of the light emitting region is the size of the region where the first electrode and the organic layer are in contact with each other. The size of the light emitting region may be changed according to the color of light to be emitted from the light emitting element.

In the light emitting elements of the present disclosure, the organic layer may have a stacked structure of at least two light emitting layers that emit different colors, and the color of light emitted in the stacked structure may be white light. That is, an organic layer constituting a red light emitting element (first light emitting element), an organic layer constituting a green light emitting element (second light emitting element), and an organic layer constituting a blue light emitting element (third light emitting element) may be configured to emit white light. In this case, the organic layer that emits white light may have a stacked structure of a red light emitting layer that emits red light, a green light emitting layer that emits green light, and a blue light emitting layer that emits blue light. Alternatively, the organic layer that emits white light may have a stacked structure of a blue light emitting layer that emits blue light and a yellow light emitting layer that emits yellow light, or may have a stacked structure of a blue light emitting layer that emits blue light and an orange light emitting layer that emits orange light. Specifically, the organic layer may have a stacked structure in which three layers of a red light emitting layer that emits red light (wavelength: 620 nm to 750 nm), a green light emitting layer that emits green light (wavelength: 495 nm to 570 nm), and a blue light emitting layer that emits blue light (wavelength: 450 nm to 495 nm) are stacked, and the organic layer emits white light as a whole. Such an organic layer (light emitting unit) that emits white light and a wavelength selection unit (or a protective layer or a flattening layer that functions as a red color filter layer) that transmits red light are combined to form a red light emitting element, an organic layer (light emitting unit) that emits white light and a wavelength selection unit (or a protective layer or a flattening layer that functions as a green color filter layer) that transmits green light are combined to form a green light emitting element, and an organic layer (light emitting unit) that emits white light and a wavelength selection unit (or a protective layer or a flattening layer that functions as a blue color filter layer) that transmits blue light are combined to form a blue light emitting element. One pixel (light emitting element unit) is composed of a combination of subpixels such as a red light emitting element, a green light emitting element, and a blue light emitting element. In some cases, one pixel may be composed of a red light emitting element, a green light emitting element, a blue light emitting element, and a light emitting element that emits white light (or a light emitting element that emits complementary color light). In the form composed of at least two light emitting layers that emit different colors, there is a case in which the light emitting layers that emit different colors may be mixed and not clearly separated into the respective layers in practice. The organic layer may be shared by a plurality of light emitting elements or may be individually provided for each light emitting element, as described above.

As described above, the protective layer or the flattening layer having a function as the color filter layer may be made of a known color resist material. In the light emitting element that emits white light, a transparent filter layer may be disposed. With the protective layer also functioning as a color filter layer, the organic layer and the protective layer (color filter layer) are close to each other, and color mixture can be effectively prevented even with a widened angle of light emitted from the light emitting element, and viewing angle characteristics improve.

The organic layer may also be composed of one light emitting layer. In this case, the light emitting element may be composed of, for example, a red light emitting element having an organic layer including a red light emitting layer, a green light emitting element having an organic layer including a green light emitting layer, or a blue light emitting element having an organic layer including a blue light emitting layer. That is, the organic layer constituting the red light emitting element may emit red light, the organic layer constituting the green light emitting element may emit green light, and the organic layer constituting the blue light emitting element may emit blue light. One pixel is composed of these three light emitting elements (subpixels). In the case of a color display device, one pixel is composed of these three light emitting elements (subpixels). In principle, formation of a color filter layer is unnecessary, but a color filter layer may be provided for improving color purity.

When the light emitting element unit (one pixel) includes a plurality of light emitting elements (subpixels), the size of the light emitting region of the light emitting elements may be changed depending on the light emitting elements. Specifically, the size of the light emitting region of the third light emitting element (blue light emitting element) may be larger than the size of the light emitting region of the first light emitting element (red light emitting element) and the size of the light emitting region of the second light emitting element (green light emitting element). This allows the amount of light emission of the blue light emitting element to be larger than the amount of light emission of the red light emitting element and the amount of light emission of the green light emitting element, helps the blue light emitting element, the red light emitting element, and the green light emitting element have appropriate amounts of light emission, and can improve image quality. Alternatively, when a light emitting element unit (one pixel) including a white light emitting element that emits white light in addition to the red light emitting element, the green light emitting element, and the blue light emitting element is assumed, the size of the light emitting region of the green light emitting element or the white light emitting element is preferably larger than the size of the light emitting region of the red light emitting element or the blue light emitting element from the viewpoint of luminance. The size of the light emitting region of the blue light emitting element is preferably larger than the size of the light emitting region of the red light emitting element, green light emitting element, or white light emitting element, from the viewpoint of the life of the light emitting element. However, the sizes of the light emitting regions are not limited to these configurations.

The first optical path control unit, the second optical path control unit, and the third optical path control unit may be made of, for example, a known transparent resin material such as an acrylic resin, and they may be obtained by melt-flowing the transparent resin material, or may be obtained by etching back the transparent material, may be obtained by a combination of a photolithography technique using a gray tone mask or a halftone mask and an etching method based on an organic material or an inorganic material, or may be obtained by a method of forming the transparent resin material into a lens shape based on a nanoimprint method. Examples of the outer shape of the first optical path control unit, the second optical path control unit, and the third optical path control unit include, but are not limited to, a circle, an ellipse, a square, and a rectangle. The size of the first optical path control unit may be, but not limited to, less than 1 μm in terms of a diameter of a circle as the outer shape of the first optical path control unit is assumed to be a circle, for example. That is, when the outer shape of the first optical path control unit is a shape other than a circle, the outer shape is deformed into a circle, and the diameter of the circle may be, but not limited to, less than 1 μm, for example.

The first substrate and the second substrate are bonded by a bonding member. Examples of the material constituting the bonding member include thermosetting adhesives such as an acrylic adhesive, an epoxy adhesive, a urethane adhesive, a silicone adhesive, and a cyanoacrylate adhesive, and ultraviolet curable adhesives.

Examples of the material constituting the protective layer or the flattening layer include an acrylic resin, an epoxy resin, and various inorganic materials [for example, SiO₂, SiN, SiON, SiC, amorphous silicon (α-Si), Al₂O₃, and TiO₂]. The protective layer or the flattening layer may have a single layer configuration or may be formed of a plurality of layers. In the latter case, in the light emitting elements of the present disclosure, it is preferable to sequentially reduce the value of the refractive index of the material constituting the protective layer or the flattening layer from the light incident direction toward the light emission direction. The protective layer or the flattening layer may be formed by a known method such as various CVD methods, various coating methods, various PVD methods including a sputtering method and a vacuum vapor deposition method, and various printing methods such as a screen printing method. Further, as a method for forming the protective layer, an atomic layer deposition (ALD) method may also be adopted. The protective layer or the flattening layer may be shared by a plurality of light emitting elements, or may be individually provided for each light emitting element.

The first substrate or the second substrate may be formed of a silicon semiconductor substrate, a high strain point glass substrate, a soda glass (Na₂O·CaO·SiO₂) substrate, a borosilicate glass (Na₂O·B₂O₃·SiO₂) substrate, a forsterite (2MgO·SiO₂) substrate, a lead glass (Na₂O·PbO·SiO₂) substrate, various glass substrates having an insulating material layer formed on the surface thereof, a quartz substrate, a quartz substrate having an insulating material layer formed on the surface thereof, or an organic polymer (having a form of a polymer material such as a flexible plastic film, a plastic sheet, or a plastic substrate made of a polymer material) exemplified by polymethyl methacrylate (PMMA), polyvinyl alcohol (PVA), polyvinylphenol (PVP), polyethersulfone (PES), polyimide, polycarbonate, polyethylene terephthalate (PET), and polyethylene naphthalate (PEN). The materials constituting the first substrate and the second substrate may be the same or different. Since the display device of the present disclosure is a top emission type display device, the second substrate is required to be transparent to light from the light emitting element.

When the first electrode functions as an anode electrode, examples of the material constituting the first electrode include a metal having a high work function such as platinum (Pt), gold (Au), silver (Ag), chromium (Cr), tungsten (W), nickel (Ni), copper (Cu), iron (Fe), cobalt (Co), or tantalum (Ta), and an alloy (for example, an Ag—Pd—Cu alloy containing silver as a main component and containing 0.3 mass % to 1 mass % of palladium (Pd) and 0.3 mass % to 1 mass % of copper (Cu), an Al—Nd alloy, an Al—Cu alloy, or an Al—Cu—Ni alloy). When a conductive material having a small work function value and a high light reflectance, such as aluminum (Al) and an alloy containing aluminum, is used, the conductive material may be used as an anode electrode by improving hole injection characteristics by providing an appropriate hole injection layer or the like. The thickness of the first electrode may be 0.1 μm to 1 μm, for example. When a light reflection layer constituting a resonator structure to be described later is provided, the first electrode is required to be transparent to light from the light emitting element. Thus, examples of the material constituting the first electrode include various transparent conductive materials such as transparent conductive materials containing, as a base layer, indium oxide, indium-tin oxide (ITO, including Sn-doped In₂O₃, crystalline ITO, and amorphous ITO), indium-zinc oxide (IZO), indium-gallium oxide (IGO), indium-doped gallium-zinc oxide (IGZO, In—GaZnO₄), IFO (F-doped In₂O₃), ITiO (Ti-doped In₂O₃), InSn, InSnZnO, tin oxide (SnO₂), ATO (Sb-doped SnO₂), FTO (F-doped SnO₂), zinc oxide (ZnO), aluminum oxide-doped zinc oxide (AZO), gallium-doped zinc oxide (GZO), B-doped ZnO, AlMgZnO (aluminum oxide and magnesium oxide-doped zinc oxide), antimony oxide, titanium oxide, NiO, spinel-type oxide, oxide having a YbFe₂O₄ structure, gallium oxide, titanium oxide, niobium oxide, nickel oxide, or the like. The first electrode may also have a structure in which a transparent conductive material having excellent hole injection characteristics, such as an oxide of indium and tin (ITO) or an oxide of indium and zinc (IZO), is stacked on a dielectric multilayer film or a reflective film having high light reflectivity, such as aluminum (Al) or an alloy thereof (for example, Al—Cu—Ni alloy). When the first electrode functions as a cathode electrode, the first electrode is desirably made of a conductive material having a small work function value and a high light reflectance. The first electrode may also be used as a cathode electrode by improving electron injection characteristics by providing an appropriate electron injection layer in a conductive material having a high light reflectance used as an anode electrode.

When the second electrode functions as a cathode electrode, the material (semi-light transmitting material or light transmitting material) constituting the second electrode is desirably made of a conductive material having a small work function value so as to transmit emission light and to efficiently inject electrons into the organic layer (light emitting layer). Examples thereof include a metal having a small work function, such as aluminum (Al), silver (Ag), magnesium (Mg), calcium (Ca), sodium (Na), strontium (Sr), and an alloy of an alkali metal or an alkaline earth metal and silver (Ag) such as magnesium (Mg) and silver (Ag) (Mg—Ag alloy), an alloy of magnesium and calcium (Mg—Ca alloy), or an alloy of aluminum (Al) and lithium (Li) (Al—Li alloy). Of these, a Mg—Ag alloy is preferable, and the volume ratio between magnesium and silver may be, for example, Mg:Ag=5:1 to 30:1. The volume ratio between magnesium and calcium may be, for example, Mg:Ca=2:1 to 10:1. The thickness of the second electrode may be, for example, 4 nm to 50 nm, preferably 4 nm to 20 nm, more preferably 6 nm to 12 nm. Examples of the material of the second electrode also include at least one material selected from the group consisting of Ag—Nd—Cu, Ag—Cu, Au, and Al—Cu. The second electrode may also have a stacked structure of the above-described material layer and a so-called transparent electrode (for example, having a thickness of 3×10⁻⁸ m to 1×10⁻⁶ m) made of, for example, ITO or IZO from the organic layer side. A bus electrode (auxiliary electrode) made of a low-resistance material such as aluminum, an aluminum alloy, silver, a silver alloy, copper, a copper alloy, gold, or a gold alloy may be provided to the second electrode to reduce the resistance of the second electrode as a whole. The average light transmittance of the second electrode is desirably 50% to 90%, and preferably 60% to 90%. When the second electrode functions as an anode electrode, the second electrode is desirably composed of a conductive material that transmits emitted light and has a large work function value.

Examples of a method for forming the first electrode and the second electrode include: vapor deposition methods including an electron beam vapor deposition method, a hot filament vapor deposition method, and a vacuum vapor deposition method; sputtering methods; chemical vapor deposition methods (CVD methods); MOCVD methods; and a combination of an ion plating method and an etching method; various printing methods such as a screen printing method, an inkjet printing method, and a metal mask printing method; plating methods such as electroplating method and electroless plating method; lift-off methods; laser ablation methods; and sol-gel methods. With various printing methods and plating methods, it is possible to directly form the first electrode and the second electrode having a desired shape (pattern). When the second electrode is formed after the organic layer is formed, it is particularly preferable to form the second electrode based on a film forming method in which the energy of film-forming particles is small such as a vacuum vapor deposition method or a film forming method such as an MOCVD method from the viewpoint of preventing occurrence of damage to the organic layer. When the organic layer is damaged, there is a possibility that a non-light emitting pixel (or a non-light emitting subpixel) called a “dot” occurs because of generation of a leakage current.

The organic layer includes a light emitting layer containing an organic light emitting material, as described above. Specifically, the organic layer may have, for example, a stacked structure of a hole transport layer, a light emitting layer, and an electron transport layer, a stacked structure of a hole transport layer and a light emitting layer also serving as an electron transport layer, and a stacked structure of a hole injection layer, a hole transport layer, a light emitting layer, an electron transport layer, and an electron injection layer. Examples of a method for forming the organic layer include: a physical vapor deposition method (PVD method) such as a vacuum vapor deposition method; a printing method such as a screen printing method or an inkjet printing method; a laser transfer method in which a stacked structure of a laser absorption layer and an organic layer formed on a transfer substrate is irradiated with a laser to separate the organic layer on the laser absorption layer and transfer the organic layer; and various coating methods. When the organic layer is formed based on a vacuum vapor deposition method, the organic layer may be obtained by using a so-called metal mask and depositing a material that has passed through an opening provided in the metal mask, for example.

In the light emitting element or the display device of the present disclosure, a base, an insulating layer, an interlayer insulating layer, and an interlayer insulating material layer (described later) are formed. Examples of the insulating material constituting them include: SiOₓ-based materials (materials constituting a silicon-based oxide film) such as SiO₂, non-doped silicate glass (NSG), boron-phosphorus silicate glass (BPSG), PSG, BSG, AsSG, SbSG, PbSG, spin-on glass (SOG), low temperature oxide (LTO), low temperature CVD-SiO₂, low-melting-point glass, and glass paste; SiN-based materials including SiON-based materials; SiOC; SiOF; and SiCN. Examples of the material also include inorganic insulating materials such as titanium oxide (TiO₂), tantalum oxide (Ta₂O₅), aluminum oxide (Al₂O₃), magnesium oxide (MgO), chromium oxide (CrOₓ), zirconium oxide (ZrO₂), niobium oxide (Nb₂O₅), tin oxide (SnO₂), and vanadium oxide (VOₓ). Examples of the material also include various resins such as a polyimide resin, an epoxy resin, and an acrylic resin, and low dielectric constant insulating materials such as SiOCH, organic SOG, and a fluorine-based resin (for example, a material having a dielectric constant k (=ε/ε₀) of, for example, 3.5 or less, and specific examples thereof include fluorocarbon, a cycloperfluorocarbon polymer, benzocyclobutene, a cyclic fluorine-based resin, polytetrafluoroethylene, amorphous tetrafluoroethylene, polyaryl ether, fluorinated aryl ether, fluorinated polyimide, amorphous carbon, parylene (polyparaxylylene), and fluorinated fullerene), Silk (coating-type low-dielectric-constant interlayer insulating film material, a trademark of The Dow Chemical Company), and Flare (polyallyl ether (PAE)-based material, a trademark of Honeywell Electronic Materials Co.). These materials may be used alone or in appropriate combination. The insulating layer, the interlayer insulating layer, the interlayer insulating material layer, and the base may have a single layer structure or a stacked structure. The insulating layer, the interlayer insulating layer, the interlayer insulating material layer, and the base may be formed based on known methods such as various CVD methods, various coating methods, various PVD methods including a sputtering method and a vacuum vapor deposition method, various printing methods such as a screen printing method, plating methods, electrodeposition methods, immersion methods, and sol-gel methods.

On the outermost surface (specifically, the outer surface of the second substrate) of the display device from which light is emitted, an ultraviolet absorbing layer, a contamination preventing layer, a hard coat layer, and an antistatic layer may be formed, or a protective member (for example, cover glass) may be disposed.

Although not limited, a light emitting element drive unit is provided beneath or below the base. The light emitting element drive unit includes, for example, a transistor (specifically, for example, a MOSFET) formed on a silicon semiconductor substrate constituting the first substrate, or a thin film transistor (TFT) provided on various substrates constituting the first substrate. The transistor or the TFT constituting the light emitting element drive unit may be connected to the first electrode via a contact hole (contact plug) formed in the base. The light emitting element drive unit may have a known circuit configuration. The second electrode may be connected to the light emitting element drive unit via a contact hole (contact plug) formed in the base in the outer periphery (specifically, the outer periphery of the pixel array unit) of the display device, for example.

The organic EL display device preferably includes a resonator structure to further improve the light extraction efficiency. The resonator structure will be described in detail later.

In the organic EL display device, it is desirable that the thickness of the hole transport layer (hole supply layer) and the thickness of the electron transport layer (electron supply layer) are substantially equal. Alternatively, the electron transport layer (electron supply layer) may be thicker than the hole transport layer (hole supply layer), which makes it possible to sufficiently supply electrons necessary for high efficiency at a low drive voltage to the light emitting layer. That is, supply of holes can be increased by disposing the hole transport layer between the first electrode corresponding to the anode electrode and the light emitting layer, the hole transport layer having a film thickness smaller than the electron transport layer. As a result, it is possible to obtain a carrier balance in which there is no excess or deficiency of holes and electrons and the carrier supply amount is sufficiently large, resulting in a high luminous efficiency. In addition, since there is no excess or deficiency of holes and electrons, carrier balance is hardly lost, drive deterioration is inhibited, and a light emission lifetime can be extended.

Further, in the light emitting elements of the present disclosure including the preferable forms and configurations described above, a light absorbing layer (black matrix layer) may be formed between the wavelength selection unit and the wavelength selection unit, may be formed on or above, or beneath or below the wavelength selection units, or may be formed between the second optical path control unit and the second optical path control unit. These forms can reliably reduce occurrence of color mixture between adjacent light emitting elements. The light absorbing layer (black matrix layer) is composed of, for example, a black resin film (specifically, for example, a black polyimide resin) mixed with a black colorant and having an optical density of 1 or more, or includes a thin film filter using interference of a thin film. The thin film filter is formed by, for example, stacking two or more thin films made of metal, metal nitride, or metal oxide, and it attenuates light using interference of the thin films. Specific examples of the thin film filter include a thin film filter in which Cr and chromium (III) oxide (Cr₂O₃) are alternately stacked. The size of the light absorbing layer (black matrix layer) may be appropriately changed according to the light emitted from the light emitting element.

A light shielding unit may be provided between light emitting elements. Specific examples of the light shielding material constituting the light shielding unit include materials capable of shielding light, such as titanium (Ti), chromium (Cr), tungsten (W), tantalum (Ta), aluminum (Al), and MoSi₂. The light shielding unit may be formed by vapor deposition methods including an electron beam vapor deposition method, a hot filament vapor deposition methods, and a vacuum vapor deposition method, sputtering methods, CVD methods, ion plating methods, and the like.

The display device of the present disclosure may be used as, for example, a monitor device constituting a personal computer, or may be used as a television receiver, a mobile phone, a personal digital assistant (PDA), a monitor device incorporated in a game device, or a display device incorporated in a projector. The display device may also be applied to an electronic viewfinder (EVF), a head mounted display (HMD), an eyewear, AR glasses, or EVR, or may be applied to a display device for virtual reality (VR), mixed reality (MR), or augmented reality (AR). It is also possible to configure an image display device in an electronic book, an electronic paper such as an electronic newspaper, a bulletin board such as a signboard, a poster, or a blackboard, a rewritable paper as a substitute for printer paper, a display unit of a home appliance, a card display unit such as a loyalty card, an electronic advertisement, or an electronic POP advertisement. Various lighting devices including a backlight device for a liquid crystal display device and a planar light source device can be configured by using the display device of the present disclosure as a light emitting device.

### Example 1

Example 1 relates to the light emitting element of the present disclosure and the display device of the present disclosure, and specifically relates to the light emitting element of the first configuration. In Example 1 or Examples 2 to 8 described later, the display device includes an organic electroluminescence display device (organic EL display device) and is an active matrix display device. The light emitting element includes an electroluminescent element (organic EL element), and the light emitting layer includes an organic electroluminescent layer. The display device of Example 1 or Examples 2 to 8 described later is a top emission type display device that emits light from the second substrate. In the light emitting element and display device of Example 1 or Examples 2 to 8 (except for Example 4) described later, the color filter layer serving as the wavelength selection unit is provided on the first substrate side. In the light emitting element and display device of Example 4 described later, the color filter layer serving as the wavelength selection unit is provided on the second substrate side.

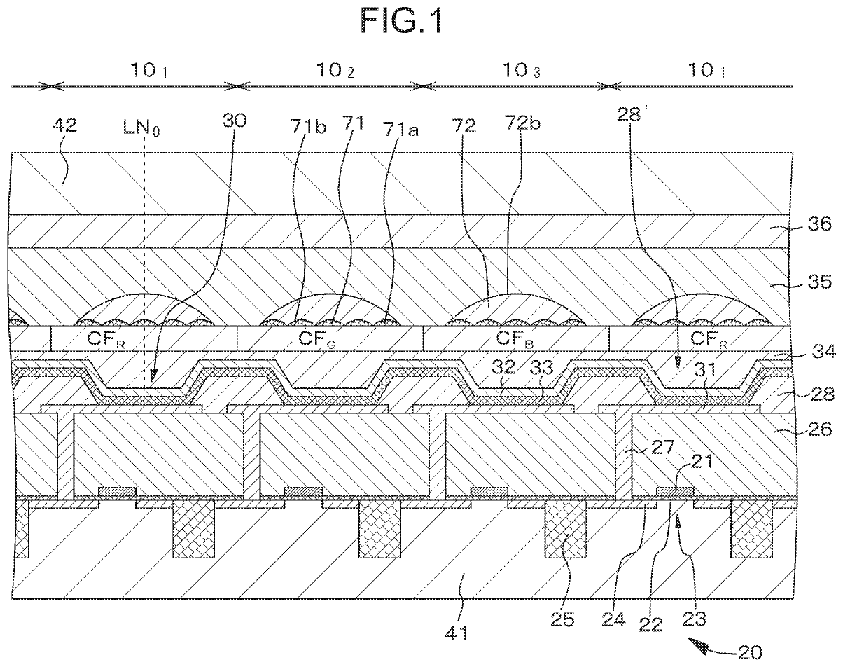

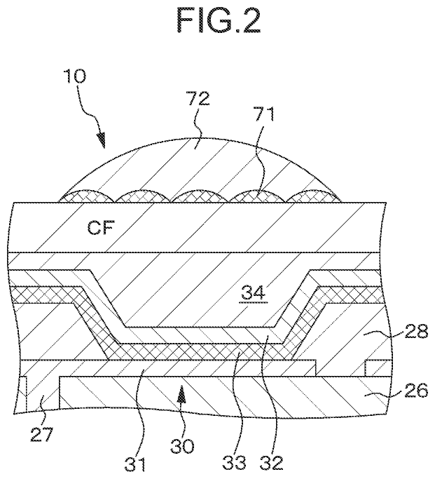

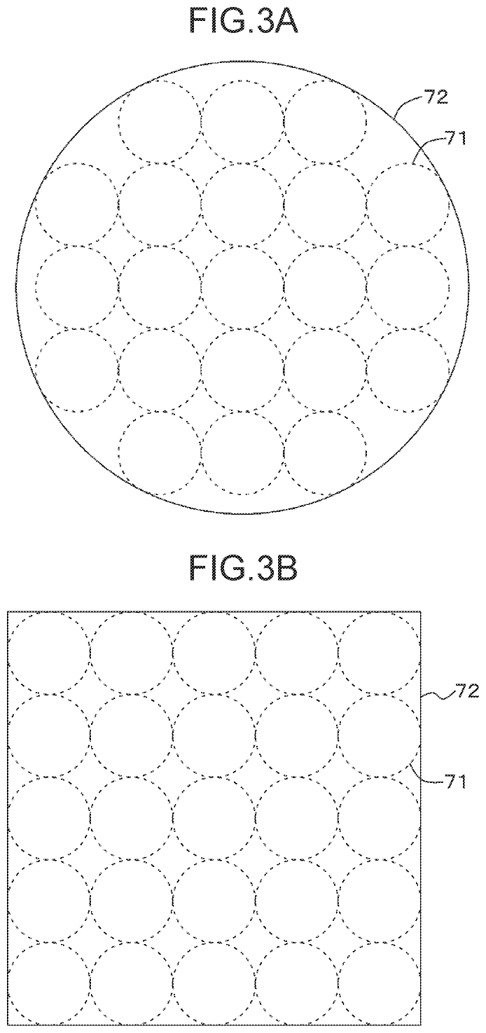

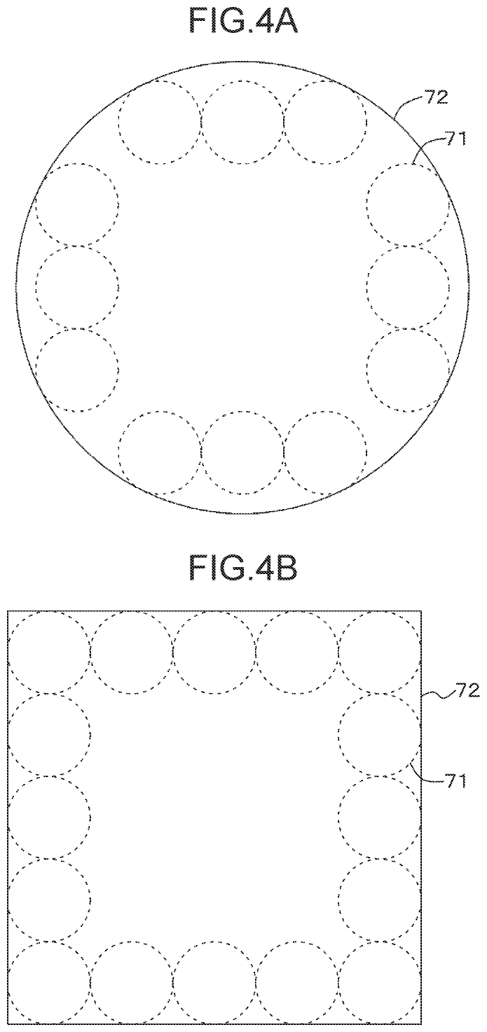

As FIG. 1 illustrates a schematic and partial sectional view, FIG. 2 illustrates an enlarged view of a part of the light emitting element, and FIG. 3A, FIG. 3B, FIG. 4A, or FIG. 4B illustrates a schematic arrangement relationship between the first optical path control unit and the second optical path control unit, a light emitting element 10 of Example 1 includes:
a light emitting unit 30 including one light emitting region;
a first optical path control unit group consisting of a plurality of first optical path control units 71 formed above the light emitting unit 30; and
a second optical path control unit 72 formed on or above the first optical path control unit group (specifically, in Example 1, on the first optical path control unit group),
wherein
the first optical path control units 71 and the second optical path control unit 72 have positive optical power, and
light emitted from the light emitting unit 30 and focused by the first optical path control units 71 is further focused by the second optical path control unit 72.

A display device of Example 1 includes:
a first substrate 41 and a second substrate 42; and
a plurality of light emitting element units including a plurality of types of light emitting elements 10,
wherein
each light emitting element 10 consists of the light emitting element of Example 1, that is,
each light emitting element 10 includes:
a light emitting unit 30 provided above the first substrate 41 and including one light emitting region,
a first optical path control unit group consisting of a plurality of first optical path control units 71 formed above the light emitting unit 30; and
a second optical path control unit 72 formed on or above the first optical path control unit group,
wherein
the first optical path control units 71 and the second optical path control unit 72 have positive optical power, and
light emitted from the light emitting unit 30 and focused by the first optical path control units 71 is further focused by the second optical path control unit 72.

An orthographic projection image of the first optical path control unit 71 is included in an orthographic projection image of the second optical path control unit 72. As FIGS. 3A and 3B schematically illustrate the arrangement relationship between the first optical path control unit 71 and the second optical path control unit 72, the orthogonal projection image of the first optical path control unit 71 is located on the outer periphery and the inner side of the orthogonal projection image of the second optical path control unit 72. Alternatively, as FIGS. 4A and 4B schematically illustrate the arrangement relationship between the first optical path control unit 71 and the second optical path control unit 72, the orthogonal projection image of the first optical path control unit 71 is located on the outer periphery of the orthogonal projection image of the second optical path control unit 72. In the example illustrated in FIGS. 3A and 4A, the planar shape of the first optical path control unit 71 and the second optical path control unit 72 is circular, and in the example illustrated in FIGS. 3B and 4B, the planar shape of the first optical path control unit 71 and the second optical path control unit 72 is square. In FIGS. 3A, 3B, 4A, and 4B, the solid line indicates the second optical path control unit 72, and the dotted line indicates the first optical path control unit 71.

The first optical path control unit 71 and the second optical path control unit 72 each of which consists of a plano-convex lens having a convex shape in a direction away from the light emitting unit 30. That is, a light emission surface 71b of the first optical path control unit 71 (first lens member) has a convex shape, and a light incident surface 71a is flat. A light emission surface 72b of the second optical path control unit 72 (second lens member) has a convex shape. The second optical path control unit 72 covers the first optical path control unit 71, but the light incident surface of the second optical path control unit 72 is flat when it is assumed that the first optical path control unit 71 is removed. The first optical path control unit 71 and the second optical path control unit 72 are formed of a part of a sphere.

Further, a wavelength selection unit (specifically, a color filter layer) CF is provided above the light emitting unit 30, and the first optical path control unit 71 and the second optical path control unit 72 are provided over or above (over in the illustrated example) the wavelength selection unit CF. That is, the light emitted from the light emitting unit 30 passes through the wavelength selection unit CF, the first optical path control unit 71, and the second optical path control unit 72 in this order. Specifically, the wavelength selection unit CF includes color filter layers CF_{R}, CF_{G}, and CF₃, and is provided on the first substrate side. In this manner, the color filter layer CF has an on-chip color filter layer structure (OCCF structure). This can shorten the distance between an organic layer 33 and the wavelength selection unit CF and can reduce occurrence of color mixture caused by light emitted from the organic layer 33 entering an adjacent wavelength selection unit CF of another color. The center of the wavelength selection unit (color filter layer) CF passes through the center of the light emitting region.

Here, the first optical path control unit 71 and the second optical path control unit 72 are made of an acrylic resin. When the refractive index of the material constituting the wavelength selection unit CF that is a foundation of the first optical path control unit 71 and the second optical path control unit 72 is n₀,

$${n}_{0} \geq {n}_{1} > {n}_{2}$$

is satisfied. Specifically,

$${n}_{0} = 1.7$$

$${n}_{1} = 1.65$$

$${n}_{2} = 1.6$$

are satisfied. Further, a bonding member 35 is made of an acrylic adhesive having a refractive index n₀′=1.35. The acrylic resin constituting the first optical path control unit 71, the acrylic resin constituting the second optical path control unit 72, and the acrylic adhesive constituting the bonding member 35 are different from each other. The second optical path control unit 72 and the wavelength selection unit CF are bonded to the second substrate 42 (specifically, an underlayer 36 formed on the inner surface of the second substrate 42) by the bonding member 35.

In the display device of Example 1 or Examples 2 to 8 described later, one light emitting element unit (pixel) is composed of three light emitting elements (three subpixels) of a first light emitting element (red light emitting element) 10₁, a second light emitting element (green light emitting element) 10₂, and a third light emitting element (blue light emitting element) 103. The organic layer 33 constituting the first light emitting element 10₁, the organic layer 33 constituting the second light emitting element 10₂, and the organic layer 33 constituting the third light emitting element 103 emit white light as a whole. That is, the first light emitting element 10; that emits red light is formed of a combination of the organic layer 33 that emits white light and the red color filter layer CF_{R}. The second light emitting element 10₂ that emits green light is formed of a combination of the organic layer 33 that emits white light and the green color filter layer CFs. The third light emitting element 10₃ that emits blue light is formed of a combination of the organic layer 33 that emits white light and the blue color filter layer CF_{B}. In some cases, in addition to the first light emitting element (red light emitting element) 10₁, the second light emitting element (green light emitting element) 10₂, and the third light emitting element (blue light emitting element) 10₃, a light emitting element (or a light emitting element that emits complementary color light) 10₄ that emits white color (or fourth color) may constitute the light emitting element unit (one pixel). The first light emitting element 10₁, the second light emitting element 10₂, and the third light emitting element 10; have substantially the same configuration and structure except for the configuration of the color filter layer, and in some cases, except for the arrangement position of the light emitting layer in the thickness direction of the organic layer. The number of pixels is, for example, 1920×1080, one light emitting element (display element) 10 constitutes one subpixel, and the number of light emitting elements (specifically, organic EL elements) 10 is three times the number of pixels.

In the display device of Example 1 or Examples 2 to 8 described later, the light emitting element specifically includes:
a first electrode 31;
an organic layer 33 formed on the first electrode 31;
a second electrode 32 formed on the organic layer 33;
a protective layer (flattening layer) 34 formed on the second electrode 32; and
a color filter layer CF (CF_{R}, CF_{G}, CF_{B}) formed on (or above) the protective layer 34.

In Example 1, the light emitting element 10 is formed on the first substrate side. That is, the color filter layer CF is disposed above the second electrode 32, and the second substrate 42 is disposed above the color filter layer CF. The following description may be appropriately applied to Examples 2 to 8 described later in principle, except for the arrangement of the color filter layer CF.

Then, light from the organic layer 33 is emitted outside via the second electrode 32, the protective layer 34, the color filter layer CF, the first optical path control unit 71, the second optical path control unit 72, the bonding member 35, the underlayer 36, and the second substrate 42.

A light emitting element drive unit (drive circuit) is provided below a base 26 made of an insulating material formed on the basis of a CVD method. The light emitting element drive unit may have a known circuit configuration. The light emitting element drive unit is composed of a transistor (specifically, a MOSFET) formed on a silicon semiconductor substrate corresponding to the first substrate 41. A transistor 20 composed of a MOSFET includes a gate insulating layer 22 formed on the first substrate 41, a gate electrode 21 formed on the gate insulating layer 22, a source/drain regions 24 formed on the first substrate 41, a channel formation region 23 formed between the source/drain regions 24, and an element isolation region 25 surrounding the channel formation region 23 and the source/drain region 24. The transistor 20 and the first electrode 31 are electrically connected via a contact plug 27 provided in the base 26. In the drawings, one transistor 20 is illustrated for one light emitting element drive unit. Examples of the material constituting the base 26 include SiO₂, SiN, and SiON.

The light emitting unit 30 is provided on the base 26. Specifically, the first electrode 31 of each light emitting element 10 is provided on the base 26. An insulating layer 28 having an opening 28′ in which the first electrode 31 is exposed at the bottom is formed on the base 26, and the organic layer 33 is formed at least on the first electrode 31 exposed at the bottom of the opening 28′. Specifically, the organic layer 33 is formed from the top of the first electrode 31 exposed at the bottom of the opening 28′ to the top of the insulating layer 28, and the insulating layer 28 is formed from the first electrode 31 to the top of the base 26. The part of the organic layer 33 that actually emits light is surrounded by the insulating layer 28. That is, the light emitting region includes the first electrode 31 and a region of the organic layer 33 formed on the first electrode 31, and is provided on the base 26. In other words, the region of the organic layer 33 surrounded by the insulating layer 28 corresponds to the light emitting region. The insulating layer 28 and the second electrode 32 are covered with the protective layer 34 made of SiN. The wavelength selection unit CF (color filter layers CF_{R}, CF_{G}, CF_{B}) made of a known material is formed on the protective layer 34 by a known method, and the wavelength selection unit CF is formed on the protective layer 34.

The first electrode 31 functions as an anode electrode, and the second electrode 32 functions as a cathode electrode. The first electrode 31 is formed of a light reflection material layer, specifically, for example, an Al—Nd alloy layer, an Al—Cu alloy layer, or a stacked structure of an Al—Ti alloy layer and an ITO layer, and the second electrode 32 is made of a transparent conductive material such as ITO. The first electrode 31 is formed on the base 26 based on a combination of a vacuum vapor deposition method and an etching method. The second electrode 32 is formed by a film forming method in which the energy of film-forming particles is small, such as a vacuum vapor deposition method, and is not patterned. That is, the second electrode 32 is a common electrode for the plurality of light emitting elements 10, and is a so-called solid electrode. The second electrode 32 is connected to the light emitting element drive unit via a contact hole (contact plug) not illustrated formed in the base 26 at the outer periphery (specifically, the outer periphery of the pixel array unit) of the display device. In the outer periphery of the display device, an auxiliary electrode connected to the second electrode 32 may be provided below the second electrode 32, and the auxiliary electrode may be connected to the light emitting element drive unit. The organic layer 33 is not patterned either. That is, the organic layer 33 is shared by the plurality of light emitting elements 10. However, the organic layer 33 is not limited to this configuration, and the organic layer 33 may be provided independently for each light emitting element 10. The first substrate 41 is composed of a silicon semiconductor substrate, and the second substrate 42 is composed of a glass substrate.

In Example 1, the organic layer 33 has a stacked structure of a hole injection layer (HIL), a hole transport layer (HTL), a light emitting layer, an electron transport layer (ETL), and an electron injection layer (EIL). The light emitting layer includes at least two light emitting layers that emit different colors, and the light emitted from the organic layer 33 is white light. Specifically, the organic layer has a structure in which three layers of a red light emitting layer that emits red light, a green light emitting layer that emits green light, and a blue light emitting layer that emits blue light are stacked. The organic layer may have a structure in which two layers of a blue light emitting layer that emits blue light and a yellow light emitting layer that emits yellow light are stacked (emitting white light as a whole), or a structure in which two layers of a blue light emitting layer that emits blue light and an orange light emitting layer that emits orange light are stacked (emitting white light as a whole). As described above, the first light emitting element 10₁ to display red is provided with the red color filter layer CF_{R}, the second light emitting element 10₂ to display green is provided with the green color filter layer CF_{G}, and the third light emitting element 10₃ to display blue is provided with the blue color filter layer CF_{B}.

The hole injection layer is a layer that improves hole injection efficiency and functions as a buffer layer that prevents leakage. The hole injection layer has a thickness of, for example, about 2 nm to 10 nm. The hole injection layer includes, for example, a hexaazatriphenylene derivative represented by the following Formula (A) or Formula (B). When an end surface of the hole injection layer contacts the second electrode, it becomes a main cause of occurrence of luminance variation between pixels, leading to deterioration of display image quality.

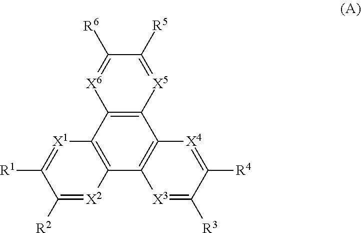

Here, R¹ to R⁶ are each independently a substituent selected from hydrogen, halogen, a hydroxy group, an amino group, an arylamino group, a substituted or unsubstituted carbonyl group having 20 or less carbon atoms, a substituted or unsubstituted carbonyl ester group having 20 or less carbon atoms, a substituted or unsubstituted alkyl group having 20 or less carbon atoms, a substituted or unsubstituted alkenyl group having 20 or less carbon atoms, a substituted or unsubstituted alkoxy group having 20 or less carbon atoms, a substituted or unsubstituted aryl group having 30 or less carbon atoms, a substituted or unsubstituted heterocyclic group having 30 or less carbon atoms, a nitrile group, a cyano group, a nitro group, or a silyl group, and adjacent R^{m} (m=1 to 6) may be bonded to each other via a cyclic structure. XI to X⁶ are each independently a carbon atom or a nitrogen atom.

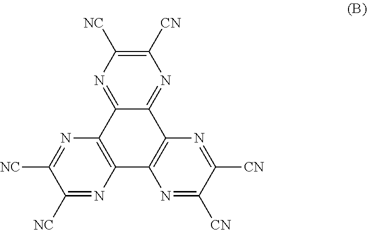 [SMILES: N#Cc1nc2c3nc(C#N)c(C#N)nc3c3nc(C#N)c(C#N)nc3c2nc1C#N]

The hole transport layer is a layer that improves hole transport efficiency to the light emitting layer. In the light emitting layer, application of an electric field causes electrons and holes to recombine and generate light. The electron transport layer is a layer that improves electron transport efficiency to the light emitting layer, and the electron injection layer is a layer that improves electron injection efficiency to the light emitting layer.

The hole transport layer is made of, for example, 4,4′,4″-tris(3-methylphenylphenylamino)triphenylamine (m-MTDATA) or α-naphthylphenyldiamine (αNPD) with a thickness of about 40 nm.

The light emitting layer is a light emitting layer that generates white light through color mixture, and is formed by, for example, stacking a red light emitting layer, a green light emitting layer, and a blue light emitting layer, as described above.

In the red light emitting layer, application of an electric field causes some of the holes injected from the first electrode 31 and some of the electrons injected from the second electrode 32 to recombine and generate red light. Such a red light emitting layer contains, for example, at least one material among a red light emitting material, a hole transporting material, an electron transporting material, and a both charge transporting material. The red light emitting material may be a fluorescent material or a phosphorescent material. The red light emitting layer having a thickness of about 5 nm is made of a material formed by mixing 30 mass % of 2,6-bis [(4′-methoxydiphenylamino) styryl]-1,5-dicyanonaphthalene (BSN) with 4,4-bis(2,2-diphenylvinin) biphenyl (DPVBi), for example.

In the green light emitting layer, application of an electric field causes some of the holes injected from the first electrode 31 and some of the electrons injected from the second electrode 32 to recombine and generate green light. Such a green light emitting layer contains, for example, at least one material among a green light emitting material, a hole transporting material, an electron transporting material, and a both charge transporting material. The green light emitting material may be a fluorescent material or a phosphorescent material. The green light emitting layer having a thickness of about 10 nm is made of a material formed by mixing 5 mass % of coumarin 6 with DPVBi, for example.

In the blue light emitting layer, application of an electric field causes some of the holes injected from the first electrode 31 and some of the electrons injected from the second electrode 32 to recombine and generate blue light. Such a blue light emitting layer contains, for example, at least one material among a blue light emitting material, a hole transporting material, an electron transporting material, and a both charge transporting material. The blue light emitting material may be a fluorescent material or a phosphorescent material. The blue light emitting layer having a thickness of about 30 nm is made of a material formed by mixing 2.5 mass % of 4,4′-bis [2-{4-(N, N-diphenylamino)phenyl}vinyl]biphenyl (DPAVBi) with DPVBi, for example.

The electron transport layer having a thickness of about 20 nm is made of, for example, 8-hydroxyquinoline aluminum (Alq3). The electron injection layer having a thickness of about 0.3 nm is made of, for example, LiF or Li₂O.

The materials constituting each layer are merely examples and are not limited to these materials. The light emitting layer may be composed of a blue light emitting layer and a yellow light emitting layer, or may be composed of a blue light emitting layer and an orange light emitting layer, for example.

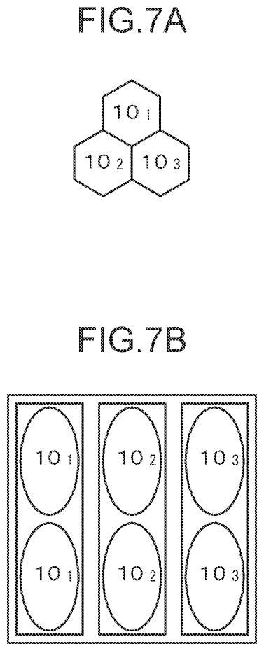

In the display device of Example 1, the array of the subpixels may be a delta array as illustrated in FIG. 7A, a stripe array as illustrated in FIG. 7B, a diagonal array as illustrated in FIG. 7C, or a rectangle array. In some cases, as illustrated in FIG. 7D, one pixel may be composed of the first light emitting element 10₁, the second light emitting element 10₂, the third light emitting element 10₃, and a fourth light emitting element 10₄ that emits white light (or the fourth light emitting element that emits complementary color light). In the fourth light emitting element 10₄ that emits white light, a transparent filter layer may be provided instead of providing the color filter layer. A square array as illustrated in FIG. 7E may also be employed. The example illustrated in FIG. 7E satisfies (the area of the first light emitting element 10₁):(the area of the second light emitting element 10₂):(the area of the third light emitting element 10₁)=1:1:2, but it may be 1:1:1.

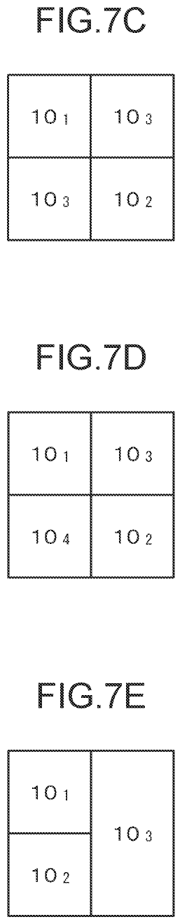

In the display device of Example 1 or Examples 2 to 8 described later, the array of the first light emitting element 10₁, the second light emitting element 10₂, and the third light emitting element 10₃ is specifically a delta array, but the array is not limited to the delta array. To simplify the drawings, the schematic and partial sectional views of the display device illustrated in FIG. 1 and FIGS. 8, 9, 10, 14, and 19 described later are different from the schematic and partial sectional views of the display device in which the light emitting elements 10 are arrayed in a delta array.

In Example 1 or Examples 2 to 8 described later, the light emitting elements 10 may have a resonator structure in which the organic layer 33 serves as a resonance unit. To appropriately adjust the distance from the light emitting surface to the reflection surface (specifically, the distance from the light emitting surface to the first electrode 31 and the second electrode 32), the thickness of the organic layer 33 is preferably 8×10⁻⁸ m or more and 5×10⁻⁷ m or less, and more preferably 1.5×10⁻⁷ m or more and 3.5×10⁻⁷ m or less. In practice, in an organic EL display device having a resonator structure, the first light emitting element (red light emitting element) 10₁ causes light emitted from the light emitting layer to resonate, and emits reddish light (light having a light spectrum peak in a red region) from the second electrode 32. The second light emitting element (green light emitting element) 10₂ causes light emitted from the light emitting layer to resonate, and emits greenish light (light having a light spectrum peak in a green region) from the second electrode 32. The third light emitting element (blue light emitting element) 10₃ causes light emitted from the light emitting layer to resonate, and emits bluish light (light having a light spectrum peak in a blue region) from the second electrode 32.

Hereinafter, an outline of a method for producing the light emitting element of Example 1 illustrated in FIG. 1 will be described.

### [Step-100]

First, form a light emitting element drive unit on a silicon semiconductor substrate (the first substrate 41) based on a known MOSFET production process.

### [Step-110]

Next, form the base 26 on the entire surface based on a CVD method.

### [Step-120]

Next, form a connection hole in the part of the base 26 located above one source/drain region of the transistor 20 based on a photolithography technique and an etching technique. Thereafter, form a metal layer on the base 26 including the connection hole based on, for example, a sputtering method, and then pattern the metal layer based on a photolithography technique and an etching technique, to form the first electrode 31 on a part of the base 26. The first electrode 31 is separated for each light emitting element. A contact hole (contact plug) 27 that electrically connects the first electrode 31 and the transistor 20 may be formed in the connection hole at the same time.

### [Step-130]

Then, after the insulating layer 28 is formed on the entire surface based a CVD method, for example, form the opening 28′ in a part of the insulating layer 28 on the first electrode 31 based on a photolithography technique and an etching technique. The first electrode 31 is exposed at the bottom of the opening 28′.

### [Step-140]

Next, form the organic layer 33 on the first electrode 31 and the insulating layer 28 through, for example, a PVD method such as a vacuum vapor deposition method or a sputtering method, or a coating method such as a spin coating method or a die coating method. Next, form the second electrode 32 on the entire surface based on, for example, a vacuum vapor deposition method. In this manner, the organic layer 33 and the second electrode 32 may be formed on the first electrode 31. The organic layer 33 may be patterned into a desired shape in some cases.

### [Step-150]

Thereafter, form the protective layer 34 on the entire surface though, for example, a CVD method, a PVD method, or a coating method, and perform a flattening treatment on the top surface of the protective layer 34. Since the protective layer 34 may be formed based on a coating method, there are few in-process restrictions, a wide selection of material is made, and a high refractive index material can be used. Then, form the wavelength selection unit CF (color filter layers CF_{R}, CF_{G}, CF_{B}) on the protective layer 34 based on a known method.

### [Step-160]

Next, form a first lens formation layer for forming the first optical path control unit 71 on the color filter layer CF (CF_{R}, CF_{G}, CF_{B}), and form a first resist material layer on the first lens formation layer. Then, pattern the first resist material layer and further, perform a heat treatment thereon to form the first resist material layer into a lens shape. Next, perform etch back of the first resist material layer and the first lens formation layer to transfer the shape formed in the first resist material layer to the first lens formation layer. The first optical path control unit 71 (first lens member) may be thus obtained.

### [Step-170]

Thereafter, form a second lens formation layer for forming the second optical path control unit 72 on the first optical path control unit 71, and form a second resist material layer on the second lens formation layer. Then, pattern the second resist material layer and further, perform a heat treatment thereon to form the second resist material layer into a lens shape. Next, perform etch back on the second resist material layer and the second lens formation layer to transfer the shape formed in the second resist material layer to the second lens formation layer. The second optical path control unit 72 (first lens member) may be thus obtained.

### [Step-180]

Then, bond the first substrate 41 and the second substrate 42, specifically, the color filter layer CF and the second optical path control unit 72 to the underlayer 36 formed on the inner surface of the second substrate 42 via the bonding member (sealing resin layer) 35. The light emitting element and display device (organic EL display device) illustrated in FIGS. 1 and 2 may be thus obtained.

In the light emitting element or the display device of Example 1, light emitted from the outer edge of the light emitting region enters the first optical path control unit and exits in a direction toward the normal line LN₀ passing through the center of the light emitting region. Since the second optical path control unit is provided on the first optical path control unit, such light further travels in a direction toward the normal line LN₀ passing through the center of the light emitting region. As a result, it is possible to provide a light emitting element and a display device having a configuration and a structure in which optical crosstalk hardly occurs, and it is possible to improve front light extraction efficiency. Further, since the second optical path control unit may be formed on the first optical path control unit, it is possible to avoid complicating manufacturing of the light emitting element and the display device, and it is possible to obtain desired structures in a wide range.

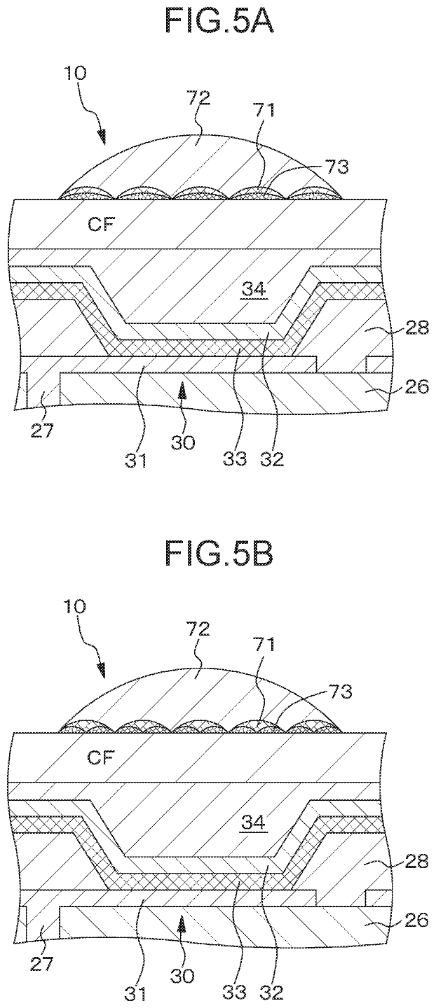

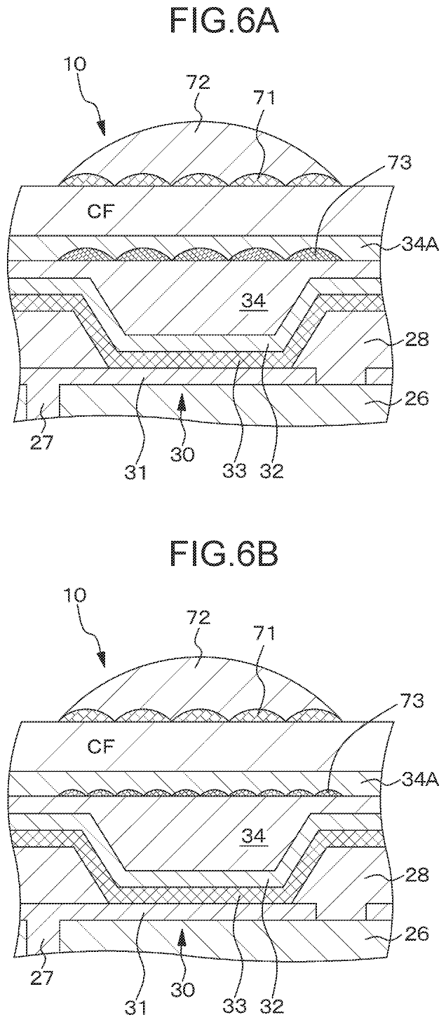

FIGS. 5A, 5B, 6A, and 6B are schematic and partial sectional views of a part of Modification-1, Modification-2, Modification-3, and Modification-4 of the light emitting element of Example 1.

In Modification-1 of the light emitting element of Example 1 illustrated in FIG. 5A, the third optical path control unit (third lens member) 73 is provided between the wavelength selection unit CF and the first optical path control unit 71. The first optical path control unit 71 and the third optical path control unit 73 have a one-to-one relationship. That is, one third optical path control unit 73 is provided for one first optical path control unit 71. In Modification-2 of the light emitting element of Example 1 illustrated in FIG. 5B, the first optical path control unit 71 and the third optical path control unit 73 have a one-to-many relationship. That is, a plurality of (for example, four) third optical path control units 73 are provided for one first optical path control unit 71. Specifically, in the example illustrated in FIGS. 5A and 5B, the wavelength selection unit CF is provided on the protective layer 34, the third optical path control unit 73 is provided on the wavelength selection unit CF, the first optical path control unit 71 is provided on the third optical path control unit 73, and the second optical path control unit 72 is provided on the first optical path control unit 71. The third optical path control unit 73 includes a plano-convex lens having a convex shape in a direction away from the light emitting unit 30.

In Modification-3 and Modification-4 of the light emitting element of Example 1 illustrated in FIGS. 6A and 6B, the third optical path control unit 73 is provided beneath or below the wavelength selection unit CF (in the illustrated example, beneath a second protective layer 34A provided beneath the wavelength selection unit CF). In Modification-3 of the light emitting element of Example 1 illustrated in FIG. 6A, the first optical path control unit 71 and the third optical path control unit 73 have a one-to-one relationship. That is, one third optical path control unit 73 is provided for one first optical path control unit 71. In Modification-4 of the light emitting element of Example 1 illustrated in FIG. 6B, the first optical path control unit 71 and the third optical path control unit 73 have a one-to-many relationship. That is, a plurality of (for example, four) third optical path control units 73 are provided for one first optical path control unit 71. Specifically, in the example illustrated in FIGS. 6A and 6B, the third optical path control unit 73 is provided on the protective layer 34, the second protective layer 34A is provided on the third optical path control unit 73, the wavelength selection unit CF is provided on the second protective layer 34A, and the first optical path control unit 71 and the second optical path control unit 72 are provided on the wavelength selection unit CF.

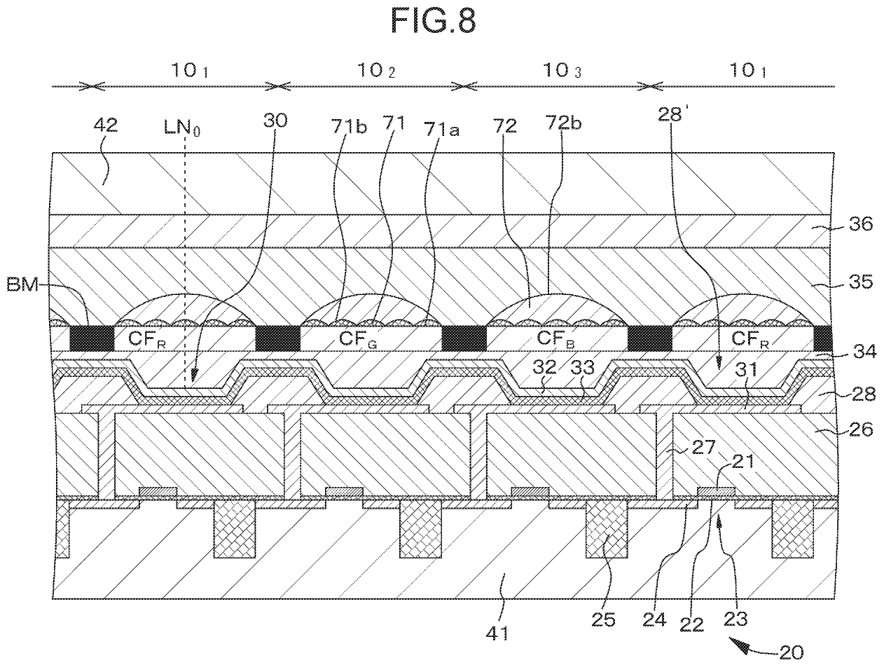

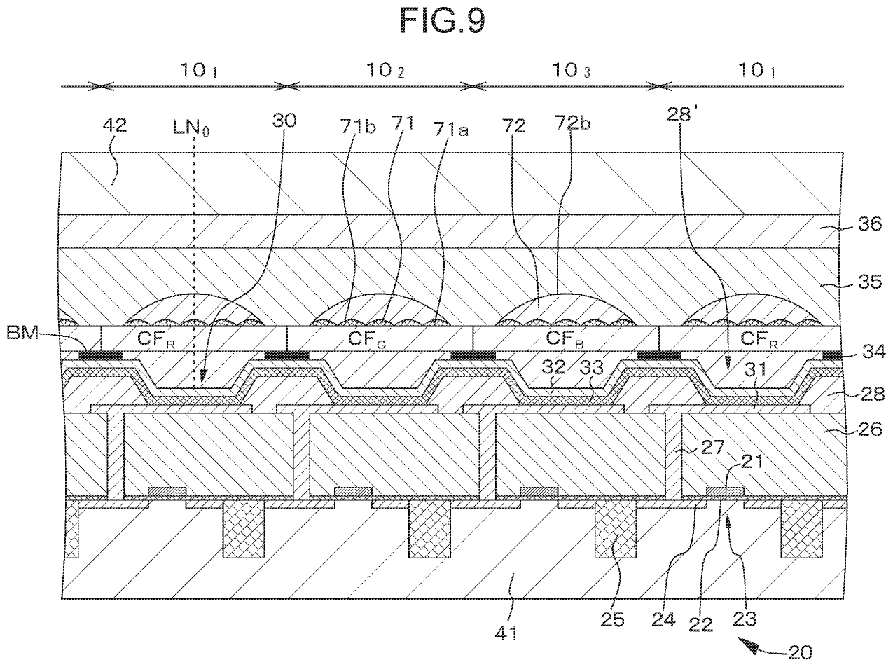

In addition, as FIG. 8 illustrates a schematic and partial sectional view of Modification-5 of the light emitting element of Example 1, a light absorbing layer (black matrix layer) BM may be formed between the wavelength selection units CF of adjacent light emitting elements. As FIG. 9 illustrates a schematic and partial sectional view of Modification-6 of the display device of Example 1, the light absorption layer (black matrix layer) BM may be formed below the position between the wavelength selection units CF of adjacent light emitting elements. As FIG. 10 illustrates a schematic and partial sectional view of Modification-7 of the display device of Example 1, the light absorption layer (black matrix layer) BM may be formed between the second optical path control unit 72 and the second optical path control unit 72 of adjacent light emitting elements. The black matrix layer BM is composed of, for example, a black resin film (specifically, for example, a black polyimide-based resin) mixed with a black colorant and having an optical density of 1 or more. These Modification-5, Modification-6, and Modification-7 may be appropriately applied to Modification-1, Modification-2, Modification-3, and Modification-4, and they may also be applied to other Examples.

The protective layer may have a function as a color filter layer. That is, the protective layer having such a function may be made of a known color resist material. With the protective layer also functioning as a color filter layer, the organic layer and the protective layer (color filter layer) can be closely disposed each other, and color mixture can be effectively prevented even with a widened angle of light emitted from the light emitting element, and viewing angle characteristics improve.

### Example 2

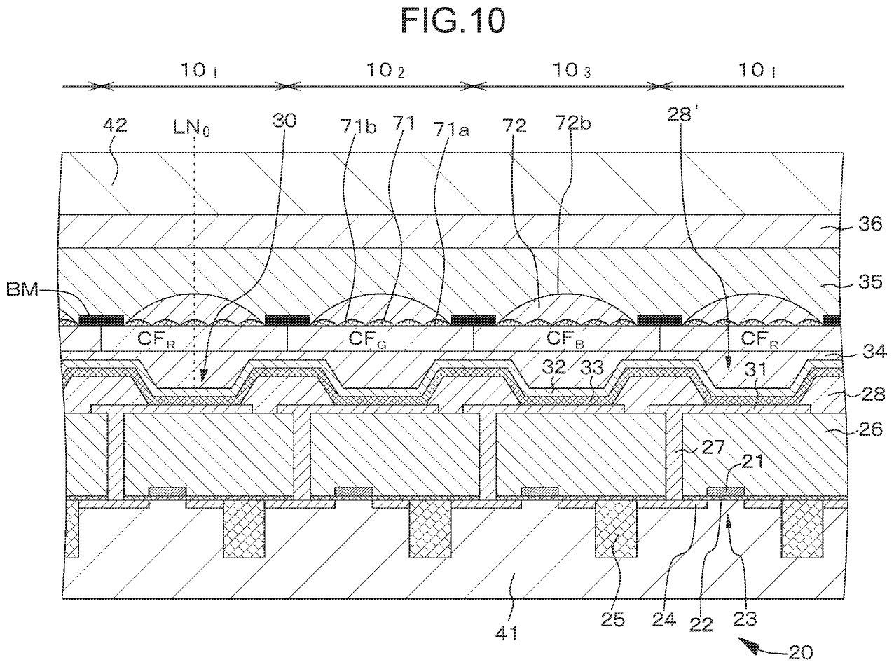

Example 2 is a modification of Example 1 and relates to the light emitting element of the second configuration. As FIG. 11 illustrates a schematic and partial sectional view of a part of the light emitting element of Example 2, the wavelength selection unit CF is provided between the first optical path control unit 71 and the second optical path control unit 72. Specifically, the first optical path control unit 71 is provided on the protective layer 34, a second protective layer 34B is provided on the first optical path control unit 71, the wavelength selection unit CF is provided on the second protective layer 34B, and the second optical path control unit 72 is provided on the wavelength selection unit CF.

Other than the above points, detailed description of the configurations and structures of the light emitting element and the display device of Example 2 is omitted since they may be the same as those of the light emitting element and the display device described in Example 1.

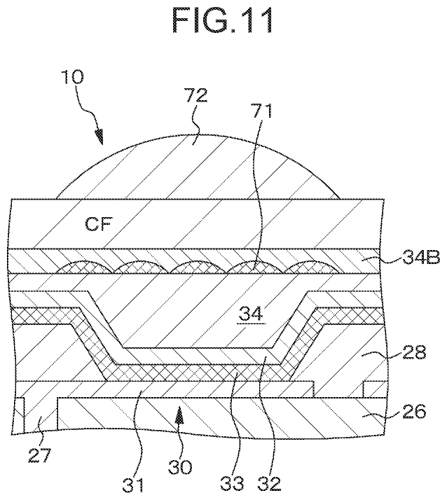

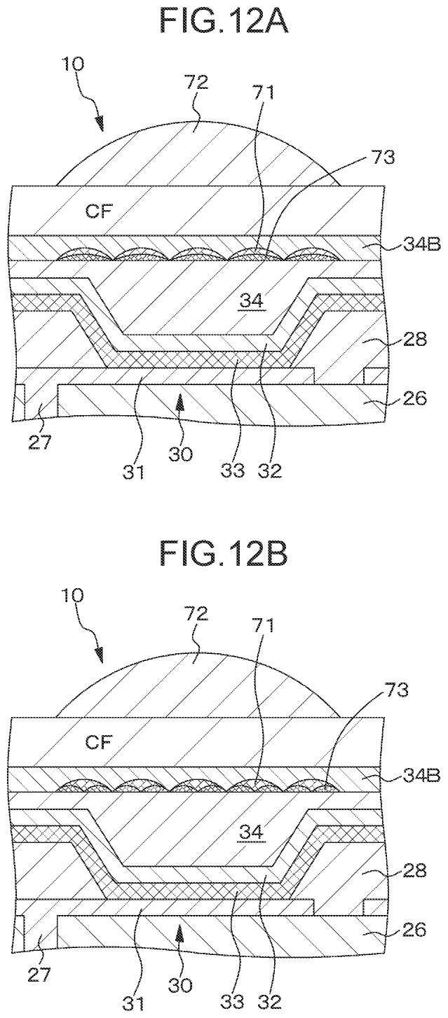

FIGS. 12A, 12B, 13A, and 13B are schematic and partial sectional views of a part of Modification-1, Modification-2, Modification-3, and Modification-4 of the light emitting element of Example 2.

In Modification-1 and Modification-2 of the light emitting element of Example 2 illustrated in FIGS. 12A and 12B, the third optical path control unit 73 is provided beneath or below the first optical path control unit 71 (in the illustrated example, beneath the first optical path control unit 71). In Modification-1 of the light emitting element of Example 2 illustrated in FIG. 12A, the first optical path control unit 71 and the third optical path control unit 73 have a one-to-one relationship. That is, one third optical path control unit 73 is provided for one first optical path control unit 71. In Modification-2 of the light emitting element of Example 2 illustrated in FIG. 12B, the first optical path control unit 71 and the third optical path control unit 73 have a one-to-many relationship. That is, a plurality of (for example, four) third optical path control units 73 are provided for one first optical path control unit 71. Specifically, in the example illustrated in FIGS. 12A and 12B, the third optical path control unit 73 is provided on the protective layer 34, the first optical path control unit 71 is provided on the third optical path control unit 73, the second protective layer 34B is provided on the first optical path control unit 71, the wavelength selection unit CF is provided on the second protective layer 34B, and the second optical path control unit 72 is provided on the wavelength selection unit CF.

In Modification-3 and Modification-4 of the light emitting element of Example 2 illustrated in FIGS. 13A and 13B, the third optical path control unit 73 is provided beneath or below the wavelength selection unit CF (in the illustrated example, below a third protective layer 34C provided beneath the wavelength selection unit CF). In Modification-3 of the light emitting element of Example 2 illustrated in FIG. 13A, the first optical path control unit 71 and the third optical path control unit 73 have a one-to-one relationship. That is, one third optical path control unit 73 is provided for one first optical path control unit 71. In Modification-4 of the light emitting element of Example 2 illustrated in FIG. 13B, the first optical path control unit 71 and the third optical path control unit 73 have a one-to-many relationship. That is, a plurality of (for example, four) third optical path control units 73 are provided for one first optical path control unit 71. Specifically, in the example illustrated in FIGS. 13A and 13B, the third optical path control unit 73 is provided on the protective layer 34, the third protective layer 34C is provided on the third optical path control unit 73, the first optical path control unit 71 is provided on the third protective layer 34C, the second protective layer 34B is provided on the first optical path control unit 71, the wavelength selection unit CF is provided on the second protective layer 34B, and the second optical path control unit 72 is provided on the wavelength selection unit CF.

### Example 3

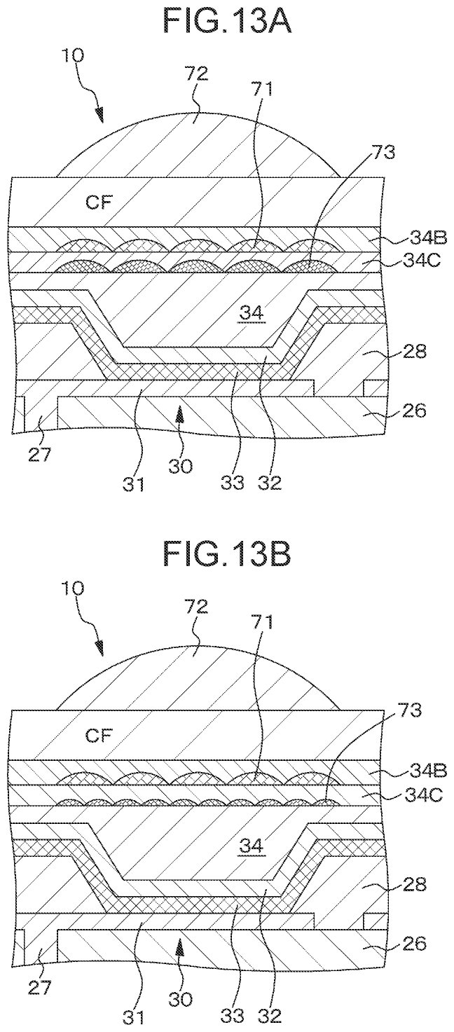

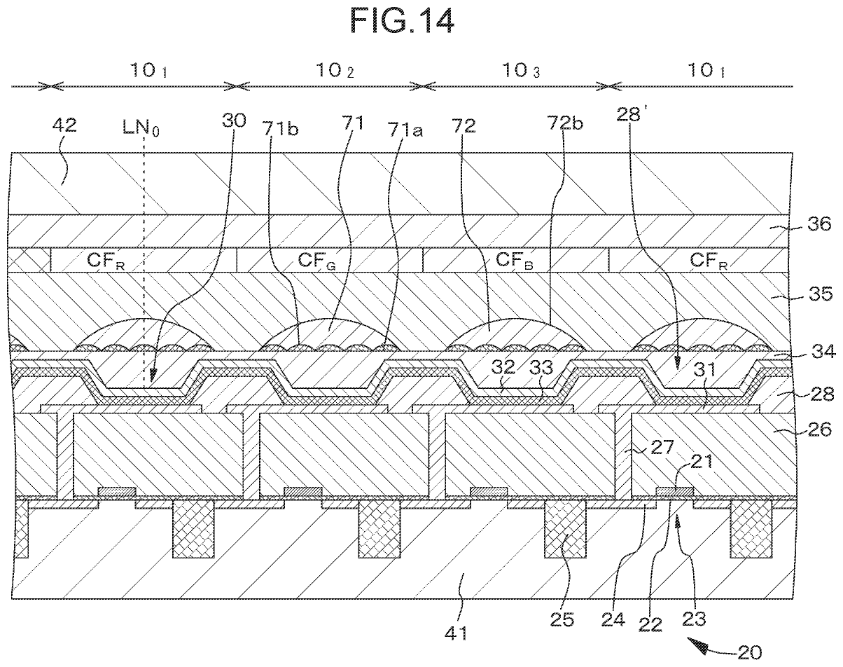

Example 3 is also a modification of Example 1, and it relates to the light emitting element of the third configuration. FIG. 14 is a schematic and partial sectional view of a light emitting element and a display device of Example 3, and FIG. 15 is a schematic and partial sectional view of a part of the light emitting element. In the light emitting element of Example 3, the wavelength selection unit CF is provided on or above the second optical path control unit 72 (in the illustrated example, above the second optical path control unit 72). Specifically, the first optical path control unit 71 is provided on the protective layer 34, the second optical path control unit 72 is provided on the first optical path control unit 71, the underlayer 36 and the wavelength selection unit CF are sequentially provided on the inner surface of the second substrate 42, and the second optical path control unit 72, the protective layer 34, and the wavelength selection unit CF are bonded to each other by the bonding member 35.

Other than the above points, detailed description of the configurations and structures of the light emitting element and the display device of Example 3 is omitted since they may be the same as those of the light emitting element and the display device described in Example 1.

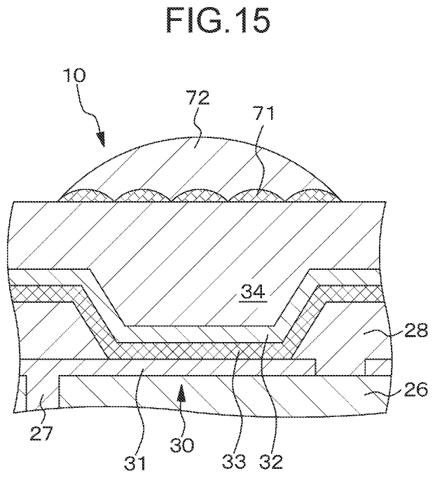

FIGS. 16A, 16B, 17A, 17B, 18A, and 18B are schematic and partial sectional views of a part of Modification-1, Modification-2, Modification-3, Modification-4, Modification-5, and Modification-6 of the light emitting element of Example 3.

In Modification-1 and Modification-2 of the light emitting element of Example 3 illustrated in FIGS. 16A and 16B, the third optical path control unit 73 is provided beneath or below the first optical path control unit 71 (in the illustrated example, beneath the first optical path control unit 71). In Modification-1 of the light emitting element of Example 3 illustrated in FIG. 16A, the first optical path control unit 71 and the third optical path control unit 73 have a one-to-one relationship. That is, one third optical path control unit 73 is provided for one first optical path control unit 71. In Modification-2 of the light emitting element of Example 3 illustrated in FIG. 16B, the first optical path control unit 71 and the third optical path control unit 73 have a one-to-many relationship. That is, a plurality of (for example, four) third optical path control units 73 are provided for one first optical path control unit 71. Specifically, in the example illustrated in FIGS. 16A and 16B, the third optical path control unit 73 is provided on the protective layer 34, the first optical path control unit 71 is provided on the third optical path control unit 73, and the second optical path control unit 72 is provided on the first optical path control unit 71.

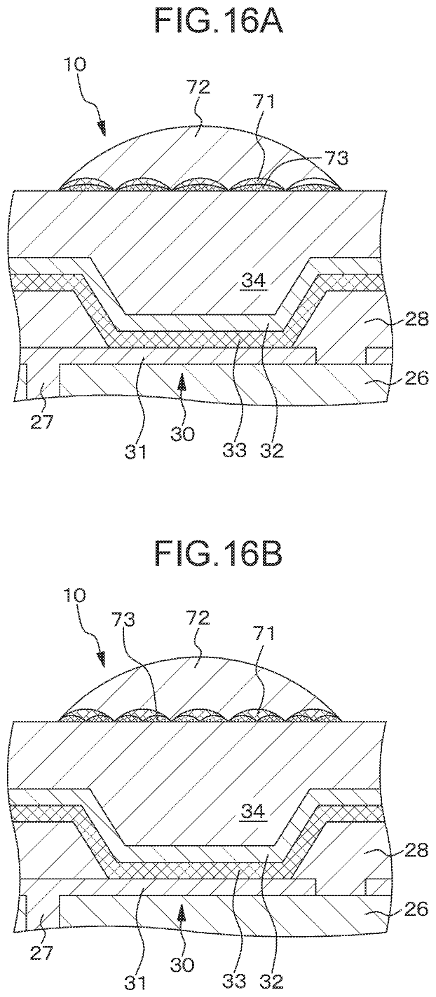

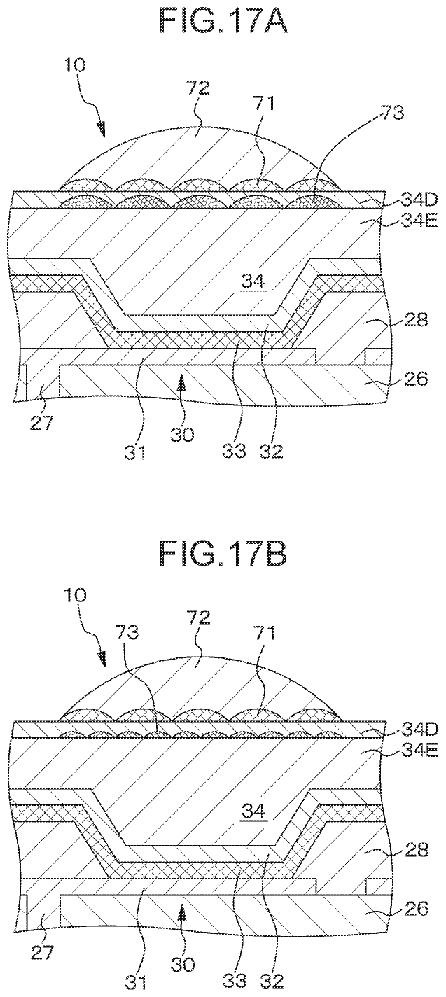

In Modification-3, Modification-4, Modification-5, and Modification-6 of the light emitting element of Example 3 illustrated in FIGS. 17A, 17B, 18A, and 18B, the third optical path control unit 73 is provided below the first optical path control unit 71. In Modification-3 and Modification-5 of the light emitting element of Example 3 illustrated in FIGS. 17A and 18A, the first optical path control unit 71 and the third optical path control unit 73 have a one-to-one relationship. That is, one third optical path control unit 73 is provided for one first optical path control unit 71. In Modification-4 and Modification-6 of the light emitting element of Example 3 illustrated in FIGS. 17B and 18B, the first optical path control unit 71 and the third optical path control unit 73 have a one-to-many relationship. That is, a plurality of (for example, four) third optical path control units 73 are provided for one first optical path control unit 71. Specifically, in the example illustrated in FIGS. 17A and 17B, the third optical path control unit 73 is provided on the protective layer 34, a second protective layer 34D is provided on the third optical path control unit 73, the first optical path control unit 71 is provided on the second protective layer 34D, and the second optical path control unit 72 is provided on the first optical path control unit 71. In the example illustrated in FIGS. 18A and 18B, the third optical path control unit 73 is provided on the protective layer 34, a third protective layer 34E is provided on the third optical path control unit 73, the first optical path control unit 71 is provided on the third protective layer 34E, the second protective layer 34D is provided on the first optical path control unit 71, and the second optical path control unit 72 is provided on the second protective layer 34D.

### Example 4

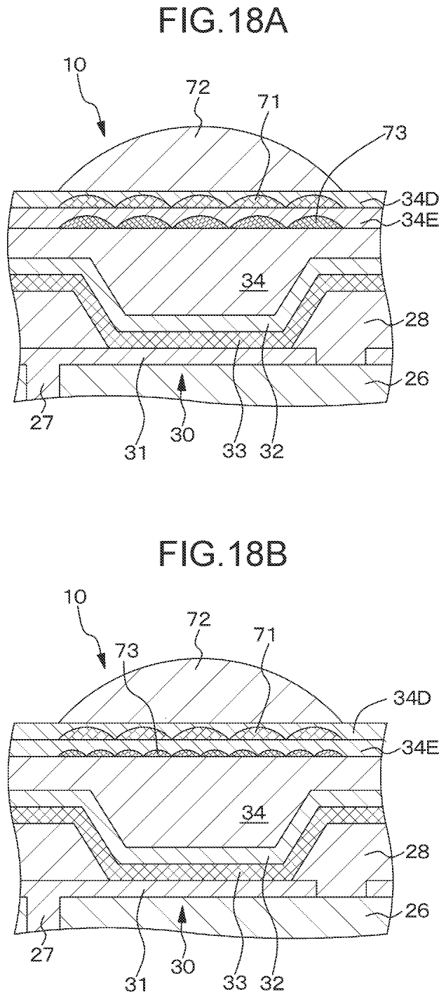

Example 4 is a modification of Examples 1 to 3. As illustrated in the schematic and partial sectional view of FIG. 19, in the light emitting element and display device of Example 4, the first optical path control unit 71 consists of a plano-convex lens having a convex shape in a direction toward the light emitting unit 30, and the second optical path control unit 72 consists of a plano-convex lens having a convex shape in a direction toward the light emitting unit 30. Specifically, the wavelength selection unit CF is provided on the protective layer 34. On the other hand, the underlayer 36, the second optical path control unit 72, a second underlayer 36A, and the first optical path control unit 71 are sequentially provided on the inner surface of the second substrate 42. The second underlayer 36A, the first optical path control unit 71, and the wavelength selection unit CF are bonded to each other by the bonding member 35.

Other than the above points, detailed description of the configurations and structures of the light emitting element and the display device of Example 4 is omitted since they may be the same as those of the light emitting element and the display device described in Example 1. Of course, Modification-1, Modification-2, Modification-3, and Modification-4 of each of Example 1, Example 2, and Example 3, Modification-5 and Modification-6 of Example 3 may be appropriately applied to the light emitting element and display device of Example 4. The third optical path control unit 73 also consists of a plano-convex lens having a convex shape in a direction toward the light emitting unit 30.

### Example 5

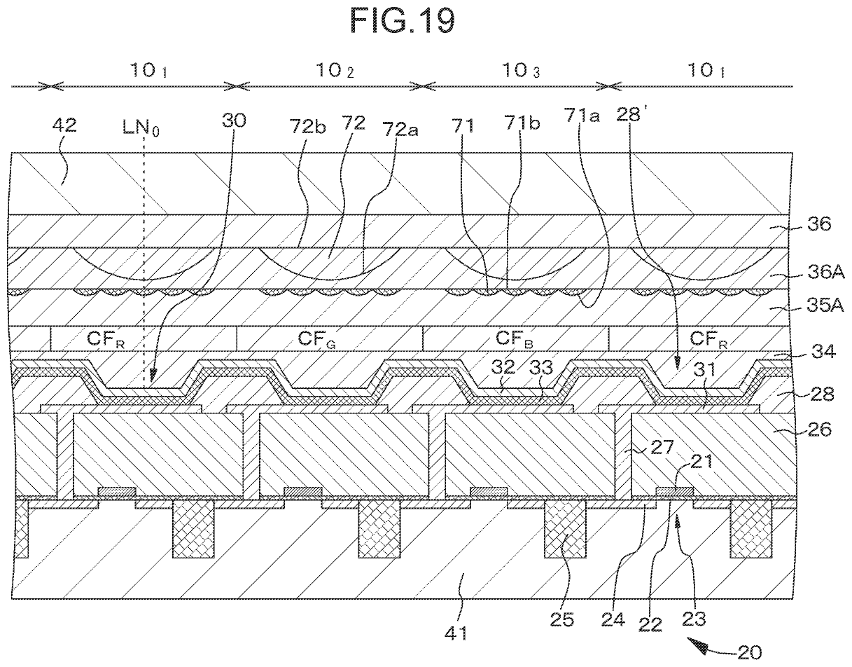

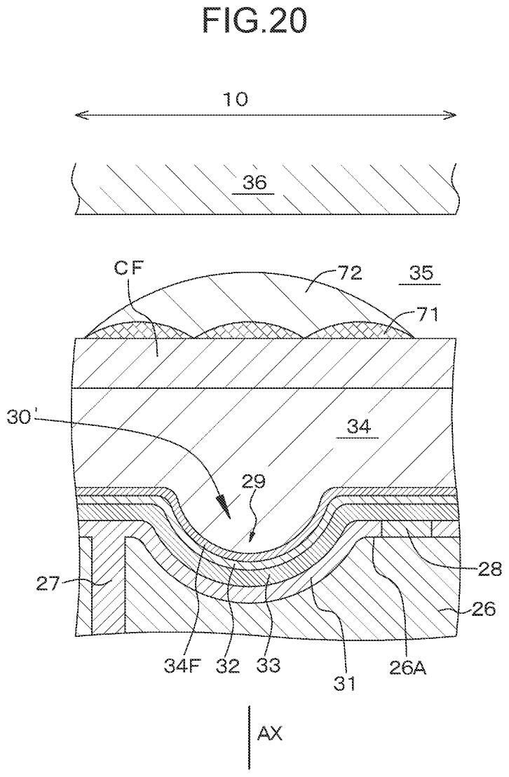

Example 5 is a modification of Examples 1 to 4. FIG. 20 is a schematic and partial sectional view of the light emitting element of Example 5, and FIG. 21 is a schematic and partial sectional view of the light emitting element for explaining the behavior of light from the light emitting element of Example 5.

In the light emitting element 10 of Example 5, a light emitting unit 30′ has a convex shape toward the first substrate 41. Specifically,
a surface 26A of the base 26 is provided with a recess 29,
at least a part of the first electrode 31 is formed following the shape of the top surface of the recess 29,
at least a part of the organic layer 33 is formed on the first electrode 31 following the shape of the top surface of the first electrode 31,
the second electrode 32 is formed on the organic layer 33 following the shape of the top surface of the organic layer 33, and
the protective layer 34 is formed on the second electrode 32.

In the light emitting element of Example 5, in the recess 29, the entire first electrode 31 is formed following the shape of the top surface of the recess 29, and the entire organic layer 33 is formed on the first electrode 31 following the shape of the top surface of the first electrode 31.

In the light emitting element 10 of Example 5, a fourth protective layer 34F is formed between the second electrode 32 and the protective layer 34. The fourth protective layer 34F is formed following the shape of the top surface of the second electrode 32. Here, n₃>n₄ is satisfied where the refractive index of the material constituting the protective layer (flattening layer) 34 is n₃ and the refractive index of the material constituting the fourth protective layer 34F is n₄. Examples of the value of (n₃−n₄) include, but are not limited to, 0.1 to 0.6. Specifically, the material constituting the protective layer 34 includes a material in which TiO₂ is added to a base material composed of an acrylic resin to adjust (enhance) the refractive index or a material in which TiO₂ is added to a base material composed of the same type of material as the color resist material (a colorless transparent material to which no pigment is added) to adjust (enhance) the refractive index, and the material constituting the fourth protective layer 34F includes SiN, SiON, Al₂O₃, or TiO₂. For example,

$${n}_{3} = 2.$$

$${n}_{4} = 1.6$$

are satisfied. Forming such a fourth protective layer 34F transmit allows part of light emitted from the organic layer 33 to pass through the second electrode 32 and the fourth protective layer 34F and enter the protective layer 34, and part of light emitted from the organic layer 33 to be reflected by the first electrode 31, pass through the second electrode 32 and the fourth protective layer 34F, and enter the protective layer 34, as illustrated in FIG. 21. In this manner, as a result of formation of an internal lens with the fourth protective layer 34F and the protective layer 34, light emitted from the organic layer 33 can be collected in a direction toward the central part of the light emitting element.

Alternatively, in the light emitting element of Example 5, when an incident angle of light emitted from the organic layer 33 and incident on the protective layer 34 through the second electrode 32 is θᵢ, and a refraction angle of light incident on the protective layer 34 is θᵣ,

$$\vert {θ}_{i} \vert > \vert {θ}_{r} \vert$$

is satisfied, where |θᵣ|≠0. Satisfying such a condition allows part of light emitted from the organic layer 33 to pass through the second electrode 32 and enter the protective layer 34, and part of light emitted from the organic layer 33 to be reflected by the first electrode 31, pass through the second electrode 32, and enter the protective layer 34. In this manner, as a result of forming an internal lens, light emitted from the organic layer 33 can be collected in a direction toward the central part of the light emitting element.

Forming the recess in this manner can further improve the front light extraction efficiency as compared with a case where the first electrode, the organic layer, and the second electrode have a flat stacked structure.

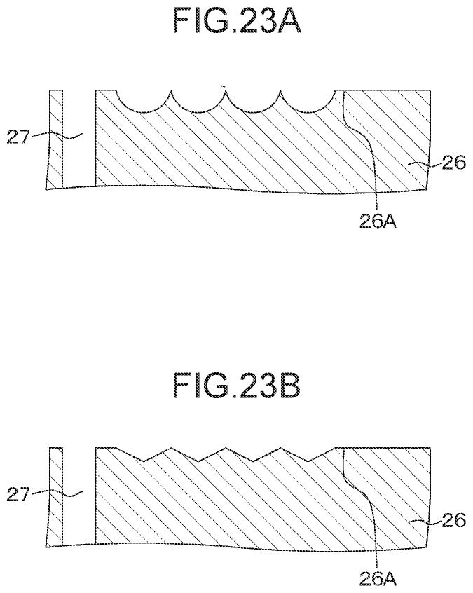

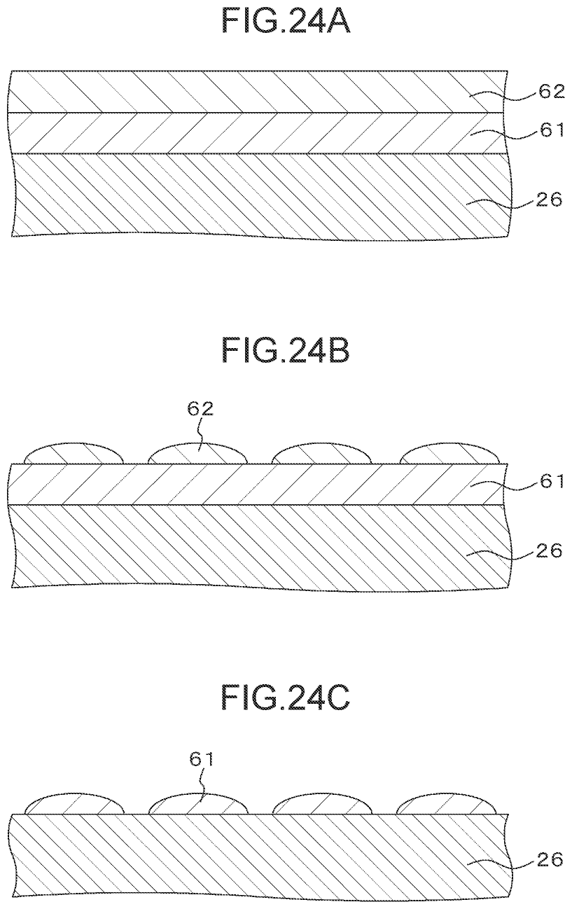

To form the recess 29 in the part of the base 26 where the light emitting element is to be formed, specifically, form a mask layer 61 made of SiN on the base 26 made of SiO₂, and form a resist layer 62 to which a shape for forming the recess is imparted on the mask layer 61 (see FIGS. 24A and 24B). Then, etch back the resist layer 62 and the mask layer 61 to transfer the shape formed on the resist layer 62 to the mask layer 61 (see FIG. 24C). Next, after a resist layer 63 is formed on the entire surface (see FIG. 25A), etch back the resist layer 63, the mask layer 61, and the base 26, whereby the recess 29 may be formed in the base 26 (see FIG. 25B). The recess 29 may be formed in the base 26 by appropriately selecting the material of the resist layer 63 and appropriately setting the etching conditions for etching back the resist layer 63, the mask layer 61, and the base 26, specifically, by selecting a material system and an etching condition in which the etching speed of the resist layer 63 is lower than the etching speed of the mask layer 61.

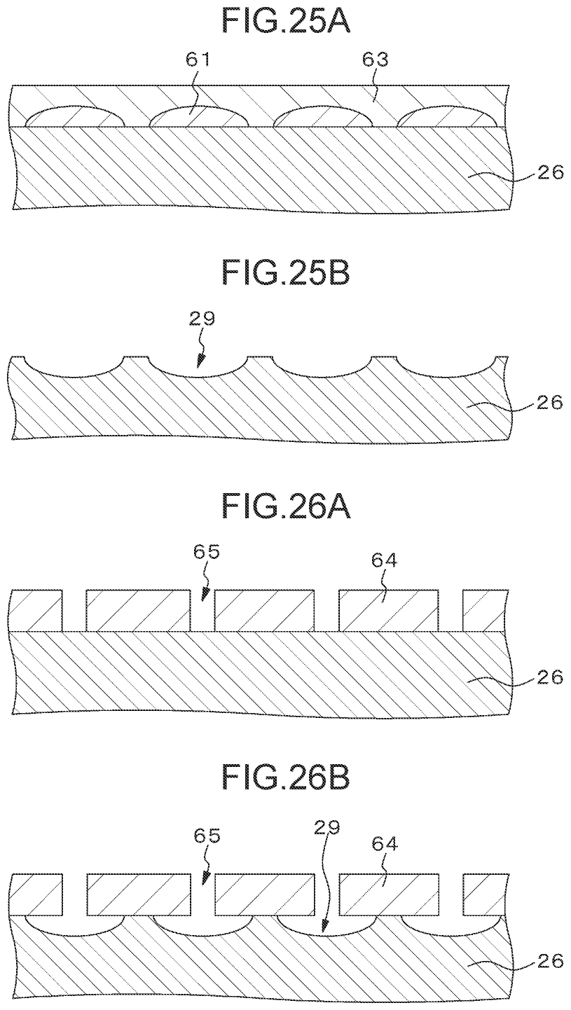

Alternatively, form a resist layer 64 having an opening 65 on the base 26 (see FIG. 26A). Then, perform wet etching on the base 26 via the opening 65, whereby the recess 29 may be formed in the base 26 (see FIG. 26B). The fourth protective layer 34F may be formed on the entire surface based on, for example, an ALD method. The fourth protective layer 34F is formed on the second electrode 32 following the shape of the top surface of the second electrode 32 and has a constant thickness in the recess 29. Subsequently, after the protective layer 34 is formed on the entire surface based on a coating method, a flattening treatment may be performed on the top surface of the protective layer 34.

In this manner, in the light emitting element of Example 5, a recess is provided on the surface of the base, and the first electrode, the organic layer, and the second electrode are formed substantially following the shape of the top surface of the recess. Since the recess is formed as described above, the recess can function as a kind of concave mirror. As a result, the front light extraction efficiency can further improve, the current-light emission efficiency remarkably improve, and the manufacturing process does not significantly increase. In addition, since the organic layer has a constant thickness, the resonator structure can be easily formed. Further, since the first electrode has a constant thickness, it is possible to reduce occurrence of a phenomenon such as coloring or luminance change of the first electrode depending on the angle at which the display device is viewed due to a thickness change of the first electrode.

Since the region other than the recess 29 is also composed of the stacked structure of the first electrode 32, the organic layer 33, and the second electrode 32, light is emitted also from this region. This may cause a decrease in light collection efficiency and a decrease in monochromaticity due to light leakage from adjacent pixels. Here, since the boundary between the insulating layer 28 and the first electrode 31 is an end of the light emitting area, it is only required to optimize the region where light is emitted by optimizing this boundary.

In particular, in a microdisplay having a small pixel pitch, high front light extraction efficiency can be achieved even when an organic layer is formed in a recess with a reduced depth. Thus the light emitting element is suitable for application to future mobile applications. In the light emitting element of Example 5, the current-light emission efficiency is further improved as compared with the conventional light emitting element, and it is possible to realize long life and high luminance of the light emitting element and the display device. In addition, the light emitting element can be applied to a remarkably expanded range of eyewear, augmented reality (AR) glasses, and EVR.

The larger the depth of the recess is, the more the light emitted from the organic layer and reflected by the first electrode can be collected in a direction toward the central part of the light emitting element. However, when the depth of the recess is large, it may be difficult to form the organic layer in the upper part of the recess. In this regard, since an internal lens is formed by the fourth protective layer and the protective layer, light reflected by the first electrode can be collected in a direction toward the central part of the light emitting element even when the depth of the recess is small, and the front light extraction efficiency can further improve. Moreover, since the internal lens is formed in a self-alignment manner with respect to the organic layer, there is no misalignment between the organic layer and the internal lens. In addition, since the angle of light passing through the color filter layer with respect to a base virtual plane can be increased by forming the recess and the internal lens, occurrence of color mixing between adjacent pixels can be effectively prevented. Thus, the color gamut reduction caused by the optical color mixture between the adjacent pixels is remedied, and the color gamut of the display device can improve. In general, the closer the organic layer and the lens are, the more efficiently the light can be spread to a wide angle. However, since the distance between the internal lens and the organic layer is very short, the design width and the design freedom of the light emitting element are widened. Moreover, by appropriately selecting the thicknesses and materials of the protective layer and the third protective layer, the distance between the internal lens and the organic layer and the curvature of the internal lens can be changed, and the design width and design freedom of the light emitting element are further expanded. Further, since heat treatment is unnecessary for forming the internal lens, the organic layer is not damaged.

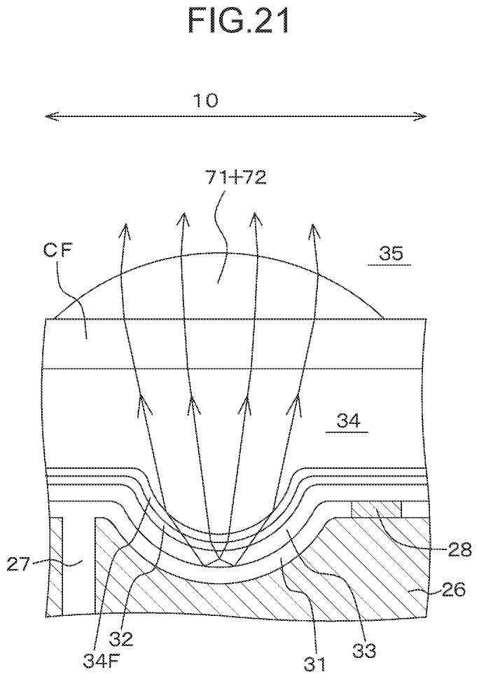

In the example illustrated in FIG. 20, the sectional shape of the recess 29 when the recess 29 is cut along the virtual plane including the axis AX of the recess 29 is a smooth curve. However, as illustrated in FIG. 22A, the sectional shape may be a part of a trapezoid, or as illustrated in FIG. 22B, the sectional shape may be a combination of a linear slope 29A and a bottom 29B including a smooth curve. In FIGS. 22A and 22B, illustration of the second optical path control unit 72 and the underlayer 36 is omitted. By forming the sectional shape of the recess 29 into these shapes, the inclination angle of the slope 29A can be increased. As a result, even when the depth of the recess 29 is small, extraction of light emitted from the organic layer 33 and reflected by the first electrode 31 can improve in the front direction.

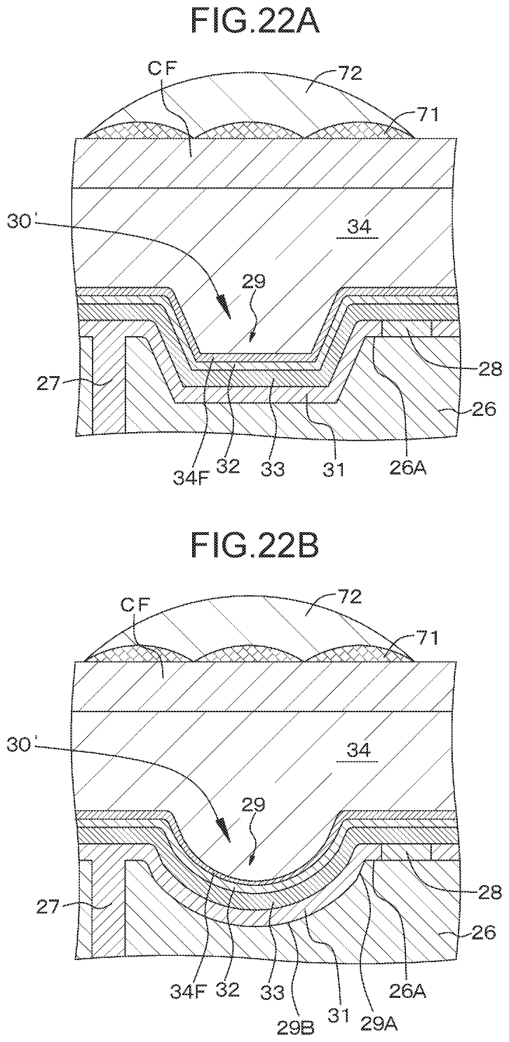

FIGS. 23A and 23B are schematic and partial sectional views of the base 26 before the first electrode 31 and the like are formed. The light emitting unit may have an uneven sectional shape toward the first substrate 41. After the state of the base 26 illustrated in FIGS. 23A and 23B is formed, the first electrode 31, the organic layer 33, and the second electrode 32 may be sequentially formed.

### Example 6

Example 6 is a modification of Examples 1 to 5. The light emitting element of Example 6 has a resonator structure. That is, the organic EL display device preferably has a resonator structure to further improve the light extraction efficiency. When the resonator structure is provided, as described above, the resonator structure may be a resonator structure in which the organic layer 33 serves as a resonance part and is sandwiched between the first electrode 31 and the second electrode 32. Alternatively, as described in Example 6, the resonator structure may be formed by forming a light reflection layer 37 below the first electrode 31 (on the first substrate 41 side), forming an interlayer insulating material layer 38 between the first electrode 31 and the light reflection layer 37, and having the organic layer 33 and the interlayer insulating material layer 38 as a resonance unit, which are sandwiched between the light reflection layer 37 and the second electrode 32.

Specifically, light emitted from the light emitting layer included in the organic layer is caused to resonate between a first interface formed of an interface between the first electrode and the organic layer (or a first interface formed of an interface between the light reflection layer and the interlayer insulating material layer in a structure in which an interlayer insulating material layer is provided beneath the first electrode and a light reflection layer is provided beneath the interlayer insulating material layer as described in Example 6) and a second interface formed of an interface between the second electrode and the organic layer, and part of the light is emitted from the second electrode. The following Formulas (1-1) and (1-2) may be satisfied where the optical distance from the maximum light emission position of the light emitting layer to the first interface is OL₁, the optical distance from the maximum light emission position of the light emitting layer to the second interface is OL₂, and m₁ and m₂ are integers.

$$0.7 \{ - {Φ}_{1} / ( 2 π ) + {m}_{1} \} \leq 2 \times {OL}_{1} / λ \leq 1.2 \{ - {Φ}_{1} / ( 2 π ) + {m}_{1} \} \qquad ( 1 - 1 )$$

$$0.7 \{ - {Φ}_{2} / ( 2 π ) + {m}_{2} \} \leq 2 \times {OL}_{2} / λ \leq 1.2 \{ - {Φ}_{2} / ( 2 π ) + {m}_{2} \} \qquad ( 1 - 2 )$$

where

λ: a maximum peak wavelength of spectrum of light generated in the light emitting layer (or a desired wavelength of light generated in the light emitting layer)

Φ₁: a phase shift amount (unit: radian) of light reflected at the first interface where −2π<Φ₁≤0

Φ₂: a phase shift amount (unit: radian) of light reflected at the second interface where −2π<Φ₂≤0.

The value of m₁ is a value of 0 or more, and the value of m₂ is a value of 0 or more independently of the value of m₁. Examples thereof include (m₁, m₂)=(0, 0), (m₁, m₂)=(0, 1), (m₁, m₂)=(1, 0), and (m₁, m₂)=(1, 1).

The distance SD₁ from the maximum light emission position of the light emitting layer to the first interface refers to an actual distance (physical distance) from the maximum light emission position of the light emitting layer to the first interface. The distance SD₂ from the maximum light emission position of the light emitting layer to the second interface refers to an actual distance (physical distance) from the maximum light emission position of the light emitting layer to the second interface. The optical distance is also referred to as an optical path length, and typically refers to n×SD when a light beam passes through a medium having a refractive index n by a distance SD. The same applies hereinafter. Thus,

$${OL}_{1} = {SD}_{1} \times {n}_{ave}$$

$${OL}_{2} = {SD}_{2} \times {n}_{ave}$$

are satisfied where nₐᵥₑ is an average refractive index. Here, the average refractive index nₐᵥₑ is obtained by summing up the product of the refractive index and the thickness of each layer constituting the organic layer (or, the organic layer, the first electrode, and the interlayer insulating layer) and dividing the sum by the thickness of the organic layer (or, the organic layer, the first electrode, and the interlayer insulating layer).

The light emitting element may be designed by determining a desired wavelength λ (specifically, a red wavelength, a green wavelength, or a blue wavelength, for example) in light generated in the light emitting layer and obtaining various parameters such as OL₁ and OL₂ in the light emitting element based on Formulas (1-1) and (1-2).

The first electrode or the light reflection layer and the second electrode absorb part of incident light and reflect the rest. Thus, a phase shift occurs in the reflected light. The phase shift amounts @; and @2 may be obtained by measuring the values of the real number part and the imaginary number part of the complex refractive index of the materials constituting the first electrode or the light reflection layer and the second electrode using, for example, an ellipsometer, and performing calculation based on these values (see, for example, “Principles of Optic”, Max Born and Emil Wolf, 1974 (PERGAMON PRESS)). The refractive index of the organic layer, the interlayer insulating layer, or the like, the refractive index of the first electrode, or the refractive index of the first electrode in a case where the first electrode absorbs part of incident light and reflect the rest may also be determined by a measurement using an ellipsometer.

Examples of the material constituting the light reflection layer include aluminum, an aluminum alloy (for example, Al—Nd or Al—Cu), an Al/Ti stacked structure, an Al—Cu/Ti stacked structure, chromium (Cr), silver (Ag), a silver alloy (for example, Ag—Cu, Ag—Pd—Cu, Ag—Sm—Cu), copper, a copper alloy, gold, and a gold alloy. The light reflection layer may be formed by, for example: vapor deposition methods including an electron beam vapor deposition method, a hot filament vapor deposition method, and a vacuum vapor deposition method; sputtering methods; CVD methods; ion plating methods; plating methods such as electroplating methods and electroless plating methods; lift-off methods; laser ablation methods; sol-gel methods, and the like. Depending on the material constituting the light reflection layer, it is preferable to form an underlayer made of, for example, TiN, to control the crystalline state of the light reflection layer to be formed.

In this manner, in the organic EL display device having a resonator structure, in practice, the light emitting unit constituting a red light emitting element causes light emitted from the light emitting layer to resonate, and emits reddish light (light having a light spectrum peak in a red region) from the second electrode. The light emitting unit constituting a green light emitting element causes light emitted from the light emitting layer to resonate, and emits greenish light (light having a light spectrum peak in a green region) from the second electrode. The light emitting unit constituting a blue light emitting element causes light emitted from the light emitting layer to resonate, and emits bluish light (light having a light spectrum peak in a blue region) from the second electrode. That is, each light emitting element may be designed by determining a desired wavelength λ (specifically, a red wavelength, a green wavelength, or a blue wavelength, for example) in light generated in the light emitting layer and obtaining various parameters such as OL₁ and OL₂ in each of the red light emitting element, green light emitting element, and the blue light emitting element based on Formulas (1-1) and (1-2). For example, paragraph of JP 2012-216495 A discloses an organic EL element having a resonator structure in which an organic layer serves as a resonance unit, and it describes that a film thickness of the organic layer is preferably 80 nm or more and 500 nm or less, and more preferably 150 nm or more and 350 nm or less because a distance from a light emitting point (light emitting surface) to a reflection surface can be appropriately adjusted. Usually, the value of (SD₁+SD₂=SD₁₂) is different in the red light emitting element, the green light emitting element, and the blue light emitting element.

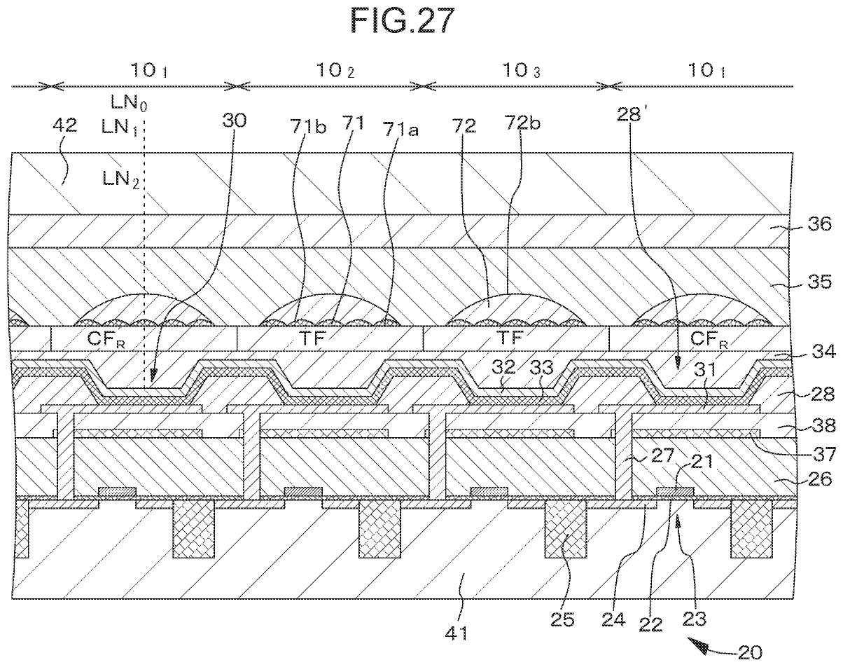

FIG. 27 is a schematic and partial sectional view of the light emitting element and display device of Example 6. In the display device of Example 6,
each of the light emitting elements 10 has a resonator structure,
the first light emitting element 10₁ emits red light, the second light emitting element 10₂ emits green light, and the third light emitting element 10₃ emits blue light,
the first light emitting element 10₁ is provided with the wavelength selection unit CF_{R} that transmits the emitted red light, and
the second light emitting element 10₂ and the third light emitting element 10₃ are not provided with the wavelength selection unit CF.

Alternatively, the display device of Example 6 includes:
a first substrate 41 and a second substrate 42; and
a plurality of light emitting element units each including a first light emitting element 10₁, a second light emitting element 10₂, and a third light emitting element 10; provided on the first substrate 41,
wherein
each of the light emitting elements 10 includes light emitting units 30, 30′ provided above the first substrate 41,
each of the light emitting elements 10 has a resonator structure,
the first light emitting element 10₁ emits red light, the second light emitting element 10₂ emits green light, and the third light emitting element 10₃ emits blue light,
the first light emitting element 10₁ is provided with the wavelength selection unit CF_{R} that transmits emitted red light, and
the second light emitting element 10₂ and the third light emitting element 10₃ are not provided with the wavelength selection unit CF.

Here, the red color filter layer CF_{R} is given as the wavelength selection unit CF that transmits emitted red light, but the wavelength selection unit CF is not limited to the red color filter layer CF_{R}. In the second light emitting element 10₂ and the third light emitting element 10₃, a transparent filter layer TF is provided instead of the color filter layer.

Optimum OL₁ and OL₂ may be obtained in each of the first light emitting element 10₁ to display red, the second light emitting element 10₂ to display green, and the third light emitting element 10₃ to display blue based on the above-described Formulas (1-1) and (1-2), whereby an emission spectrum having a sharp peak can be obtained in each light emitting element. The first light emitting element 10₁, the second light emitting element 10₂, and the third light emitting element 10₃ have the same configuration and structure except for the color filter layer CF_{R}, the filter layer TF, and the resonator structure (the configuration of the light emitting layer).

In some cases, in addition to the maximum peak wavelength λ_{R} (red) of the spectrum of light generated in the light emitting layer provided in the first light emitting element 10₁ to display red, light having a wavelength λ_{R}′ shorter than λ_{R} resonates in the resonator, depending on the settings of m₁ and m₂. Similarly, in addition to the maximum peak wavelength λ_{G} (green) of the spectrum of light generated in the light emitting layer provided in the second light emitting element 10₂ to display green, light having a wavelength λ_{G}′ shorter than No resonates in the resonator in some cases. In addition to the maximum peak wavelength λ_{B} (blue) of the spectrum of light generated in the light emitting layer provided in the third light emitting element 10₃ to display blue, light having a wavelength λ_{B}′ shorter than λ_{B} resonates in the resonator in some cases. Usually, light having wavelengths λ_{G}′ and λ_{B}′ is out of the range of visible light, and thus is not observed by an observer of the display device. However, light having a wavelength λ_{R}′ may be observed as blue by an observer of the display device.

Thus, in such a case, there is no need to provide the wavelength selection unit CF in the second light emitting element 10₂ or the third light emitting element 10₃, but it is preferable to provide the wavelength selection unit CF_{R} that transmits the emitted red light in the first light emitting element 10₁. Thus, it is possible to display an image with high color purity with the first light emitting element 10₁, and it is possible to achieve high light emission efficiency in the second light emitting element 10₂ and the third light emitting element 10₃ because the wavelength selection unit CF is not provided in the second light emitting element 10₂ or the third light emitting element 10₃.

Specifically, when the first interface is formed of the first electrode 31 in the resonator structure, the first electrode 31 may be made of a material that reflects light with high efficiency as described above. When the light reflection layer 37 is provided below the first electrode 31 (on the first substrate 41 side), the first electrode 31 may be made of a transparent conductive material as described above. When the light reflection layer 37 is provided on the base 26, and the first electrode 31 is provided on the interlayer insulating material layer 38 covering the light reflection layer 37, the first electrode 31, the light reflection layer 37, and the interlayer insulating material layer 38 may be made of the above-described materials. The light reflection layer 37 may be connected to the contact hole (contact plug) 27 (see FIG. 27) but does not have to be connected to the contact hole 27.

In some cases, instead of the filter layer TF, the green color filter layer CFs may be provided as the wavelength selection unit CF that transmits green light emitted from the second light emitting element 10₂, or the blue color filter layer CFs may be provided as the wavelength selection unit CF that transmits blue light emitted from the third light emitting element 10₃.

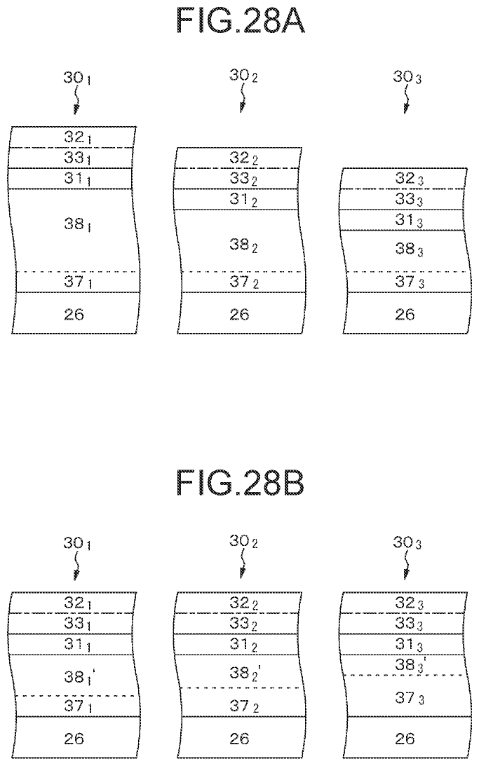

Hereinafter, the resonator structure will be described based on first to eighth examples with reference to FIG. 28A (first example), 28B (second example), 29A (third example), 29B (fourth example), 30A (fifth example), 30B (sixth example), 31A (seventh example), and 31B and 31C (eighth example). In the first to fourth examples and the seventh example, the first electrode has the same thickness in the light emitting units, and the second electrode has the same thickness in the light emitting units. In the fifth to sixth examples, the first electrode has different thicknesses in the light emitting units, and the second electrode has the same thickness in the light emitting units. In the eighth example, the first electrode may have different thicknesses or may have the same thickness in the light emitting units, and the second electrode has the same thickness in the light emitting units.

In the following description, the light emitting units 30, 30′ constituting the first light emitting element 10₁, the second light emitting element 10₂, and the third light emitting element 10₃ are denoted by reference numerals 30₁, 30₂, 30₃, the first electrode is denoted by reference numerals 31₁, 31₂, 31₃, the second electrode is denoted by reference numerals 32₁, 32₂, 32₃, the organic layer is denoted by reference numerals 33₁, 33₂, 33₃, the light reflection layer is denoted by reference numerals 37₁, 37₂, 37₃, and the interlayer insulating material layer is denoted by reference numerals 38₁, 38₂, 38₃, 38₁′, 38₂′, 38₃′. In the following description, materials to be used are examples, and they may be changed as appropriate.

In the illustrated examples, the resonator lengths of the first light emitting element 10₁, the second light emitting element 10₂, and the third light emitting element 10₃ derived from Formulas (1-1) and (1-2) are shortened in the order of the first light emitting element 10₁, the second light emitting element 10₂, and the third light emitting element 10₃, that is, the value of SD₁₂ is shortened in the order of the first light emitting element 10₁, the second light emitting element 10₂, and the third light emitting element 10₃, but the resonator lengths are not limited to this configuration, and the optimum resonator length may be determined by appropriately setting the values of m₁ and m₂.

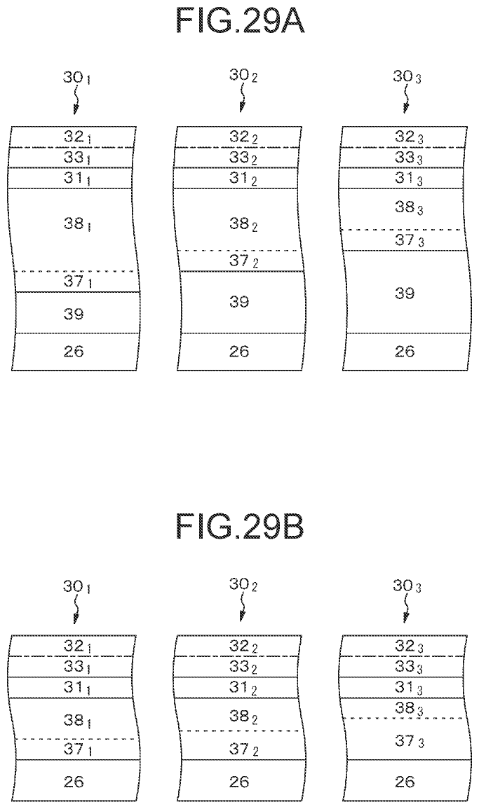

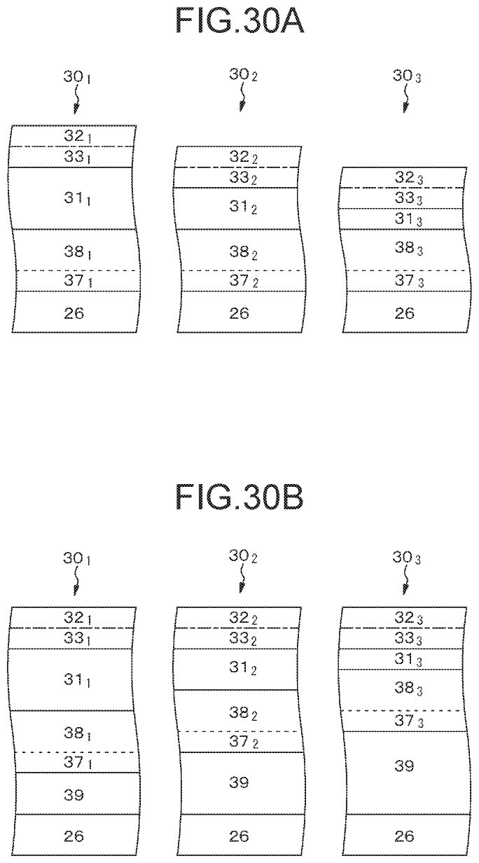

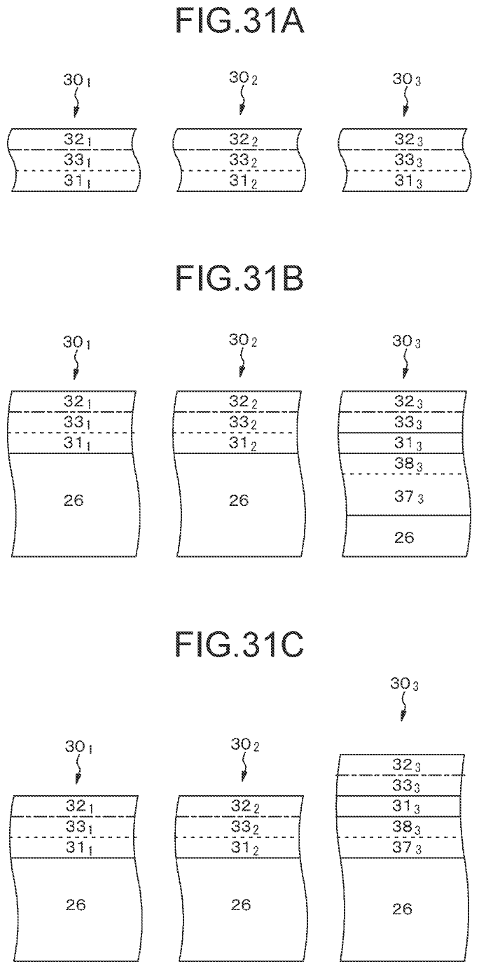

FIG. 28A is a conceptual diagram of light emitting elements of the first example having a resonator structure. FIG. 28B is a conceptual diagram of light emitting elements of the second example having a resonator structure. FIG. 29A is a conceptual diagram of light emitting elements of the third example having a resonator structure. FIG. 29B is a conceptual diagram of light emitting elements of the fourth example having a resonator structure. In some of the first to sixth examples and the eighth example, the interlayer insulating material layers 38, 38′ are formed beneath the first electrode 31 of the light emitting units 30, 30′ and the light reflection layer 37 is formed beneath the interlayer insulating material layers 38, 38′. In the first to fourth examples, the thicknesses of the interlayer insulating material layers 38, 38′ are different in the light emitting units 30₁, 30₂, 30₃. By appropriately setting the thicknesses of the interlayer insulating material layers 38₁, 38₂, 38₃, 38₁′, 38₂′, 38₃′, it is possible to set an optical distance at which optimum resonance is generated with respect to the emission wavelength of the light emitting units 30, 30′.

In the first example, the first interface (indicated by a dotted line in the drawings) is set to the same level in the light emitting units 30₁, 30₂, 30₃, while the level of the second interface (indicated by one-dot chain line in the drawings) is different in the light emitting units 30₁, 30₂, 30₃. In the second example, the first interface is set to different levels in the light emitting units 30₁, 30₂, 30₃, while the level of the second interface is the same in the light emitting units 30₁, 30₂, 30₃.

In the second example, the interlayer insulating material layers 38₁′, 38₂′, 38₃′ are made of an oxide film in which the surface of the light reflection layer 37 is oxidized. The interlayer insulating material layer 38′ made of an oxide film is made of, for example, aluminum oxide, tantalum oxide, titanium oxide, magnesium oxide, zirconium oxide, or the like depending on the material constituting the light reflection layer 37. The surface of the light reflection layer 37 may be oxidized by, for example, the following method. That is, immerse the first substrate 41 on which the light reflection layer 37 is formed in an electrolytic solution filled in a container. Dispose a cathode to face the light reflection layer 37. Then, anodize the light reflection layer 37 using the light reflection layer 37 as an anode. The film thickness of the oxide film formed through the anodization is proportional to the potential difference between the light reflection layer 37 as an anode and the cathode. Thus, anodization is performed in a state where voltages corresponding to the light emitting units 30₁, 30₂, 30₃ are applied to the light reflection layers 37₁, 37₂, 37₃, respectively. As a result, the interlayer insulating material layers 38₁′, 38z′, 38₃′ made of oxide films having different thicknesses can be collectively formed on the surface of the light reflection layer 37. The thicknesses of the light reflection layers 37₁, 37₂, 37₃ and the thicknesses of the interlayer insulating material layers 38₁′, 38₂′, 38₃′ are different in the light emitting units 30₁, 30₂, 30₃.

In the third example, an underlying film 39 is disposed beneath the light reflection layer 37, and the underlying film 39 has different thicknesses in the light emitting units 30₁, 30₂, 30₃. That is, in the illustrated example, the thickness of the underlying film 39 is increased in the order of the light emitting unit 30₁, the light emitting unit 30₂, and the light emitting unit 30₃.

In the fourth example, the thicknesses of the light reflection layers 37₁, 37₂, 37₃ at the time of film formation are different in the light emitting units 30₁, 30₂, 30₃. In the third and fourth examples, the second interface is set to the same level in the light emitting units 30₁, 30₂, 30₃, while the level of the first interface is different in the light emitting units 30₁, 30₂, 30₃.

In the fifth and sixth examples, the thicknesses of the first electrodes 31₁, 31₂, 31₃ are different in the light emitting units 30₁, 30₂, 30₃. The light reflection layer 37 has the same thickness in each light emitting unit 30.

In the fifth example, the level of the first interface is the same in the light emitting units 30₁, 30₂, 30₃, while the level of the second interface is different in the light emitting units 30₁, 30₂, 30₃.

In the sixth example, the underlying film 39 is disposed beneath the light reflection layer 37, and the underlying film 39 has different thicknesses in the light emitting units 30₁, 30₂, 30₃. That is, in the illustrated example, the thickness of the underlying film 39 is increased in the order of the light emitting unit 30₁, the light emitting unit 30₂, and the light emitting unit 30₃. In the sixth example, the second interface is set to the same level in the light emitting units 30₁, 30₂, 30₃, while the level of the first interface is different in the light emitting units 30₁, 30₂, 30₃.

In the seventh example, the first electrodes 31₁, 31₂, 31₃ also serve as light reflection layers, and the optical constant (specifically, the phase shift amount) of the material constituting the first electrodes 31₁, 31₂, 31₃ is different in the light emitting units 30₁, 30₂, 30₃. For example, the first electrode 31₁ of the light emitting unit 30₁ may be made of copper (Cu), and the first electrode 31₂ of the light emitting unit 30₂ and the first electrode 31₃ of the light emitting unit 30₃ may be made of aluminum (Al).

In the eighth example, the first electrodes 31₁, 31₂ also serve as light reflection layers, and the optical constant (specifically, the phase shift amount) of the material constituting the first electrodes 31₁, 31₂ is different in the light emitting units 30₁, 30₂. For example, the first electrode 31₁ of the light emitting unit 30₁ may be made of copper (Cu), and the first electrode 31₂ of the light emitting unit 30₂ and the first electrode 31₃ of the light emitting unit 30₃ may be made of aluminum (Al). In the eighth example, for example, the seventh example is applied to the light emitting units 30₁, 30₂, and the first example is applied to the light emitting unit 30₃. The thicknesses of the first electrodes 31₁, 31₂, 31₃ may be different or the same.

### Example 7

Example 7 is a modification of Examples 1 to 6. In Example 7, a relationship between the normal line LN₀ passing through the center of the light emitting region, the normal line LN₁ passing through the center of the second optical path control unit, and the normal line LN₂ passing through the center of the wavelength selection unit (color filter layer) CF, and a modification thereof will be described.

D₀, d₀, and D₁ are as follows.

D₀: Distance (offset amount) between the normal line LN₀ passing through the center of the light emitting region and the normal line LN; passing through the center of the second optical path control unit 72

d₀: Distance (offset amount) between the normal line LN₀ passing through the center of the light emitting region and the normal line LN₂ passing through the center of the wavelength selection unit CF

D₁: Distance from a reference point (reference region) P to the normal line LN₀ passing through the center of the light emitting region

In the light emitting elements of Example 7, when the distance (offset amount) between the normal line LN₀ passing through the center of the light emitting region and the normal line LN₁ passing through the center of the second optical path control unit 72 is D₀, the value of the distance (offset amount) D₀ is not 0 in at least some of the light emitting elements constituting the display device. In the display device, a reference point (reference region) P is assumed, and the distance D₀ depends on the distance D₁ from the reference point (reference region) P to the normal line LN₀ passing through the center of the light emitting region. The reference point (reference region) may include a certain extent of spread.

Such a form can have a configuration in which the light emitted from each light emitting element is focused (collected) to a certain region of the space outside the display device, a configuration in which the light emitted from each light emitting element diverges in the space outside the display device, or a configuration in which the light emitted from each light emitting element is parallel light.

Whether the light (image) emitted from the entire display device is a focusing system or a diverging system depends on the specification of the display device, and also depends on how much viewing angle dependency and wide viewing angle characteristic are required for the display device.

The distance D₀ may be changed in the subpixels constituting one pixel. That is, the distance D₀ may be changed in the plurality of light emitting elements constituting one pixel. For example, when one pixel is composed of three subpixels, the value of D₀ may be the same value in the three subpixels constituting one pixel, may be the same value in two subpixels except for one subpixel, or may be different values in the three subpixels.

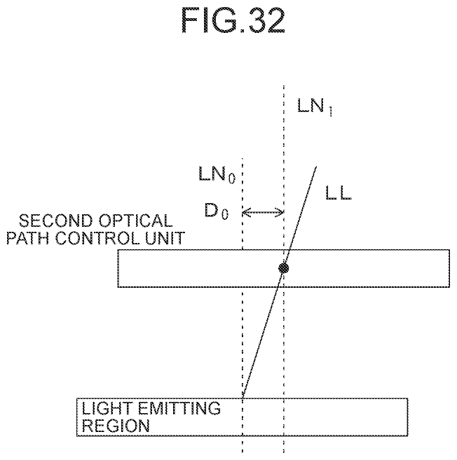

As illustrated in the conceptual diagram of FIG. 32, in the display device of Example 7, when the distance (offset amount) between the normal line LN₀ passing through the center of the light emitting region and the normal line LN₁ passing through the center of the second optical path control unit 72 is D₀, the value of the distance (offset amount) D₀ is not 0 in at least some of the light emitting elements 10 constituting the display device. The straight line LL is a straight line connecting the center of the light emitting region and the center of the second optical path control unit 72.

The display device may have a form in which the reference point (reference region) P is assumed, and the distance D₀ depends on the distance D₁ from the reference point (reference region) P to the normal line LN₀ passing through the center of the light emitting region. The reference point (reference region) may include a certain extent of spread. These various normal lines are perpendicular lines to the light emission surface of the display device.

The image display area (display panel) of the display device of Example 7 including the above preferable form may have a configuration in which the reference point P is assumed in the display panel. In this case, a configuration may be taken in which the reference point P is not located in (not included in) the central region of the display panel or in which the reference point P is located in the central area of the display panel. Further, in these cases, one reference point P may be assumed, or a plurality of reference points P may be assumed. In these cases, a configuration may be taken in which the value of the distance D₀ is 0 in some light emitting elements, and the value of the distance D₀ is not 0 in the other light emitting elements.

When one reference point P is assumed in the display device of Example 7 including the above preferable form, a configuration may be taken in which the reference point P is not included in the central region of the display panel, or a configuration may be taken in which the reference point P is included in the central region of the display panel. When a plurality of reference points P are assumed, a configuration may be taken in which at least one reference point P is not included in the central region of the display panel.

Alternatively, the reference point P may be assumed to be outside the display panel. In this case, one reference point P may be assumed, or a plurality of reference points P may be assumed. In these cases, a configuration may be taken in which the value of the distance D₀ is not 0 in any of the light emitting elements.

Further, in the display device of Example 7, the value of the distance (offset amount) D₀ may be different according to the location occupied by the light emitting element in the display panel. Specifically, a form may be taken in which
a reference point P is set, and
a plurality of light emitting elements are arrayed in a first direction and a second direction different from the first direction,
when a distance from the reference point P to a normal line LN₀ passing through the center of a light emitting region is D₁, values of the distance D₀ in the first direction and the second direction are D_{0-X} and D_{0-Y}, respectively, and values of the distance D₁ in the first direction and the second direction are D_{1-X} and D_{1-Y}, respectively,
D_{0-X} changes linearly with respect to a change of D_{1-X}, and D_{0-Y} changes linearly with respect to a change of D₁-Y, or
D_{0-X} changes linearly with respect to a change of D_{1-X}, and D_{0-Y} changes nonlinearly with respect to a change of D_{1-Y}, or
D_{0-X} changes nonlinearly with respect to a change of D_{1-X}, and D_{0-Y} changes linearly with respect to a change of D₁-Y, or
D_{0-X} changes nonlinearly with respect to a change of D_{1-X}, and D_{0-Y} changes nonlinearly with respect to a change of D₁-Y.

The value of the distance D₀ may increase as the value of the distance D₁ increases. That is, in the display device of Example 7, a form may be taken in which
a reference point P is set, and
when a distance from the reference point P to a normal line LN₀ passing through the center of a light emitting region is D₁, a value of the distance D₀ increases as a value of the distance D₁ increases.

Here, the fact that D_{0-X} changes linearly with respect to a change of D_{1-X}, and D_{0-Y} changes linearly with respect to a change of D_{1-Y} means that

$${D}_{0 - X} = {k}_{X} \cdot {D}_{1 - X}$$

$${D}_{0 - Y} = {k}_{Y} \cdot {D}_{1 - Y}$$

are formed. Here, k_{X} and k_{Y} are constants. That is, D_{0-X} and D_{0-Y} change based on a linear function. On the other hand, the fact that D_{0-X} changes nonlinearly with respect to a change of D_{1-X}, and D_{0-Y} changes linearly with respect to a change of D_{1-Y} means that

$${D}_{0 - X} = {f}_{X} ( {D}_{1 - X} )$$

$${D}_{0 - Y} = {k}_{Y} ( {D}_{1 - Y} )$$

are formed. Here, f_{X}, f_{Y} are functions that are not linear functions (for example, a quadratic function).

The change of D_{0-X} with respect to a change of D_{1-X} and the change of D_{0-Y} with respect to a change of D_{1-Y} may also be stepwise changes. In this case, when the stepwise change is viewed as a whole, the change may be a linear change, or the change may be a non-linear change. Further, when the display panel is divided into M×N regions, the change of D_{0-X} with respect to a change of D_{1-X} and the change of D_{0-Y} with respect to a change of D_{1-Y} may be unchanged or constant in one region. The number of light emitting elements in one region may be, but is not limited to, 10×10.

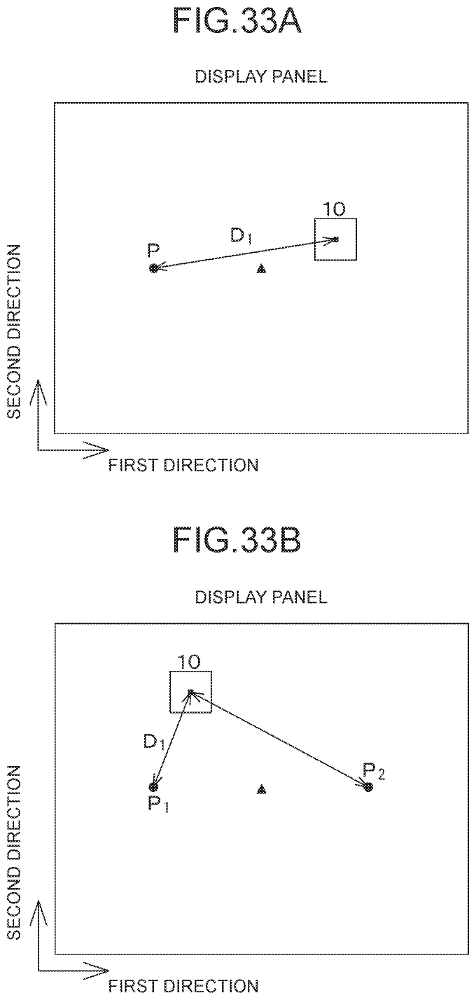

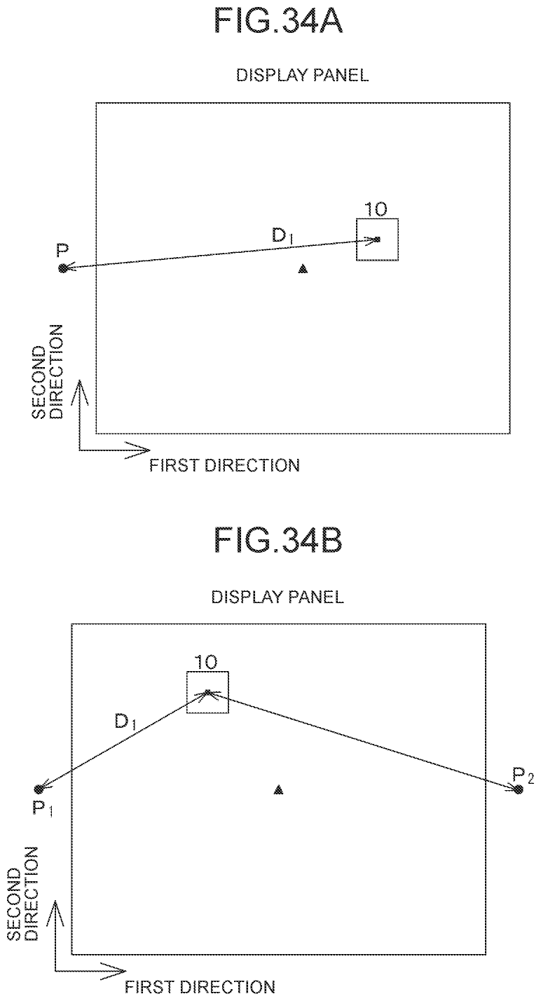

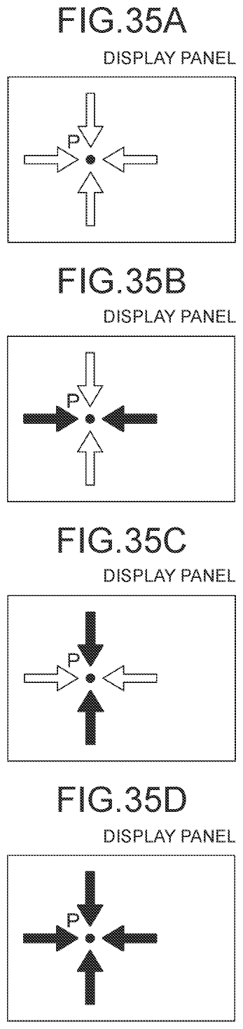

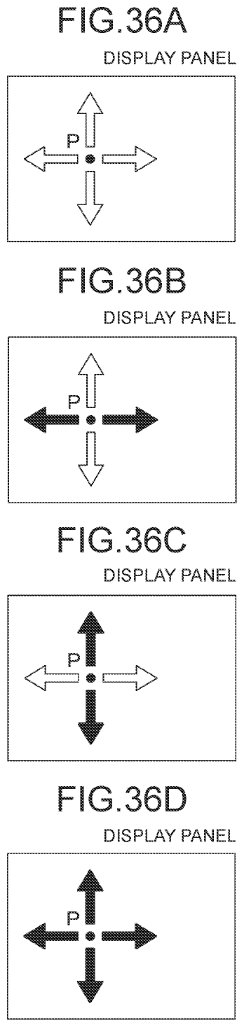

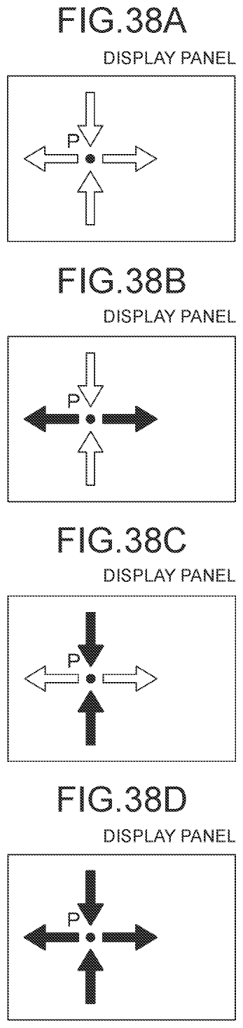

FIGS. 33A and 33B and FIGS. 34A and 34B are schematic diagrams each illustrating a positional relationship between a light emitting element and the reference point in the display device of Example 7, and FIGS. 35A, 35B, 35C, and 35D, 36A, 36B, 36C, and 36D, 37A, 37B, 37C, and 37D, and FIGS. 38A, 38B, 38C, and 38D are schematic diagrams each illustrating the change in Dox with respect to a change in D_{1-X} and a change in D_{0-Y} with respect to a change in D_{1-Y}.

In the display device of Example 7 in the conceptual diagrams of FIGS. 33A and 33B, the reference point P is assumed in the display device. That is, an orthographic projection image of the reference point P is included in the image display region (display panel) of the display device, but the reference point P is not located in the central region of the display device (image display region of the display device, display panel). In FIGS. 33A, 33B, 34A, and 34B, the central region of the display panel is indicated by a black triangle, the light emitting element is indicated by a white square, and the center of the light emitting region is indicated by a black square. Then, one reference point P is assumed. The positional relationship between the light emitting element 10 and the reference point P is schematically illustrated in FIGS. 33A, 33B, in which the reference point P is indicated by a black circle. One reference point P is assumed in FIG. 33A, and a plurality of reference points P (two reference points P₁, P₂ are illustrated in FIG. 33B) is assumed in FIG. 33B. Since the reference point P may include a certain extent of spread, the value of the distance D₀ is 0 in some light emitting elements (specifically, one or a plurality of light emitting elements included in the orthographic projection image of the reference point P), and the value of the distance D₀ is not 0 in the other light emitting elements. The value of the distance (offset amount) D₀ varies depending on the location occupied by the light emitting element in the display panel.

In the display device of Example 7, light emitted from each light emitting element 10 is focused (collected) to a certain region in a space outside the display device. Alternatively, light emitted from each light emitting element 10 diverges in a space outside the display device. Alternatively, light emitted from each light emitting element 10 is parallel light. Whether the light emitted from the display device is focused light, divergent light, or parallel light is based on the specifications required for the display device. Based on the specifications, the power and the like of the first optical path control unit 71 and the second optical path control unit 72 may be designed. When light emitted from each light emitting element is focused light, the location of the space in which the image emitted from the display device is formed may be on the normal line of the reference point P or is not on the normal line of the reference point P in some cases, which depends on the specifications required for the display device. An optical system through which the image emitted from the display device passes may be disposed to control the display dimension, the display location, and the like of the image emitted from the display device. What kind of optical system is disposed depends on the specifications required for the display device, and an imaging lens system may be given as an example.

In the display device of Example 7, the reference point P is set, and the plurality of light emitting elements 10 are arrayed in a first direction (specifically, X direction) and a second direction (specifically, Y direction) different from the first direction. When the distance from the reference point P to the normal line LN₀ passing through the center of the light emitting region is D₁, values of the distance D₀ in the first direction (X direction) and the second direction (Y direction) are D_{0-X} and D_{0-Y}, respectively, and values of the distance D₁ in the first direction (X direction) and the second direction (Y direction) are D_{1-X} and D_{1-Y}, respectively, the display device may have
[A] a design in which D_{0-X} changes linearly with respect to a change of D_{1-X}, and D_{0-Y} changes linearly with respect to a change of D_{1-Y},
[B] a design in which D_{1-X} changes linearly with respect to a change of D_{1-X}, and D_{0-Y} changes nonlinearly with respect to a change of D_{1-X},
[C] a design in which D_{0-X} changes nonlinearly with respect to a change of D_{1-X}, and D_{0-Y} changes linearly with respect to a change of D_{1-Y}, or
[D] a design in which D_{1-X} changes nonlinearly with respect to a change of D_{1-X}, and D_{0-Y} changes nonlinearly with respect to a change of D_{1-Y}.

FIGS. 35A, 35B, 35C, 35D, 36A, 36B, 36C, 36D, 37A, 37B, 37C, 37D, 38A, 38B, 38C, and 38D schematically illustrate a change of D_{0-X} with respect to a change of D_{1-X} and a change of D_{0-Y} with respect to a change of D_{1-Y}. In these drawings, outlined arrows indicate linear changes and black arrows indicate non-linear changes. When the arrows are directed to the outside of the display panel, it indicates that light passing through the optical path control units 71, 72 is divergent light, and when the arrows are directed to the inside of the display panel, it indicates that light passing through the optical path control units 71, 72 is focused light or parallel light.

Alternatively, when the reference point P is set and the distance from the reference point P to the normal line LN₀ passing through the center of the light emitting region is D₁, the value of the distance D₀ may be designed to increase as the value of the distance D₁ increases.

That is, the changes of D_{0-X}, D_{0-Y} depending on the changes of D_{1-X}, D_{1-Y} may be determined based on the specifications required for the display device.

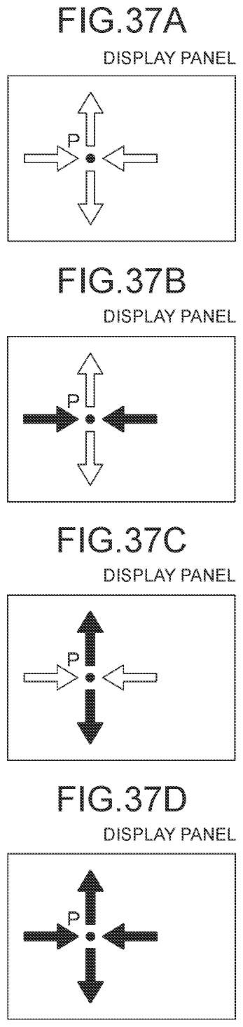

The orthogonal projection image of the second optical path control unit 72 is included in the orthogonal projection images of the wavelength selection units CF_{R}, CF_{G}, and CF_{B}. The outer shapes of the light emitting unit 30, the wavelength selection unit CF, the optical path control units 71, 72 are circular for the sake of convenience, but they are not limited to such shapes. Further, in the light emitting element 10 in which the value of the distance D₀ is not 0, the normal line LN₂ passing through the centers of the wavelength selection units CF_{R}, CF_{G}, CFs matches up with the normal line LN₀ passing through the center of the light emitting region, as illustrated in FIG. 37B, for example.

In a preferred form of the display device of Example 7, when the distance (offset amount) between the normal line LN₀ passing through the center of the light emitting region and the normal line LN; passing through the center of the second optical path control unit 72 is D₀, the value of the distance D₀ is not 0 in at least some of the light emitting elements constituting the display device, and thus, it is possible to reliably and accurately control the traveling direction of light emitted from the organic layer and passing through the optical path control units depending on the position of the light emitting element in the display device. That is, it is possible to reliably and accurately control where in the external space to emit an image from the display device and in what state. In addition, by providing the optical path control units, not only an increase in brightness (luminance) of an image emitted from the display device and prevention of color mixture between adjacent pixels can be achieved, but also light can be appropriately diverged according to a required viewing angle, and it is possible to realize a long life and high luminance of the light emitting element and the display device. Thus, it is possible to achieve miniaturization, weight reduction, and high quality of the display device. Further, it can be applied to a remarkably expanded range of eyewear, augmented reality (AR) glasses, and EVR.

Alternatively, in a modification of the display device of Example 7, the reference point P is assumed to be outside the display panel. FIGS. 34A and 34B schematically illustrate the positional relationship between the light emitting element 10 and the reference points P, P₁, P₂. However, one reference point P may be assumed (see FIG. 34A), or a plurality of reference points P (two reference points P₁, P₂ are illustrated in FIG. 34B) may be assumed. With the center of the display panel as a symmetry point, the two reference points P₁, P₂ are arranged in two-fold rotational symmetry. Here, at least one reference point P is not included in the center region of the display panel. In the illustrated example, two reference points P₁, P₂ are not included in the center region of the display panel. The value of the distance D₀ is 0 in some light emitting elements (specifically, one or a plurality of light emitting elements included in the reference point P), and the value of the distance D₀ is not 0 in the other light emitting elements. For the distance D₁ from the reference point P to the normal line LN₀ passing through the center of the light emitting region, the distance between the reference point P closer to the normal line LN₀ passing through the center of a certain light emitting region is defined as the distance D₁. Alternatively, the value of the distance D₀ is not 0 in any of the light emitting elements. For the distance D₁ from the reference point P to the normal line LN₀ passing through the center of the light emitting region, the distance between the reference point P closer to the normal line LN₀ passing through the center of a certain light emitting region is defined as the distance D₁. In these cases, light emitted from the light emitting unit 30 constituting each light emitting element 10 and passing through the optical path control units 71, 72 is focused (collected) in a certain region of the space outside the display device. Alternatively, light emitted from the light emitting unit 30 constituting each light emitting element 10 and passing through the optical path control units 71, 72 diverges in the space outside the display device.

### Example 8

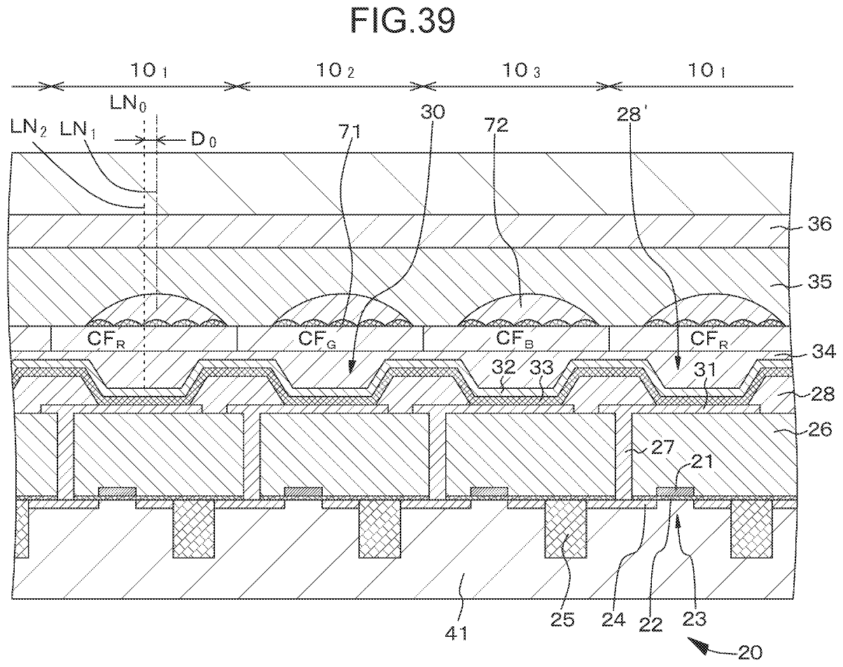

Example 8 is a modification of Examples 1 to 7. FIG. 39 is a schematic and partial sectional view of a light emitting element and a display device of Example 8.

In Example 8, an arrangement relationship of the light emitting region, the wavelength selection unit CF, and the second optical path control unit 72 will be described. Here, in a light emitting element in which the value of the distance D₀ is not 0 may have,
(a) a form in which the normal line LN₂ passing through the center of the wavelength selection unit CF matches up with the normal line LN₀ passing through the center of the light emitting region,
(b) a form in which the normal line LN₂ passing through the center of the wavelength selection unit CF matches up with the normal line LN; passing through the center of the second optical path control unit 72, and
(c) a form in which the normal line LN₂ passing through the center of the wavelength selection unit CF does not match up with the normal line LN₀ passing through the center of the light emitting region, and the normal line LN₂ passing through the center of the wavelength selection unit CF does not match up with the normal line LN₁ passing through the center of the second optical path control unit 72. By adopting (b) or (c) the latter configuration, occurrence of color mixture between adjacent light emitting elements can be reliably reduced.

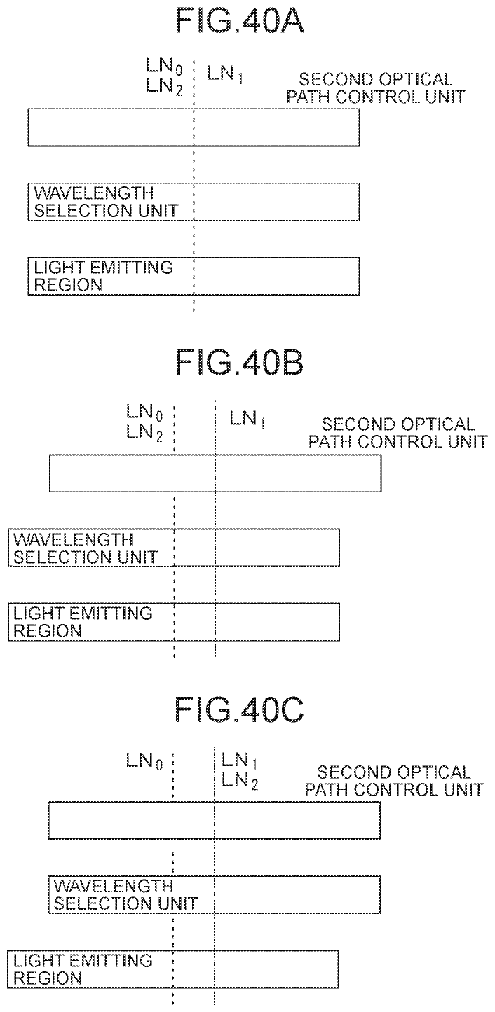

As illustrated in the conceptual diagram of FIG. 40A, the normal line LN₀ passing through the center of the light emitting region, the normal line LN₂ passing through the center of the wavelength selection unit CF, and the normal line LN; passing through the center of the second optical path control unit 72 may match up with each other. That is, D₀=d₀=0. As described above, do is the distance (offset amount) between the normal line LN₀ passing through the center of the light emitting region and the normal line LN₂ passing through the center of the wavelength selection unit.

For example, when one pixel is composed of three subpixels, the values of do, D₀ may be the same value in the three subpixels constituting one pixel, may be the same value in two subpixels except for one subpixel, or may be different values in the three subpixels.

As illustrated in the conceptual diagram of FIG. 40B, the normal line LN₀ passing through the center of the light emitting region matches up with the normal line LN₂ passing through the center of the wavelength selection unit CF, but the normal line LN₀ passing through the center of the light emitting region and the normal line LN₂ passing through the center of the wavelength selection unit CF do not match up with the normal line LN; passing through the center of the second optical path control unit 72 in some cases. That is, D₀≠d₀=0.

Further, as illustrated in the conceptual diagram of FIG. 40C, the normal line LN₀ passing through the center of the light emitting region does not match up with the normal line LN₂ passing through the center of the wavelength selection unit CF or the normal line LN; passing through the center of the second optical path control unit 72, and the normal line LN₂ passing through the center of the wavelength selection unit CF matches up with the normal line LN₁ passing through the second optical path control unit 72 in some cases. That is, D₀=d₀>0.

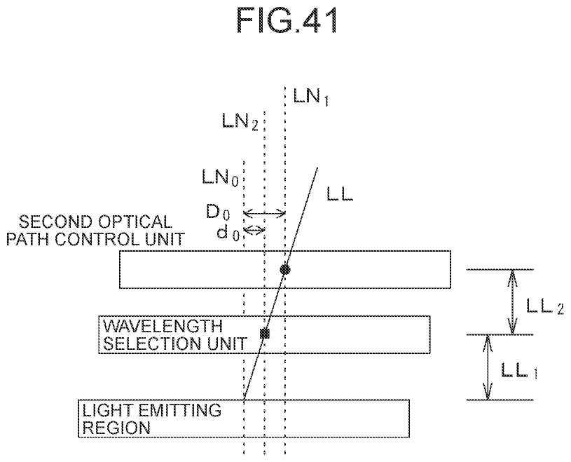

Further, as illustrated in the conceptual diagram of FIG. 41, the normal line LN₀ passing through the center of the light emitting region does not match up with the normal line LN₂ passing through the center of the wavelength selection unit CF or the normal line LN₁ passing through the center of the second optical path control unit 72, and the normal line LN; passing through the center of the second optical path control unit 72 does not match up with the normal line LN₀ passing through the center of the light emitting region or the normal line LN₂ passing through the center of the wavelength selection unit CF in some cases. Here, the center (indicated by a black square in FIG. 41) of the wavelength selection unit CF is preferably located on the straight line LL connecting the center of the light emitting region and the center (indicated by a black circle in FIG. 41) of the second optical path control unit 72. Specifically, when the distance in the thickness direction from the center of the light emitting region to the center of the wavelength selection unit CF is LL₁, and the distance in the thickness direction from the center of the wavelength selection unit CF to the center of the second optical path control unit 72 is LL₂,

$${D}_{0} > {d}_{0} > 0$$

is satisfied, and considering variations in production,

$${d}_{0} : {D}_{0} = {LL}_{1} : ( {LL}_{1} + {LL}_{2} )$$

is preferably satisfied.

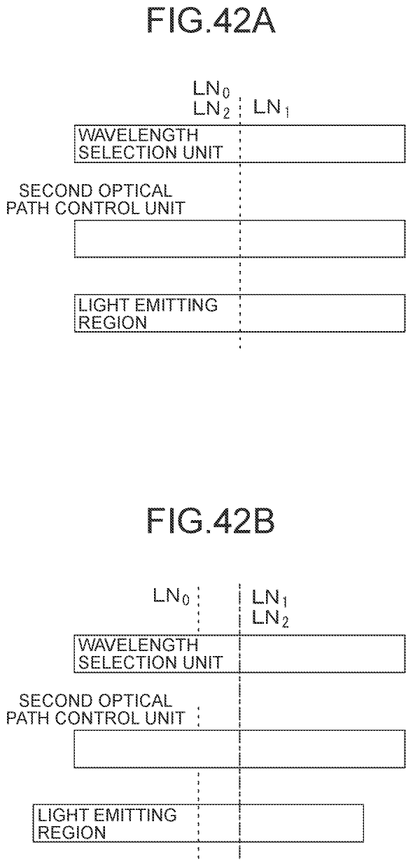

Alternatively, as illustrated in the conceptual diagram of FIG. 42A, the normal line LN₀ passing through the center of the light emitting region, the normal line LN₂ passing through the center of the wavelength selection unit CF, and the normal line LN₁ passing through the center of the second optical path control unit 72 match up with each other in some cases. That is, D₀=d₀=0.

Further, as illustrated in the conceptual diagram of FIG. 42B, the normal line LN₀ passing through the center of the light emitting region does not match up with the normal line LN₂ passing through the center of the wavelength selection unit CF or the normal line LN₁ passing through the center of the second optical path control unit 72, and the normal line LN₂ passing through the center of the wavelength selection unit CF and the normal line LN₁ passing through the center of the second optical path control unit 72 match up with each other in some cases. That is, D₀=d₀>0.

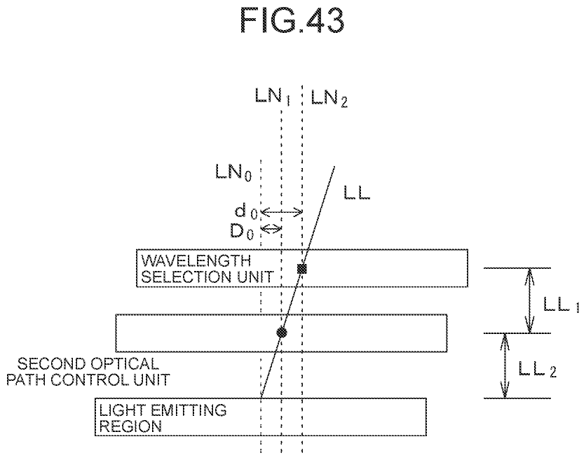

Further, as illustrated in the conceptual diagram of FIG. 43, the normal line LN₀ passing through the center of the light emitting region does not match up with the normal line LN₂ passing through the center of the wavelength selection unit CF or the normal line LN; passing through the center of the second optical path control unit 72, and the normal line LN; passing through the second optical path control unit 72 does not match up with the normal line LN₀ passing through the center of the light emitting region or the normal line LN₂ passing through the center of the wavelength selection unit CF in some cases. Here, the center of the wavelength selection unit CF is preferably located on the straight line LL connecting the center of the light emitting region and the center of the second optical path control unit 72. Specifically, when the distance in the thickness direction from the center of the light emitting region to the center (indicated by a black square in FIG. 43) of the wavelength selection unit CF is LL₁, and the distance in the thickness direction from the center of the wavelength selection unit CF to the center (indicated by a black circle in FIG. 43) of the second optical path control unit 72 is LL₂,

$${d}_{0} > {D}_{0} > 0$$

is satisfied, and considering variations in production,

$${D}_{0} : {d}_{0} = {LL}_{2} : ( {LL}_{1} + {LL}_{2} )$$

is preferably satisfied.

The present disclosure has been described above based on preferred Examples. The present disclosure is not limited to these Examples. The configurations and structures of the display device (organic EL display device) and the light emitting element (organic EL element) described in Examples are examples and may be appropriately changed, and the production methods of the light emitting element and the display device are also examples and may be appropriately changed.

The number of second optical path control units for one pixel can essentially take any number, and the number is one or more. For example, when one pixel is composed of a plurality of subpixels, one second optical path control unit may be provided corresponding to one subpixel, one second optical path control unit may be provided corresponding to a plurality of subpixels, or a plurality of second optical path control units may be provided corresponding to one subpixel. When p×q of second optical path control units are provided corresponding to one subpixel, the values of p, q may be 10 or less, 5 or less, or 2 or less.

Examples have
(A) a from in which the first optical path control unit 71 and the second optical path control unit 72 each of which consists of a plano-convex lens having a convex shape in a direction away from the light emitting units 30, 30′,
or
(D) a form in which the first optical path control unit 71 consists of a plano-convex lens having a convex shape in a direction toward the light emitting units 30, 30′, and the second optical path control unit 72 consists of a plano-convex lens having a convex shape in a direction toward the light emitting units 30, 30′,
and
(E) a form in which the first optical path control unit 71 and the third optical path control unit 73 each of which consists of a plano-convex lens having a convex shape in a direction away from the light emitting units 30, 30′,
(H) a form in which the first optical path control unit 71 consists of a plano-convex lens having a convex shape in a direction toward the light emitting units 30, 30′, and the third optical path control unit 73 consists of a plano-convex lens having a convex shape in a direction toward the light emitting units 30, 30′.

However, the present invention is not limited to these forms and may take
(B) a form in which the first optical path control unit 71 consists of a plano-convex lens having a convex shape in a direction away from the light emitting units 30, 30′, and the second optical path control unit 72 consists of a plano-convex lens having a convex shape in a direction toward the light emitting units 30, 30′,
(C) a form in which the first optical path control unit 71 consists of a plano-convex lens having a convex shape in a direction toward the light emitting units 30, 30′, and the second optical path control unit 72 consists of a plano-convex lens having a convex shape in a direction away from the light emitting units 30, 30′,
(F) a form in which the first optical path control unit 71 consists of a plano-convex lens having a convex shape in a direction away from the light emitting units 30, 30′, and the third optical path control unit 73 consists of a plano-convex lens having a convex shape in a direction toward the light emitting units 30, 30′, or
(G) a form in which the first optical path control unit 71 consists of a plano-convex lens having a convex shape in direction toward the light emitting units 30, 30′, and the third optical path control unit 73 consists of a plano-convex lens having a convex shape in a direction away from the light emitting units 30, 30′.

In Examples, one pixel is mostly composed of three subpixels of a combination of a white light emitting element and a color filter layer, but for example, one pixel may be composed of four subpixels including a light emitting element that emits white light. Alternatively, the light emitting elements may be a red light emitting element in which the organic layer generates red, a green light emitting element in which the organic layer generates green, and a blue light emitting element in which the organic layer generates blue, and one pixel may be composed of a combination of these three types of light emitting elements (subpixels). In Examples, the light emitting element drive unit (drive circuit) is composed of a MOSFET, but it may be composed of a TFT. The first electrode and the second electrode may have a single-layer structure or a multilayer structure.

A light shielding unit may be provided between the light emitting elements to prevent light emitted from a light emitting unit constituting a certain light emitting element from entering a light emitting element adjacent to the certain light emitting element to cause optical crosstalk. That is, a groove may be formed between the light emitting elements, and the light shielding unit may be formed by embedding the groove with a light shielding material. With the light shielding unit provided in this manner, it is possible to reduce probability of entering of light emitted from a light emitting unit constituting a certain light emitting element into an adjacent light emitting element, and it is possible to reduce occurrence of a phenomenon in which color mixture occurs and chromaticity of the entire pixel deviates from desired chromaticity. Then, since color mixture can be prevented, the color purity when the pixel emits light in a single color is increased, and the chromaticity point is deepened. Thus, the color gamut is widened, and the range of color representation of the display device is widened. Specific examples of the light shielding material constituting the light shielding unit include materials capable of shielding light, such as titanium (Ti), chromium (Cr), tungsten (W), tantalum (Ta), aluminum (Al), and MoSi₂. The light shielding layer may be formed by vapor deposition methods including an electron beam vapor deposition method, a hot filament vapor deposition method, and a vacuum vapor deposition method, sputtering methods, CVD methods, ion plating methods, and the like. In addition, the color filter layer disposed for each pixel to improve the color purity may be thinned or omitted depending on the configuration of the light emitting element, which enables light absorbed in the color filter layer to be extracted, resulting in improvement in the light emission efficiency. Alternatively, a light shielding property may be imparted to the black matrix layer BM.

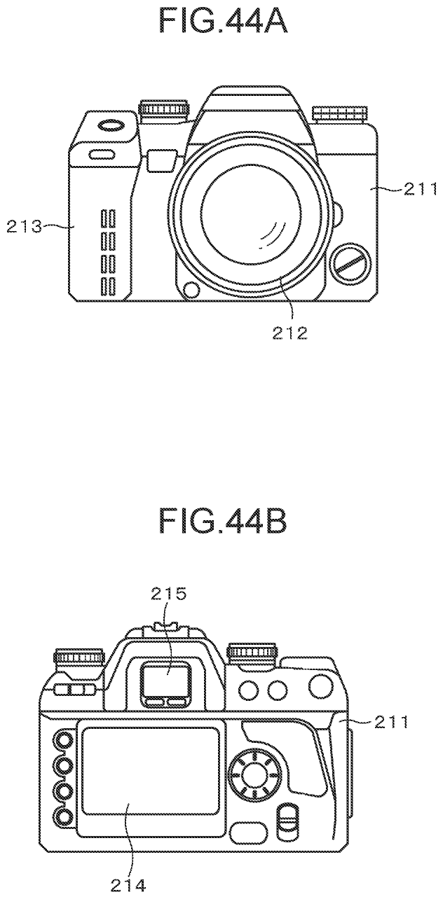

The display device of the present disclosure may be applied to a mirrorless interchangeable lens digital still camera. FIG. 44A is a front view of a digital still camera. FIG. 44B is a back view of the digital still camera. This mirrorless interchangeable lens digital still camera includes, for example, an interchangeable imaging lens unit (interchangeable lens) 212 on the front right side of a camera body 211, and a grip 213 to be held by a photographer on the front left side. A monitor device 214 is provided substantially at the center of the back surface of the camera body 211. An electronic view finder (eyepiece window) 215 is provided above the monitor device 214. The photographer can visually recognize an optical image of a subject guided from the imaging lens unit 212 and determine a composition by looking into the electronic view finder 215. The display device of the present disclosure can be used as the electronic view finder 215 in a mirrorless interchangeable lens digital still camera having such a configuration.

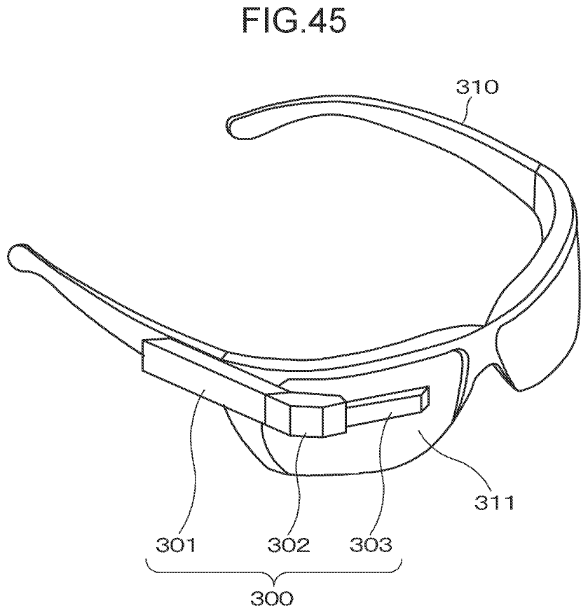

The display device of the present disclosure may also be applied to a head mounted display. As illustrated in the external view of FIG. 45, a head mounted display 300 is composed of a transmissive head mounted display including a main body 301, an arm 302, and a lens barrel 303. The main body 301 is connected to the arm 302 and eyeglasses 310. Specifically, an end of the main body 301 in a long side direction is attached to the arm 302. One side surface of the main body 301 is connected to the eyeglasses 310 via a connection member (not illustrated). The main body 301 may be directly mounted on the head of a human body. The main body 301 incorporates a control board and a display unit for controlling the operation of the head mounted display 300. The arm 302 connects the main body 301 and the lens barrel 303 to support the lens barrel 303 with respect to the main body 301. Specifically, the arm 302 is coupled to an end of the main body 301 and an end of the lens barrel 303 to fix the lens barrel 303 to the main body 301. The arm 302 incorporates a signal line for communicating data related to an image provided from the main body 301 to the lens barrel 303. The lens barrel 303 projects image light provided from the main body 301 via the arm 302 toward the eyes of a user wearing the head mounted display 300 through a lens 311 of the eyeglasses 310. The display device of the present disclosure can be used as the display unit incorporated in the main body 301 in the head mounted display 300 having the above configuration.

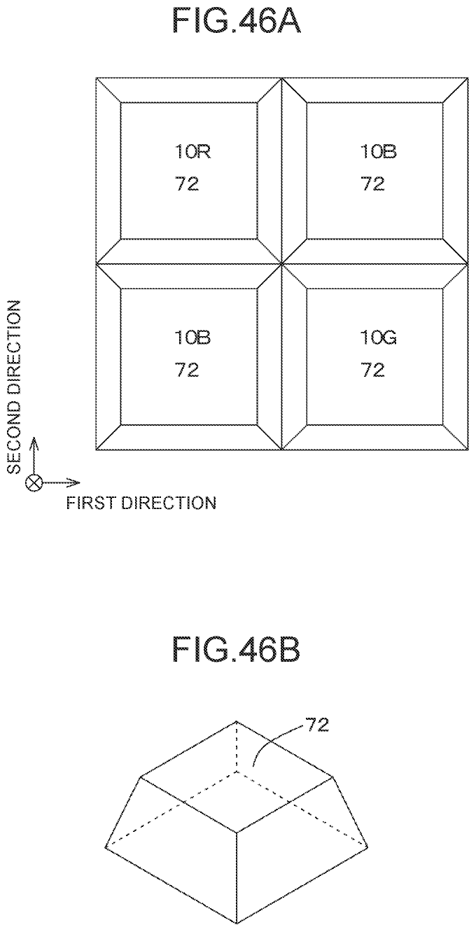

In Examples, the planar shapes of the optical path control units 71, 72 are circle shapes, but the shapes are not limited to circle shapes. As illustrated in FIGS. 46A, 46B, the lens member may be a truncated quadrangular pyramid. FIG. 46A is a schematic plan view of the second optical path control unit (second lens member) 72 having a truncated quadrangular pyramid shape, and FIG. 46B is a schematic perspective view thereof. The illustration of the first optical path control unit (first lens member) 71 is omitted.

The optical path control units may include a light emission direction control member described below.

To increase the light use efficiency of the entire display device, it is preferable to effectively collect light at the outer edge of the light emitting element. However, in a hemispherical lens, although the effect of collecting light near the center of the light emitting element to the front is large, the effect of collecting light near the outer edge of the light emitting element may be small.

Side surfaces of a first light emission direction control member and a second light emission direction control member (hereinafter, the first light emission direction control member and the second light emission direction control member may be collectively referred to as “light emission direction control members”) constituting the first optical path control unit and the second optical path control unit are surrounded by a material or layer (covering layer) having a refractive index n₂ lower than the refractive index m₁ of the material constituting the light emission direction control members. Alternatively, the first optical path control unit made of the material having the refractive index m₁ is surrounded by the second optical path control unit made of the material having the refractive index n₂. Thus, the light emission direction control members have a function as a kind of lens, and can effectively enhance the light collection effect in the vicinity of the outer edge of the light emission direction control members. In geometrical optics, when a light beam is incident on a side surface of the light emission direction control members, the incident angle and the reflection angle become equal, and thus it is difficult to improve the extraction of light in the front direction. However, in wave motion analysis (FDTD), the light extraction efficiency in the vicinity of the outer edge of the light emission direction control members improves. Thus, light in the vicinity of the outer edge of the light emitting element can be effectively collected, and as a result, the light extraction efficiency in the front direction of the entire light emitting element can improve. This can achieve high light emission efficiency of the display device. That is, it is possible to realize high luminance and low power consumption of the display device. In addition, since the light emission direction control members have a flat plate shape, it is easy to form the light emission direction control members, and the production process can be simplified.

Specifically, examples of the three-dimensional shape of the light emission direction control members include a columnar shape, an elliptical columnar shape, an oval columnar shape, a cylindrical shape, a prismatic shape (including a hexagonal prism, an octagonal prism, and a prism with rounded ridges), a truncated conical shape, and a truncated pyramidal shape (including a truncated pyramidal shape with rounded ridges). The prism shape and the truncated pyramid shape include a regular prism shape and a regular truncated pyramid shape. The ridge part where a side surface of the light emission direction control members intersects the top surface may be rounded. The bottom surface of the truncated pyramid may be located on the first substrate side or on the second electrode side. Specific examples of the planar shape of the light emission direction control members include a circle, an ellipse, an oval, and a polygon including a triangle, a quadrangle, a hexagon, and an octagon. The polygon includes a regular polygon (including a regular polygon such as a rectangle or a regular hexagon (honeycomb shape)). The light emission direction control members may be made of, for example, a transparent resin material such as an acrylic resin, an epoxy resin, a polycarbonate resin, or a polyimide resin, or a transparent inorganic material such as SiO₂.

The sectional shape of the side surfaces of the light emission direction control members in the thickness direction may be linear, convexly curved, or concavely curved. That is, the side surfaces of the prism or the truncated pyramid may be flat, convexly curved, or concavely curved.

A first light emission direction control member extending unit having a thickness smaller than that of the first light emission direction control member may be formed between the first light emission direction control member and the first light emission direction control member adjacent to each other. A second light emission direction control member extending unit having a thickness smaller than that of the second light emission direction control member may be formed between the second light emission direction control member and the second light emission direction control member adjacent to each other.

The top surface of the light emission direction control members may be flat, may have an upward convex shape, or may have an upward concave shape, but from the viewpoint of improving the luminance in the front direction of the image display region (display panel) of the display device, the top surface of the light emission direction control members is preferably flat. The light emission direction control members may be obtained by, for example, a combination of a photolithography technique and an etching method or may be formed based on a nanoimprint method.

The sizes of the planar shapes of the light emission direction control members may be changed depending on the light emitting element. For example, when one pixel is composed of three subpixels, the sizes of the planar shapes of the light emission direction control members may have the same value in the three subpixels constituting one pixel, may have the same value in two subpixels except for one subpixel, or may have different values in the three subpixels. The refractive index of the material constituting the light emission direction control members may also be changed depending on the light emitting element. For example, when one pixel is composed of three subpixels, the refractive index of the material constituting the light emission direction control members may have the same value in the three subpixels constituting one pixel, may have the same value in two subpixels except for one subpixel, or may have different values in the three subpixels.

The planar shape of the second light emission direction control member is preferably similar to the light emitting region, or the light emitting region is preferably included in an orthogonal projection image of the second light emission direction control member.

The side surfaces of the light emission direction control members are preferably vertical or substantially vertical. Specifically, examples of the inclination angle of the side surfaces of the light emission direction control members may include 80 degrees to 100 degrees, preferably 81.8 degrees or more and 98.2 degrees or less, more preferably 84.0 degrees or more and 96.0 degrees or less, still more preferably 86.0 degrees or more and 94.0 degrees or less, particularly preferably 88.0 degrees or more and 92.0 degrees or less, and most preferably 90 degrees.

Examples of the average height of the second light emission direction control member may include 1.5 μm or more and 2.5 μm or less, with which the light collection effect in the vicinity of the outer edge of the second light emission direction control member can be effectively enhanced. The height of the second light emission direction control member may be changed depending on the light emitting element. For example, when one pixel is composed of three subpixels, the height of the second light emission direction control member may have the same value in the three subpixels constituting one pixel, may have the same value in two subpixels except for one subpixel, or may have different values in the three subpixels.

The shortest distance between the side surfaces of adjacent light emission direction control members may be 0.4 μm or more and 1.2 μm or less, preferably 0.6 μm or more and 1.2 μm or less, more preferably 0.8 μm or more and 1.2 μm or less, and still more preferably 0.8 μm or more and 1.0 μm or less. By defining the minimum value of the shortest distance between the side surfaces of adjacent light emission direction control members to be 0.4 μm, the shortest distance between the adjacent light emission direction control members can be set to be about the same as the lower limit value of the wavelength band of visible light, and thus it is possible to reduce the functional degradation of the material or layer surrounding the light emission direction control members, and as a result, it is possible to effectively enhance the light collection effect in the vicinity of the side surfaces of the light emission direction control members. On the other hand, by defining the maximum value of the shortest distance between the side surfaces of the adjacent light emission direction control members as 1.2 μm, the sizes of the light emission direction control members can be reduced, and as a result, the light collection effect in the vicinity of the side surfaces of the light emission direction control members can be effectively enhanced.

The distance between the centers of adjacent second light emission direction control members is preferably 1 μm or more and 10 μm or less. With the distance set to 10 μm or less, the wave property of the light remarkably appears, and thus a high light collection effect can be imparted to the second light emission direction control member.

The maximum distance (maximum distance in the height direction) from the light emitting region to the bottom surface of the second light emission direction control member is desirably more than 0.35 μm and 7 μm or less, preferably 1.3 μm or more and 7 μm or less, more preferably 2.8 μm or more and 7 μm or less, and still more preferably 3.8 μm or more and 7 μm or less. By defining the maximum distance from the light emitting region to the second light emission direction control member to be more than 0.35 μm, the light collection effect in the vicinity of the outer edge of the second light emission direction control member can be effectively enhanced. On the other hand, by defining the maximum distance from the light emitting region to the second light emission direction control member to be 7 μm or less, deterioration of the viewing angle characteristic can be reduced.

The number of second light emission direction control members for one pixel can essentially take any number, and the number is one or more. For example, when one pixel is composed of a plurality of subpixels, one second light emission direction control member may be provided corresponding to one subpixel, one second light emission direction control member may be provided corresponding to a plurality of subpixels, or a plurality of second light emission direction control members may be provided corresponding to one subpixel. When p×q of second light emission direction control members are provided corresponding to one subpixel, the values of p, q may be 10 or less, 5 or less, or 3 or less.

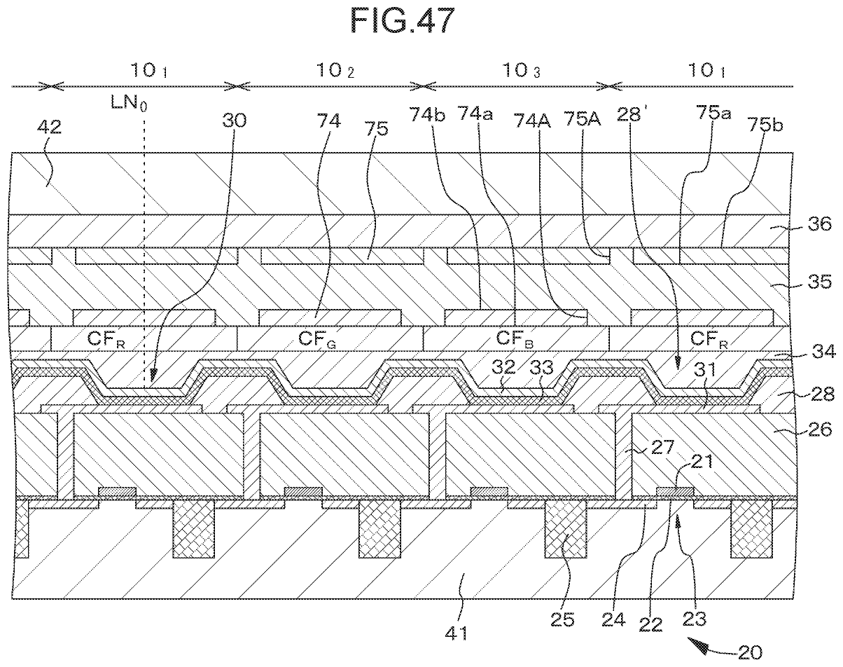

As illustrated in the schematic and partial sectional view of FIG. 47, light emission direction control members 74, 75 (first light emission direction control member 74 and second light emission direction control member 75), which are optical path control units, are provided above the light emitting units 30, 30′, specifically, at positions similar to those of the optical path control units 71, 72. When the light emission direction control members are cut along a virtual plane (vertical virtual plane) including a thickness direction of the light emission direction control members 74, 75, the sectional shapes of the light emission direction control members 74, 75 are rectangular. The three-dimensional shapes of the light emission direction control members 74, 75 are, for example, columnar. In the example illustrated in FIG. 47, since the first light emission direction control member 74 is surrounded by the second light emission direction control member 75, and the second light emission direction control member 75 is surrounded by the bonding member 35, the light emission direction control members 74, 75 have a function as a kind of lens, and the light collection effect in the vicinity of the outer edges of the light emission direction control members 74, 75 can be effectively enhanced, assuming that the refractive indexes of the materials constituting the light emission direction control members 74, 75 are n₁, n₂, and the refractive index of the material constituting the bonding member 35 is n₅ (n₅<n₂<n₁). Since the light emission direction control members 74, 75 have a flat plate shape, it is easy to form the light emission direction control members, and the production process can be simplified. The light emission direction control members 74, 75 may be surrounded by a material different from the material constituting the bonding member 35 as long as the refractive index condition (n₅<n₂<n₁) is satisfied. Alternatively, the light emission direction control members 74, 75 may be surrounded by, for example, an air layer or a decompression layer (vacuum layer). Light incident surfaces 74a, 75a and light emission surfaces 74b, 75b of the light emission direction control members 74, 75 are flat. Reference numerals 74A, 75A indicate side surfaces of the light emission direction control members 74, 75, respectively. The light emission direction control members 74, 75 can be applied to various Examples and modifications thereof. In such a case, the refractive index of the material surrounding the first light emission direction control member 74 and the refractive index of the material surrounding the second light emission direction control member 75 may be appropriately selected.

The present disclosure may also have the following configurations.

### [A01]<<Light Emitting Element>>

A light emitting element including:
a light emitting unit including one light emitting region;
a first optical path control unit group consisting of a plurality of first optical path control units formed above the light emitting unit; and
a second optical path control unit formed on or above the first optical path control unit group,
wherein
the first optical path control units and the second optical path control unit have positive optical power, and
light emitted from the light emitting unit and focused by the first optical path control units is further focused by the second optical path control unit.
   [A02] The light emitting element according to [A01], wherein an orthographic projection image of the first optical path control units is included in an orthographic projection image of the second optical path control unit.
   [A03] The light emitting element according to [A02], wherein the orthogonal projection image of the first optical path control units in the first optical path control units is located on an outer periphery of the orthogonal projection image of the second optical path control unit.
   [A04] The light emitting element according to any one of [A01] to [A03], wherein the first optical path control units and the second optical path control unit each of which consists of a plano-convex lens having a convex shape in a direction away from the light emitting unit.
   [A05] The light emitting element according to any one of [A01] to [A04], wherein
a wavelength selection unit is provided above the light emitting unit, and
the first optical path control units and the second optical path control unit are provided on or above the wavelength selection unit.
   [A06] The light emitting element according to [A05], wherein a third optical path control unit is provided between the wavelength selection unit and the first optical path control units.
   [A07] The light emitting element according to [A06], wherein one or a plurality of the third optical path control units are provided for each of the first optical path control units.
   [A08] The light emitting element according to [A05], wherein a third optical path control unit is provided beneath or below the wavelength selection unit.
   [A09] The light emitting element according to [A08], wherein one or more of the third optical path control units are provided for each of the first optical path control units.
   [A10] The light emitting element according to any one of [A01] to [A04], wherein a wavelength selection unit is provided between the first optical path control units and the second optical path control unit.
   [A11] The light emitting element according to [A10], wherein a third optical path control unit is provided beneath or below the first optical path control units.
   [A12] The light emitting element according to [A11], wherein one or a plurality of the third optical path control units are provided for each of the first optical path control units.
   [A13] The light emitting element according to any one of [A01] to [A04], wherein a wavelength selection unit is provided on or above the second optical path control unit.
   [A14] The light emitting element according to [A13], wherein a third optical path control unit is provided beneath or below the first optical path control unit.
   [A15] The light emitting element according to [A14], wherein one or a plurality of the third optical path control units are provided for each of the first optical path control units.

### [B01]<<Display Device>>

A display device including:
a first substrate; second substrate; and
a plurality of light emitting element units including a plurality of types of light emitting elements,
wherein
each light emitting element includes:
a light emitting unit provided above the first substrate and including one light emitting region,
a first optical path control unit group consisting of a plurality of first optical path control units formed above the light emitting unit; and
a second optical path control unit formed on or above the first optical path control unit group,
wherein
the first optical path control units and the second optical path control unit have positive optical power, and
light emitted from the light emitting unit and focused by the first optical path control units is further focused by the second optical path control unit.

### REFERENCE SIGNS LIST

10, 10₁, 10₂, 10₃ LIGHT EMITTING ELEMENT
20 TRANSISTOR
21 GATE ELECTRODE
22 GATE INSULATING LAYER
23 CHANNEL FORMATION REGION
24 SOURCE/DRAIN REGION
25 ELEMENT ISOLATION REGION
26 BASE
26A SURFACE OF BASE
27 CONTACT PLUG
28 INSULATING LAYER
28′ OPENING
29 RECESS
29A SLOPE OF RECESS
29B BOTTOM OF RECESS
30, 30′30₁, 30₂, 30₃ LIGHT EMITTING UNIT
31, 31₁, 31₂, 31₃ FIRST ELECTRODE
32, 32₁, 32₂, 32₃ SECOND ELECTRODE
33, 33₁, 33₂, 33₃ ORGANIC LAYER
34 PROTECTIVE LAYER (FLATTENING LAYER)
34A, 34B, 34D SECOND PROTECTIVE LAYER
34C, 34E THIRD PROTECTIVE LAYER
34F FOURTH PROTECTIVE LAYER
35 BONDING MEMBER
36 UNDERLAYER
36A SECOND UNDERLAYER
37, 37₁, 37₂, 37₃ LIGHT REFLECTION LAYER
38, 38′, 38₁, 38₂, 38₃, 38₁′, 38₂′, 38₃′ INTERLAYER INSULATING MATERIAL LAYER
39 UNDERLAYING FILM
41 FIRST SUBSTRATE
42 SECOND SUBSTRATE
61 MASK LAYER
62, 63, 64 RESIST LAYER
65 OPENING
71 FIRST OPTICAL PATH CONTROL UNIT
71a LIGHT INCIDENT SURFACE OF FIRST OPTICAL PATH CONTROL UNIT
71b LIGHT EMISSION SURFACE OF FIRST OPTICAL PATH CONTROL UNIT
72 SECOND OPTICAL PATH CONTROL UNIT
72a LIGHT INCIDENT SURFACE OF SECOND OPTICAL PATH CONTROL UNIT
72b LIGHT EMISSION SURFACE OF SECOND OPTICAL PATH CONTROL UNIT
73 THIRD OPTICAL PATH CONTROL UNIT
74, 75 LIGHT EMISSION DIRECTION CONTROL MEMBER
74a, 75a LIGHT INCIDENT SURFACE OF LIGHT EMISSION DIRECTION CONTROL MEMBER
74b, 75b LIGHT EMISSION SURFACE OF LIGHT EMISSION DIRECTION CONTROL MEMBER
211 CAMERA BODY
212 PHOTOGRAPHING LENS UNIT (INTERCHANGEABLE LENS)
213 GRIP
214 MONITOR DEVICE
215 ELECTRONIC VIEW FINDER (EYEPIECE WINDOW)
300 HEAD MOUNTED DISPLAY
301 MAIN BODY
302 ARM
303 LENS BARREL
310 EYEGLASSES
CF, CF_{R}, CF_{G}, CF_{B} WAVELENGTH SELECTION UNIT (COLOR FILTER LAYER)
TF TRANSPARENT FILTER LAYER
BM BLACK MATRIX LAYER
LN₀ NORMAL LINE PASSING THROUGH CENTER OF LIGHT EMITTING REGION
LN₁ OPTICAL AXIS OF SECOND OPTICAL PATH CONTROL UNIT
LN₂ NORMAL LINE PASSING THROUGH CENTER OF WAVELENGTH SELECTION UNIT

1. A light emitting element including:
a light emitting unit including one light emitting region;
a first optical path control unit group consisting of a plurality of first optical path control units formed above the light emitting unit; and
a second optical path control unit formed on or above the first optical path control unit group,
wherein
the first optical path control units and the second optical path control unit have positive optical power, and
light emitted from the light emitting unit and focused by the first optical path control units is further focused by the second optical path control unit.

2. The light emitting element according to claim 1, wherein an orthographic projection image of the first optical path control units is included in an orthographic projection image of the second optical path control unit.

3. The light emitting element according to claim 2, wherein the orthogonal projection image of the first optical path control units in the first optical path control units is located on an outer periphery of the orthogonal projection image of the second optical path control unit.

4. The light emitting element according to claim 1, wherein the first optical path control units and the second optical path control unit each of which consists of a plano-convex lens having a convex shape in a direction away from the light emitting unit.

5. The light emitting element according to claim 1, wherein
a wavelength selection unit is provided above the light emitting unit, and
the first optical path control units and the second optical path control unit are provided on or above the wavelength selection unit.

6. The light emitting element according to claim 5, wherein a third optical path control unit is provided between the wavelength selection unit and the first optical path control units.

7. The light emitting element according to claim 6, wherein one or a plurality of the third optical path control units are provided for each of the first optical path control units.

8. The light emitting element according to claim 5, wherein a third optical path control unit is provided beneath or below the wavelength selection unit.

9. The light emitting element according to claim 8, wherein one or more of the third optical path control units are provided for each of the first optical path control units.

10. The light emitting element according to claim 1, wherein a wavelength selection unit is provided between the first optical path control units and the second optical path control unit.

11. The light emitting element according to claim 10, wherein a third optical path control unit is provided beneath or below the first optical path control units.

12. The light emitting element according to claim 11, wherein one or a plurality of the third optical path control units are provided for each of the first optical path control units.

13. The light emitting element according to claim 1, wherein a wavelength selection unit is provided on or above the second optical path control unit.

14. The light emitting element according to claim 13, wherein a third optical path control unit is provided beneath or below the first optical path control unit.

15. The light emitting element according to claim 14, wherein one or a plurality of the third optical path control units are provided for each of the first optical path control units.

16. A display device including:
a first substrate; second substrate; and
a plurality of light emitting element units including a plurality of types of light emitting elements,
wherein
each light emitting element includes:
a light emitting unit provided above the first substrate and including one light emitting region,
a first optical path control unit group consisting of a plurality of first optical path control units formed above the light emitting unit; and
a second optical path control unit formed on or above the first optical path control unit group,
wherein
the first optical path control units and the second optical path control unit have positive optical power, and
light emitted from the light emitting unit and focused by the first optical path control units is further focused by the second optical path control unit.
